(19) United States
(12) Patent Application Publication
(10) Pub. No.: US 2026/0125261 A1
(43) Pub. Date: May 7, 2026

(54) MEMS ELECTROSTATIC ACTUATOR BLADE CONFIGURATIONS AND METHODS OF MANUFACTURE

(71) Applicant: CALIENT.AI INC., Goleta, CA (US)

(72) Inventors: Andrew HOCKING, Ithaca, NY (US); Scott A. MILLER, Ithaca, NY (US)

(73) Assignee: CALIENT.AI INC., Goleta, CA (US)

(21) Appl. No.: 19/372,739

(22) Filed: Oct. 29, 2025

Related U.S. Application Data
(60) Provisional application No. 63/714,979, filed on Nov. 1, 2024.

(51) Int. Cl. B81B 3/00; B81C 1/00

(52) U.S. Cl. CPC B81B 3/0086; B81C 1/00698; B81B 2201/042; B81B 2203/0136; B81B 2203/0172; B81B 2203/0315; B81B 2203/04; B81B 2207/07; B81B 2207/096; B81C 2201/0132; B81C 2201/0133; B81C 2201/0176; B81C 2201/112; B81C 2203/0109; B81C 2203/0172

(57) ABSTRACT

Methods, apparatuses and methods of manufacture are described for a MEMS electrostatic blade actuator with different configurations to allow for improvements to performance. The MEMS electrostatic blade actuator with different configurations can be used in a MEMS mirror to reduce mass or reduce operating voltage.

### CROSS REFERENCE TO RELATED APPLICATION

This application claims priority to U.S. Provisional Application No. 63/714,979, filed on Nov. 1, 2024. The entire contents of the above-identified application are incorporated herein by reference.

### TECHNICAL FIELD

The present disclosure relates to the field of electrostatic blade actuators and, more particularly, to various actuator configurations developed to enhance device performance.

### BACKGROUND

Microelectromechanical systems (MEMS) and their arrays may incorporate parallel-plate actuators designed with gaps significantly larger than the actuator's stroke range. When a voltage is applied across the electrode plates, an attractive electrostatic force is generated, causing one plate to rotate. The maximum achievable rotation depends on the separation between the opposing plates. A larger gap allows greater deflection; however, in practice, the gap is usually made larger than strictly required for the plate's physical motion. This is because when the distance between the plates becomes too small (e.g., less than about one-third of the initial gap), the system reaches an unstable point at which the electrodes may suddenly snap together.

The force generated by a parallel-plate actuator is proportional to (voltage/gap)². Consequently, as the electrode gap increases, the required voltage rises with the square of the distance in order to produce the same force. During operation, the electrode plates do not remain perfectly parallel, causing the effective gap to decrease as the structure moves. As a result, the voltage required to achieve a specific displacement is high, nonlinear, and continuously varying. Furthermore, employing a large gap can introduce crosstalk between neighboring actuators within an array.

U.S. Pat. No. 6,753,638 (Adams), entitled “Electrostatic Actuator for Micromechanical Systems,” describes an electrostatic blade actuator designed to address the limitations of conventional parallel-plate actuators. In the apparatus disclosed, a stage includes a surface with a first blade extending perpendicularly from that surface. A frame likewise includes a surface with a second blade extending perpendicularly, positioned parallel to the first blade. The stage is pivotally coupled to the frame, enabling interaction between the blades to achieve actuation.

FIGS. 1A and 1B illustrate a blade actuator 100 described in U.S. Pat. No. 6,753,638. Blade actuator 100 includes a stage 140 and a frame 135. FIG. 1A shows stage 140 parallel to frame 135. FIG. 1B shows stage 140 tilted with respect to frame 135. Stage 140 may have a reflective element 145, such as a mirror, disposed on the top surface of stage 140. Stage 140 is pivotally coupled to frame 135 using stage flexures 153, 154 on diametrically opposed sides of stage 140. Stage flexures 153, 154 suspend stage 140 in a cavity formed by frame 135 such that stage 140 is free to pivot around a rotational axis formed by stage flexures 153, 154. Stage 140 and frame 135 each have one or more blades (e.g., blade 120 and blade 125, respectively) coupled to and extending from them. For example, blade 120 is coupled to stage 140 and blade 125 is coupled to frame 135. Applying a voltage difference between blades 120 and 125 can cause stage 140 to pivot.

Similarly, frame 135 may be pivotally coupled to an outer stationary frame (not shown) using frame flexures 151 and 152 on diametrically opposed sides of frame 135. The outer frame may be a stationary frame or, alternatively, may also be designed to move relative to yet another outer frame structure. Frame flexures 151 and 152 suspended frame 135 in a cavity formed by the outer frame such that frame 135 is free to pivot around a rotational axis formed by frame flexures 151 and 152. Frame flexures 151 and 152 are orthogonal to stage flexures 153, 154, thereby enabling a reflective element coupled to stage 140 to be pivoted in two dimensions (e.g., rolled and pitched).

Blade 125 remains fixed relative to blade 120, while blade 120 can rotate—such as by tilting or pivoting—as illustrated in FIG. 1A and FIG. 1B. Accordingly, blade 125 is referred to (e.g., designated) as a “fixed blade,” while blade 120 is referred to (e.g., designated) as a “movable blade.”

Blade 126 is fixed relative to blade 121, which is rotatable as shown in FIG. 1A and FIG. 1B. Thus, blade 126 is referred to (e.g., designated) as a “fixed blade,” and blade 121 is referred to (e.g., designated) as a “movable blade.”

Blade 120 extends in a direction perpendicular to the undersurface of stage 140 and blade 125 extends in a direction perpendicular to the undersurface of frame 135. An electric potential applied between blades 120 and 125 may cause an attraction between blade 120 and blade 125. Because blade 120 is coupled to stage 140, an attraction of blade 120 towards blade 125 causes stage 140 to pivot about the rotational axis formed by stage flexures 153, 154. For example, stage 140, and the corresponding blades coupled to stage 140, may be pivoted such that the surface of stage 140 lies at an angle relative to the surface of frame 135 as shown by the position illustrated in FIG. 1B. The operation of the blades is discussed below in relation to FIGS. 2A and 2B.

FIG. 2A is a perspective view illustrating a blade actuator 211 from U.S. Pat. No. 6,753,638. Blade actuator 211 includes a movable blade 212 that is part of structure 222 to be actuated. For example, structure 222 may be a segment of stage 140 where blade 120 of FIG. 1A and FIG. 1B is attached to. Structure 222 may be constrained from vertical or lateral motion but remains free to pivot on flexures 235, 235′. Flexures 235, 235′ are rectangularly shaped. The rotation of structure 222 allows for blade 212 to rotate within the X-Y plane (292, 291). By the design of flexures 235, 235′, the motion of blade 212 is constrained in Z-direction 293 (into/out of the page).

Blade actuator 211 also includes blade 213 that is part of structure 223. For example, blade 213 corresponds to blade 125 of FIGS. 1A and 1B and blade 212 corresponds to blade 120 of FIGS. 1A and 1B. Blade 213 can, for example, be attached to frame 135. Given that blade 212 rotates within the X-Y plane (292, 291) relative to blade 213, blade 212 is referred to as a movable blade and blade 213 is referred to as a fixed blade.

Blades 212 and 213 may be configured as electrodes having electric charges to generate an electrostatic field between them. An electrostatic field forms around any single object that is electrically charged with respect to its environment. An object is negatively charged (−) if the object has an excess of electrons with respect to its surroundings. An object is positively charged (+) the object is deficient in electrons with respect to its surroundings. Objects attract if the charges of the objects are of opposite polarity (+/−) and repel if the charges of the objects are of the same polarity (+/+ or −/−).

An electrostatic field also arises from a potential difference, or voltage gradient, that exists when charge carriers, such as electrons, are stationary (hence the “static” in “electrostatic”). When two objects (e.g., blades 212 and 213) positioned in each other's vicinity have different electric charges, an electrostatic field exists between the objects. As such, when different voltages are applied to blades 212 and 213, an attractive force is produced between the blades 212 and 213. The attractive force between blades 212 and 213 is proportional to the square of the voltage potential (e.g., voltage difference) between the blades 212 and 213.

When there is no voltage potential (e.g., no voltage difference) between blades 212 and 213, surface 252 of structure 222 is substantially parallel with surface 253 of structure 223, and blade 212 is separated from blade 213 by a distance 230 along X-direction 292. Distance 230 can either be positive or negative, indicating that blades 212 and 213 may overlap or non-overlap. When a voltage potential exists between blades 212 and 213, the blade 212 is moveably attracted toward blade 213, which is fixed in relative to blade 212, and structure 222 pivots about flexures 235, 235′. The greater the height 233 of the blades 212 and 213, the greater the torque that is generated on structure 222. The generation of a greater torque decreases the amount of voltage potential required to pivot structure 222. Because structure 222 (to which blade 212 is coupled) is constrained to pivot on flexures 235, 235′, blade 212 moves in X-direction 292 and Y-direction 291 toward blade 213 until blades 212 and 213 overlap (e.g., surface areas of blades 212 and 213 overlap), as illustrated in FIG. 2B.

Blade 212 is configured to rotate about flexures 235, 235′, which may be implemented as torsional springs similar to flexures 153, 154 illustrated in FIG. 1. Accordingly, the electrostatic attractive force generated between blades 212 and 213 may be represented as a torque. In particular, when a voltage potential is applied between blades 212 and 213, a torque is induced on blade 212 that is approximately proportional to the square of the blade height 233 and inversely proportional to gap 232, as defined by Equation 1 set forth below:

$$torque = \frac{1}{2} \frac{{ε}_{0} {height}^{2} {voltage}^{2}}{gap} \qquad Equation 1$$

As shown in FIG. 2C, based on length 240 and height 233, a portion 219 of blade 212 may no longer overlap blade 213 towards the end of the blade 212's stroke range. As the leading tip 209 of blade 212 moves past the edge 208 of blade 213, the torque may taper off. As such, for a given height 233, the stroke range may be primarily determined by the length 240 of the blades 212 and 213.

Blades 212 and 213 may have a length 240 and a height 233 each on the order of hundreds of microns and widths 231 on the order of tens of microns. For example, structure 222 may be rotated an angle (θ) that may be greater than 20 degrees relative to the resting position of structure 222. As will be appreciated by those skilled in the art, blades 212 and 213 may have differing lengths, heights, and widths, which may also vary relative to each other.

The extent of overlap between blades 212 and 213, as well as the geometric configuration of portion 219 of blade 212, are factors influencing the force profile as a function of deflection angle. Because blade 212 is constrained from motion in Z-direction 293, gap 232 or distance between blades 212 and 213 remains substantially constant along the stroke range of blade 212. As shown in Equation 1 above, the torque produced between blades 212 and 213 is proportional to 1/gap. Because the gap remains substantially constant along the stroke range of blade 212, the torque also remains substantially constant for a given voltage potential. Gap 232 of FIG. 2A between the blades 212 and 213 is typically on the order of five to twenty microns. Maintaining a small and constant gap between blades 212 and 213 results in high forces, and consequently high torques, being generated throughout the full stroke range of blade 212. As a result, a greater deflection angle of blade 212 can be achieved with a reduced actuation voltage (i.e., voltage potential). For instance, the actuation voltage may be on the order of 100 volts.

FIG. 2D is a top view of another blade actuator 211 where an additional fixed blade 214 may be used to further increase the attraction force on blade 212 and, thereby, reduce the voltage potential necessary for blade actuation. In this example, a first voltage potential between blade 212 and blade 213 and a second voltage potential between blade 212 and blade 214 cause blade 212 to rotate. As a result, the voltage potential required between fixed blades 213 and 214 and movable blade 212 to rotate blade 212 may be reduced.

As shown in FIG. 2E, an additional fixed blade 229 (corresponding to blade 126 in FIG. 1A) may also be placed on the other side of a blade 212 to rotate blade 212 in both directions. Alternatively, an additional movable blade 121 may be used in conjunction with additional fixed blade 126, as illustrated in FIGS. 1A and 1B. In this example, there is one fixed blade and one movable blade for each direction of motion.

In conventional designs, electrostatic actuator blades employ a single electrical voltage throughout the entire depth of the blade. Accordingly, the structural silicon at the upper portion of the blade is held at the same electrical voltage as the actuator blade and is constrained from extending beyond the boundary isolation, as described in U.S. Pat. No. 7,728,339 (Adams).

FIG. 3A illustrates that etch lag encountered during deep reactive etching can impede complete etching of the regions between the blades, as indicated by the circled areas A-D. In particular, certain regions (circled as area C in the example in FIG. 3A) may be partially unetched, resulting in electrical connection between adjacent blades. By contrast, other regions (circled by A, B, and D) may also be partially etched such that blades are not electrically connected, but the jagged edges may still touch when the blades move. Furthermore, unpredictable geometries can lead to unpredictable forcing. Such improper etch conditions (shown in circled as areas A, B, C, and D) restrict the ability to fabricate overlapped blades, a structure that can be used for comb fingers in MEMS devices. Consequently, the electrostatic effectiveness—specifically, the electrically applied torque—of the system is significantly reduced until engagement of the blades occurs, as shown in FIG. 3B.

While the blade actuator described in U.S. Pat. No. 6,753,638 offers advantages over parallel-plate actuators, certain limitations remain. Blade actuators introduce substantial mass to the MEMS structure, a drawback that U.S. Pat. No. 8,982,440 (Lee) addresses to some extent. Furthermore, existing electrostatic actuator blades employ a single electrical voltage throughout their depth, requiring that the structural silicon at the top of each blade be held at the same potential as the actuator blade, which precludes extension beyond boundary isolation. The deep reactive ion etching (DRIE) process used for silicon fabrication is subject to reactive ion etching lag, which results in slower etching rates in narrow gaps compared to wide gaps. In practice, electrostatic actuator blades are fabricated with wide gaps. To accommodate reliable production etching, blade designs should avoid excessively tight gaps. As a result, producing an initial blade overlap with narrow gaps is not feasible, leading to reduced initial electrostatic force generated by the blades.

Accordingly, there is a continuing need for MEMS electrostatic blade actuators that can overcome the limitation of insufficient initial overlap. For instance, actuator configurations capable incorporating additional fingers could facilitate initial blade overlap and thereby enhance the initial electrostatic force.

There is also a need for MEMS electrostatic blade actuators that address the combined issues of excess mass, uniform voltage application, and lack of initial overlap. Designs that integrate multiple voltages and enable initial blade overlap would provide increased electrostatic force and simultaneously reduce drawbacks associated with actuator mass.

### SUMMARY

One aspect of the disclosure provides an actuator comprising a frame defining a cavity and including a first base, and a stage including a second base. The actuator further includes a first flexure and a second flexure that suspend the stage within the cavity, a first blade coupled to (e.g., extended from) the first base, and a second blade coupled to (e.g., extended from) the second base. An insulation layer includes a first portion disposed between the first base and the first blade, a second portion disposed between the second base and the second blade, and a third portion disposed on the second blade, wherein the third portion has a first side in contact with the second blade and a second side that is exposed.

Implementations of the disclosure may include one or more of the following optional features. In some implementations, the insulation layer comprises a buried oxide layer. In some implementations, the first or second blades are electrically connected to their respective bases through vias, e.g. respective first via and second via, extending through corresponding portions of the insulation layer. In some implementations, the first blade extends from the first base substantially perpendicularly such that the first base and the first blade define a T-shaped configuration.

In some implementations, the third portion of the insulation layer and a side surface of the second base define a notch. The notch may define an opening that partially overlaps with the first base in a first direction.

In some implementations, applying different voltages to the first and second blades causes the second blade to be electrostatically attracted toward the first blade, thereby causing the stage to pivot about the first and second flexures. In some implementations, applying the voltages causes the second blade to overlap the first blade to generate a primary actuating torque and further overlap a first end of the first base to generate a supplemental actuating torque.

In some implementations, the actuator further comprises a third blade coupled to a third base. Applying a first voltage to the first and third blades and a second voltage to the second blade causes the second blade to overlap both the first and third blades to generate a primary actuating torque, and further overlap ends of the first and third bases to generate a supplemental actuating torque. The first and third blades each extend substantially perpendicularly from their bases, forming T-shaped configurations, and the first voltage is different from the second voltage.

Another aspect of the disclosure provides an actuator comprising a frame defining a cavity, a stage, first and second flexures suspending the stage within the cavity, a plurality of stage fingers extending from the stage toward the frame, and a plurality of frame fingers extending from the frame toward the stage, wherein an end portion of a first stage finger overlaps with an end portion of a first frame finger.

Implementations of the disclosure may include one or more of the following optional features. In some implementations, the actuator includes a first blade extending from the stage and a second blade extending from the frame, the two blades being substantially parallel. In some implementations, a third blade extends from the frame and is spaced from the second blade to define a gap into which the first blade tilts during operation.

In some implementations, the plurality of stage fingers includes first and second stage fingers parallel to one another, and the end portion of a first frame finger is disposed between the two stage fingers. In some implementations, the frame fingers can include first and second frame fingers parallel to one another, with the end portion of a stage finger disposed between them.

In some implementations, applying different voltages to the first and second blades causes the plurality of stage fingers to be electrostatically attracted toward the plurality of frame fingers, causing the stage to pivot about the flexures. Applying the voltages further causes the stage fingers and frame fingers to generate a first actuating torque and the first blade to overlap the second blade, producing a second actuating torque.

In some implementations, applying different voltages further causes overlap between the first blade and the frame fingers to produce a third actuating torque. A first overlap area is defined by interleaving of the stage and frame fingers, and applying different voltages causes the overlap area to increase.

In some implementations, a first overlap area is defined by an overlapping region of the first and second blades, and application of different voltages causes the overlap area to increase. In yet other examples, applying different voltages causes the top surfaces of the plurality of stage fingers to elevate such that those surfaces are disposed higher than the top surfaces of the plurality of frame fingers.

The details of one or more implementations of the disclosure are set forth in the accompanying drawings and the description below. Other aspects, features, and advantages will be apparent from the description and drawings, and from the claims.

### INCORPORATION BY REFERENCE

All publications, patents, and patent applications mentioned in this specification are herein incorporated by reference to the same extent as if each individual publication, patent, or patent application was specifically and individually indicated to be incorporated by reference.
US 2003/0200748 A1 published Oct. 30, 2003 by Bromley, Susan C. et al.;
US 2004/0160118 A1 published Aug. 19, 2004 by Knollenberg, Clifford F. et al.;
US 2007/0247018 A1 published Oct. 25, 2007 by Flores et al.;
US 2012/0279837 A1 published Nov. 8, 2012 by De Wolf et al.;
US 2021/0396992 A1 published Dec. 23, 2021 by Wang et al.;
US 2022/0269067 A1 published Aug. 25, 2022 by McDONALD et al.;
US 2024/0012332 A1 published Jan. 11, 2024 by HASPESLAGH et al.;
US 2024/0018549 A1 published Jan. 18, 2024 by BANERJEE;
US 2024/0094525 A1 published Mar. 21, 2024 by HOCKING;
US 2024/0295728 A1 published Sep. 5, 2024 by JIN et al.;
U.S. Pat. No. 5,563,343 A published Oct. 8, 1996 by Shaw et al.;
U.S. Pat. No. 5,729,026 A published Mar. 17, 1998 by Mamin et al.;
U.S. Pat. No. 5,739,941 A published Apr. 14, 1998 by Knipe et al.;
U.S. Pat. No. 6,054,659 A published Apr. 25, 2000 by Lee et al.;
U.S. Pat. No. 6,201,629 B1 issued Mar. 13, 2001 by McClelland et al.;
U.S. Pat. No. 6,239,473 B1 issued May 29, 2001 by Adams et al.;
U.S. Pat. No. 6,396,620 B1 issued May 28, 2002 by Goodwin-Johansson;
U.S. Pat. No. 6,701,038 B2 issued Mar. 2, 2004 by Rensing et al.;
U.S. Pat. No. 6,753,638 B2 issued Jun. 22, 2004 by Adams et al.;
U.S. Pat. No. 7,095,546 B2 issued Aug. 22, 2006 by Mala et al.;
U.S. Pat. No. 7,098,571 B2 issued Aug. 29, 2006 by Adams et al.;
U.S. Pat. No. 7,196,599 B2 issued Mar. 27, 2007 by Dabbaj;
U.S. Pat. No. 7,261,826 B2 issued Aug. 28, 2007 by Adams et al.;
U.S. Pat. No. 7,548,145 B2 issued Jun. 16, 2009 by Rubel;
U.S. Pat. No. 7,728,339 B1 issued Jun. 1, 2010 by Adams et al.;
U.S. Pat. No. 7,952,778 B2 issued May 31, 2011 by Moidu et al.;
U.S. Pat. No. 8,115,576 B2 issued Feb. 14, 2012 by Lu et al.;
U.S. Pat. No. 8,134,277 B2 issued Mar. 13, 2012 by Moidu;
U.S. Pat. No. 8,188,634 B2 issued May 29, 2012 by Krueger et al.;
U.S. Pat. No. 8,205,268 B2 issued Jun. 19, 2012 by Shile;
U.S. Pat. No. 8,361,331 B2 issued Jan. 29, 2013 by Yang et al.;
U.S. Pat. No. 8,378,434 B2 issued Feb. 19, 2013 by Krylov et al.;
U.S. Pat. No. 9,086,571 B2 issued Jul. 21, 2015 by Zhou;
U.S. Pat. No. 9,310,609 B2 issued Apr. 12, 2016 by Rueblinger et al.;
U.S. Pat. No. 9,674,627 B2 issued Jun. 6, 2017 by Hsu et al.;
U.S. Pat. No. 9,764,942 B2 issued Sep. 19, 2017 by Iihola et al.;
U.S. Pat. No. 10,274,723 B2 issued Apr. 30, 2019 by Ozaki et al.;
U.S. Pat. No. 10,291,151 B2 issued May 14, 2019 by Gutierrez;
U.S. Pat. No. 10,444,492 B2 issued Oct. 15, 2019 by Hopkins et al.;
U.S. Pat. No. 10,761,317 B2 issued Sep. 1, 2020 by Hauf et al.;
U.S. Pat. No. 10,879,869 B2 issued Dec. 29, 2020 by Elsayad et al.;
U.S. Pat. No. 11,567,312 B2 issued Jan. 31, 2023 by Zhou;
U.S. Pat. No. 12,091,313 B2 issued Sep. 17, 2024 by Towfighian et al.;
WO 2003/073597 A1 published Sep. 4, 2003 by KyoHo;
WO 2016/020716 A1 published Feb. 11, 2016 by BaTis et al.;
WO 2016/143804 A1 published Sep. 15, 2016 by Ozaki et al;
US 2023/0136105 A1 published May 4, 2025 by Miller;
US 2023/0023348 A1 published Jan. 26, 2023 by Miller;
U.S. Pat. No. 12,259,546 B2 issued Mar. 25, 2025 by Halbach et al;
US 2024/0094525 A1 published Mar. 21, 2024 by Hocking;
US 2024/0025733 A1 published Jan. 25, 2024 by Hocking et al.;
U.S. Pat. No. 8,982,440 B2 issued Mar. 17, 2015 by Lee;
U.S. Pat. No. 8,705,159 B2 issued Apr. 22, 2014 by Lee;
U.S. Pat. No. 4,814,774 A issued Mar. 21, 1989 by Herczfeld; and
U.S. Pat. No. 8,674,460 B2 issued Mar. 18, 2014 by Gutierrez et al.

### BRIEF DESCRIPTION OF THE DRAWINGS

The features of the present disclosure are set forth with particularity in the appended claims. A better understanding of the features and advantages of the present disclosure will be obtained by reference to the following detailed description that sets forth illustrative examples, in which the principles of the disclosure are utilized, and the accompanying drawings of which:

FIG. 1A illustrates a prior art actuator with a stage parallel to a frame;

FIG. 1B illustrates a prior art actuator an actuator with a stage tilted with respect to a frame;

FIG. 2A is a perspective view of a prior art blade actuator; FIG. 2B is a perspective view of the prior art blade actuator in FIG. 2A rotated about the flexure; FIG. 2C is a side view of the prior art blade actuator in FIG. 1A; FIG. 2D is a top view of an alternative prior art blade actuator; FIG. 2E is a top view illustrating another prior art blade actuator;

FIG. 3A is an image of MEMs blades illustrating a failure to achieve full etching for a prior art blade actuator; FIG. 3B is a graph of the results of electrostatic simulation showing the blade tilt and torque for the prior art blade actuator;

FIG. 4A shows a perspective view of a blade actuator in accordance with some implementations of the disclosure; FIG. 4B shows a cross-sectional side view of blade actuator in accordance with some implementations of the disclosure; FIG. 4C is the graph of the results of an electrostatic simulation of the actuator shown in FIG. 4B compared to the actuator shown in FIG. 2A;

FIG. 5A shows a perspective view of a blade actuator in accordance with some implementations of the present disclosure; FIG. 5B is a cross-section of the actuator shown in FIG. 5A in accordance with some implementations of the present disclosure; FIG. 5C is a side view illustrating the actuation of the blade actuator of FIG. 5A; FIG. 5D is the graph of the results of an electrostatic simulation of the actuator shown in FIG. 5A compared to the actuator shown in FIG. 2A;

FIG. 6A shows a perspective view of a blade actuator in accordance with some implementations of this disclosure; FIG. 6B is a cross-section of the actuator shown in FIG. 6A; FIG. 6C is the graph of the results of an electrostatic simulation of the actuator shown in FIG. 6A compared to the actuator shown in FIG. 2A;

FIGS. 7A-I′ illustrate a blade actuator in accordance with some implementations of the disclosure; FIG. 7J shows blades configured to increase engagement due to applied voltage instead of thermal mismatch; FIG. 7K shows the blades in FIG. 7J when a small voltage difference is applied to blades; FIG. 7L shows a top view of FIG. 7J and FIG. 7K;

FIGS. 8A-H relate to a MEMs device with increased electrostatic effectiveness that allows large gaps around the blades;

FIG. 9A illustrates a cross-sectional side view of blade actuator configured with blade actuator and base blade which enhances rotational actuation of blade actuator in accordance with some implementations of the present disclosure; FIG. 9B illustrates a top view of blades and base blade as arranged in FIG. 9A; FIG. 9C shows a top view of another example of blade actuator, featuring an additional fixed blade as illustrated in FIG. 2D, along with a base blade; FIG. 9D illustrates finite element analysis (FEA) results of the electrostatic performance for blade actuators shown in FIG. 2A, FIG. 9A, and FIG. 9C;

FIG. 9E depicts a close-up of the torque-angle response in the 0°-5° range shown in FIG. 9D; FIG. 9F shows a close-up of the torque-angle response in the 17.5°-20.5° range shown in FIG. 9D;

FIG. 10A shows a cross-sectional side view of blade actuator in accordance with some implementations of the present disclosure; FIG. 10B illustrates the results of a finite element analysis evaluating the electrostatic behavior of the blade actuators shown in FIG. 10A; FIG. 10C provides a magnified view of the net torque curve within the 0° to 5° range of rotational motion; FIG. 10D provides a magnified view of the net torque curve within the 17.5° to 20.5° rotation range;

FIG. 11 shows a cross-sectional side view of blade actuator in accordance with some implementations of the present disclosure;

FIG. 12 shows a cross-sectional side view of blade actuator in accordance with some implementations of the present disclosure;

FIG. 13 shows a cross-sectional side view of blade actuator in accordance with some implementations of the present disclosure;

FIG. 14A illustrates a cross-section of a silicon wafer; FIG. 14B illustrates a portion of a wafer with a masking layer, photo-resistant layer, and an opening to the silicon surface of the wafer; FIG. 14C illustrates an isolation trench formed in a silicon wafer; FIG. 14D illustrates a portion of a wafer with a dielectric layer on the top surface of the silicon wafer and on the sidewalls and bottom of the isolation trench; FIG. 14E illustrates a portion of a wafer after planarization of a dielectric layer; FIG. 14F illustrates isolation trenches on top of a wafer and a masking layer for blades on a bottom of the wafer; FIG. 14G illustrates metallization on the top of the wafer; FIG. 14H illustrates trenches on the top of the wafer;

FIG. 14I illustrates blades that result from deep silicon etching; FIG. 14J illustrates a base wafer bonded to a wafer containing blades; FIG. 14K illustrates a wafer after a release etch separates portions of the structure and after attachment of a lid wafer;

FIG. 15 shows a cross-section view of a cavity silicon-on-insulator (CSOI) wafer in accordance with some implementations of the disclosure;

FIG. 16A-FIG. 16T show a fabrication method of the base wafer in accordance with some implementations of the disclosure; and

FIG. 17A-FIG. 17N show a fabrication method of the device wafer in accordance with some implementations of the disclosure.

Like reference symbols in the various drawings indicate like elements.

### DETAILED DESCRIPTION

### I. Devices

### (a) Torque Enhancement by Geometric Configuration

As will be appreciated by those skilled in the art, blades disclosed herein may be either movable or fixed. For example, a movable blade or structure associated with the movable blade may be configured to move toward a fixed blade or a structure associated with the fixed blade. As a result, the movable blade or structure associated with the movable blade may be pivotable or rotatable. The fixed blade or the structure associated with the fixed blade remains stationary relative to the movable blade or the structure associated with the movable blade.

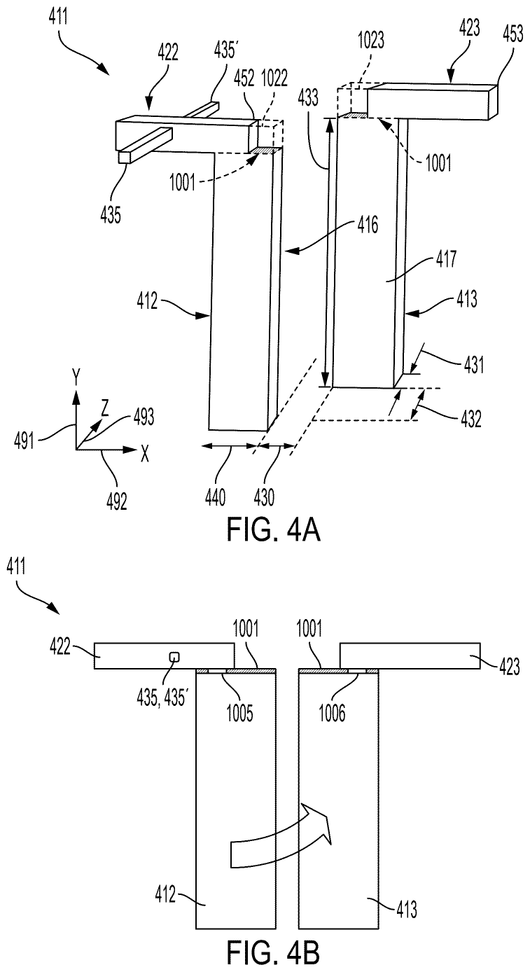

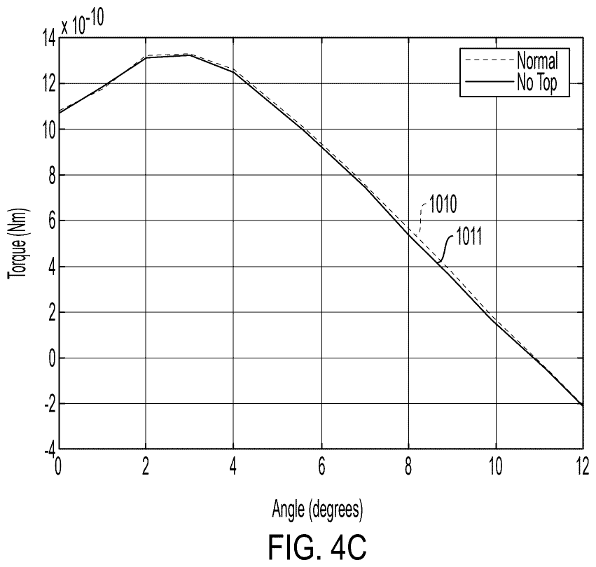

FIG. 4A shows a perspective view of a blade actuator 411 in accordance with some implementations of the disclosure.

Blade actuator 411 includes a blade 412, that is part of structure 422, to be actuated. In this example, structure 422 (also referred to as a first blade base) may be a segment of a stage (e.g., stage 140). As shown, in this example, a buried insulation layer 1001 (e.g., buried oxide layer) is disposed between blade 412 and structure 422, which is moveable in relative to buried insulation layer 1001 between blade 413 and structure 423. Similarly, buried insulation layer 1001 is disposed between blade 413 and structure 423, which is fixed in relative to buried insulation layer 1001 between blade 412 and structure 422. In this example, buried insulation layer 1001 includes silicon dioxide. As depicted in FIG. 4A, a dotted first portion 1022 (a portion of structure 422 in this example), positioned on blade 412, has been removed from structure 422. This removal may be accomplished through one or more silicon etching processes that terminate at buried insulation layer 1001. In this example, the removed first portion 1022 has a cubic or rectangular prism shape. As a result, a first notch is created defined by exposed portion of insulation layer 1001 on blade 412 and a side surface of structure 422.

Blade actuator 411 also includes blade 413 that is part of structure 423. In this example, structure 423 (also referred to as a second blade base) may be a segment of a frame (e.g., frame 135). Buried insulation layer 1001 (e.g., buried oxide layer) is disposed between blade 413 and structure 423, which is fixed. As described above, buried insulation layer 1001 may include silicon dioxide. As shown in FIG. 4A, a dotted second portion 1023 (a portion of structure 423), positioned on the blade 413, has been removed from structure 423. In this example, the removed second portion 1023 has a cubic or rectangular prism shape. This removal may be accomplished through one or more silicon etching processes that terminate at the buried insulation layer 1001. As a result, a second notch is created defined by exposed portion of insulation layer 1001 on blade 413 and a side surface of structure 423.

As used herein, the term “blade” denotes a rigid object that may exhibit various shapes. By way of example, a blade can be embodied as a polyhedron, as illustrated in FIG. 4A and FIG. 4B. Alternatively, the blade may possess other three-dimensional polygonal shapes, including but not limited to cubic or trapezoidal configurations. The blade may be constructed as either a solid or a hollow member.

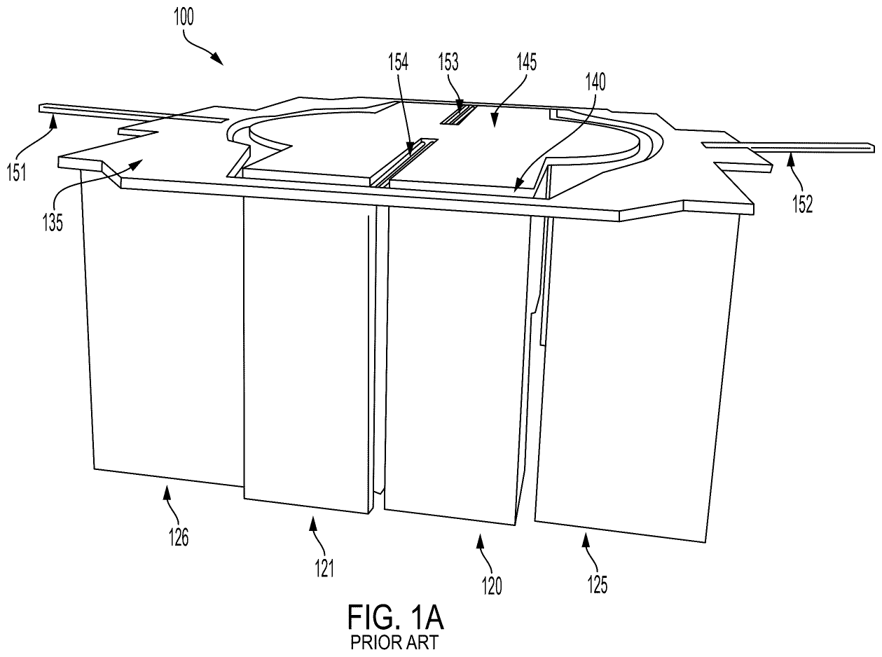

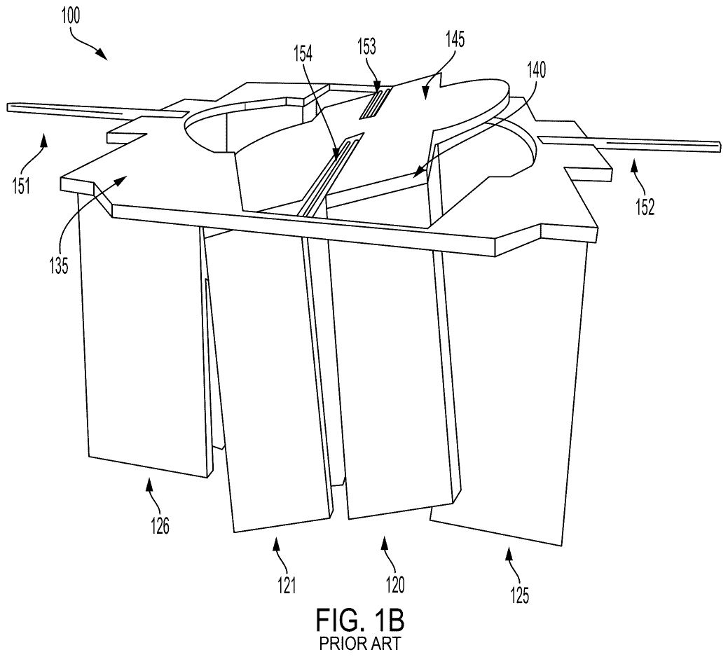

The removal of dotted first portion 1022 and dotted second portion 1023 reduces the overall mass of blade actuator 411. Blade 413 may correspond to blade 125 in FIG. 1A, and the blade 412 may correspond to blade 120 in FIG. 1A. Blade 413 may, for example, be attached to frame 135, while the blade 412 may, for example, be attached to stage 140. The removals of the dotted first portion 1022 and dotted second portions 1023 reduce the mass associated with frame 135 and stage 140, thereby increasing the resonant frequencies of frame 135 and stage 140. Higher resonant frequencies can provide faster response times and reduce coupling to environmental vibrations. In certain applications, however, it may be desirable to maintain the original resonant frequencies of frame 135 and stage 140. This can be achieved by adjusting the stiffness of frame flexures 151, 152 and stage flexures 153, 154 (corresponding to flexures 435, 435′ in FIG. 4A) to compensate for the reduced mass. Such adjustments would result in a larger angular deflection for a given applied voltage potential.

As illustrated in FIG. 4A, blade actuator 411 may have both dotted first portion 1022 and the dotted second portion 1023 removed from structures 422 and 423, respectively. Alternatively, only dotted first portion 1022 may be removed from structure 422, or only dotted second portion 1023 may be removed from structure 423. In this manner, the mass of stage 140 or the mass of frame 135 may be independently reduced.

FIG. 4B shows a cross-sectional side view of blade actuator 411 in accordance with some implementations of the present disclosure.

In this example, a via 1005 (e.g., one or more conductive vias such as polysilicon vias) electrically connects structure 422 (e.g., silicon structure 422) to blade 412 (e.g., silicon blade 412) through buried insulation layer 1001. Via 1006 (e.g., one or more conductive vias such as polysilicon vias) electrically connects structure 423 (e.g., silicon structure 423) to blade 413 (e.g., silicon blade 413) through buried insulation layer 1001.

As a voltage potential is applied between blades 412 and 413 (e.g., applying different voltages to blades 412 and 413), blade 412, which is configured to move, is moveably attracted toward blade 413 and structure 422 pivots about flexures 435, 435′.

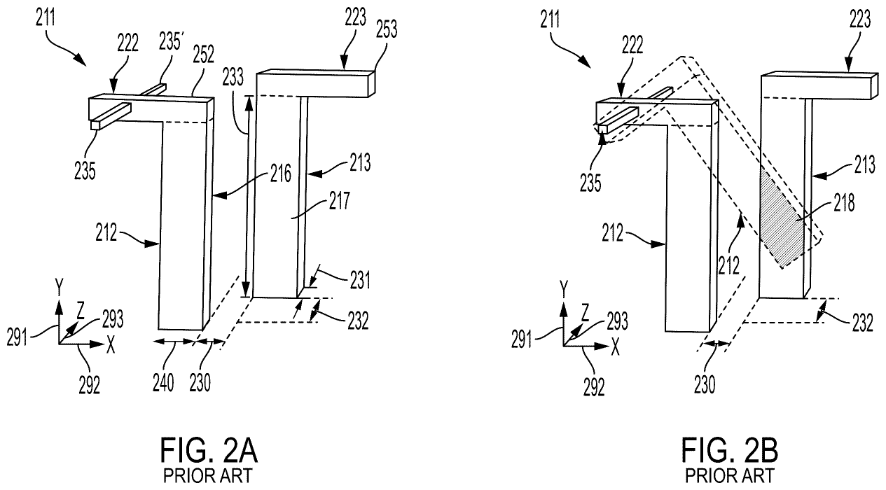

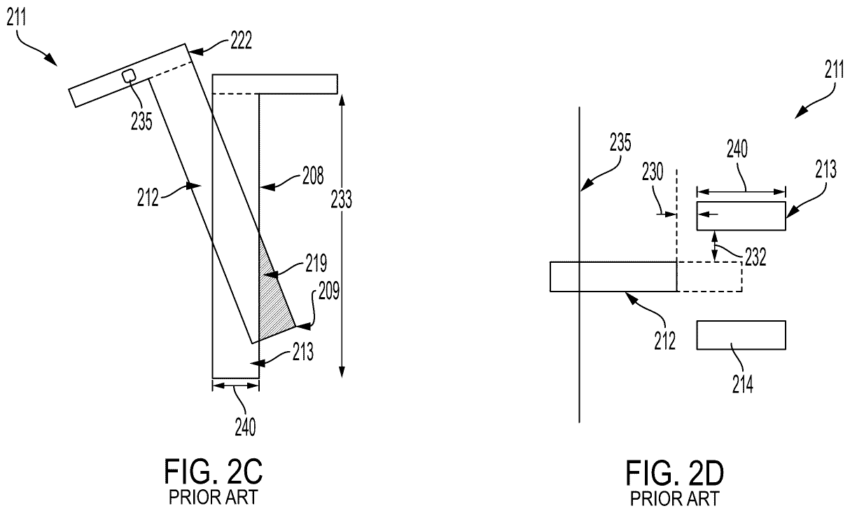

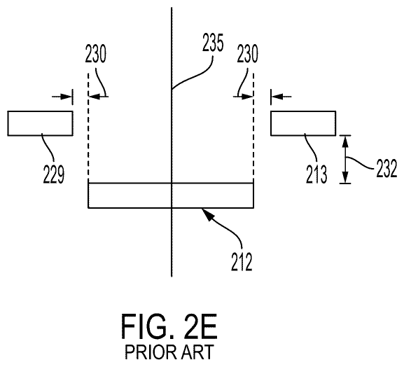

FIG. 4C presents the results of a finite element analysis of the electrostatic behavior of blade actuators 211, 411. The graph plots the torque sum (defined as the electrostatic torque minus the mechanical restoring torque provided by flexures 435, 435′) as a function of rotation angle (in degrees) for a constant applied voltage potential of 100V (e.g., 100V voltage difference between blades 412 (212) and 413 (213)). The displaced angle of the system corresponds to the point where the curve crosses zero. Curve 1010 illustrates the results for blade actuator 211 shown in FIG. 2A with a given set of dimensions, while curve 1011 represents the blade actuator 411 of FIG. 4A with the same dimensions but with dotted first and second portions 1022, 1023 removed. The two curves 1010, 1011 are nearly identical, with both actuators 211, 411 exhibiting approximately 11 degrees of tilt under the voltage potential of 100V. These results indicate that the removals of dotted first portion 1022 and dotted second 1023 have no effect on the electrostatic performance of blade actuator 211. In other words, removing dotted first dotted portion 1022 and dotted second portion 1023 reduces the mass associated with stage 140 and mass associated with frame 135, respectively, while preserving characteristic features of blade actuator 411 (e.g., strength, torque).

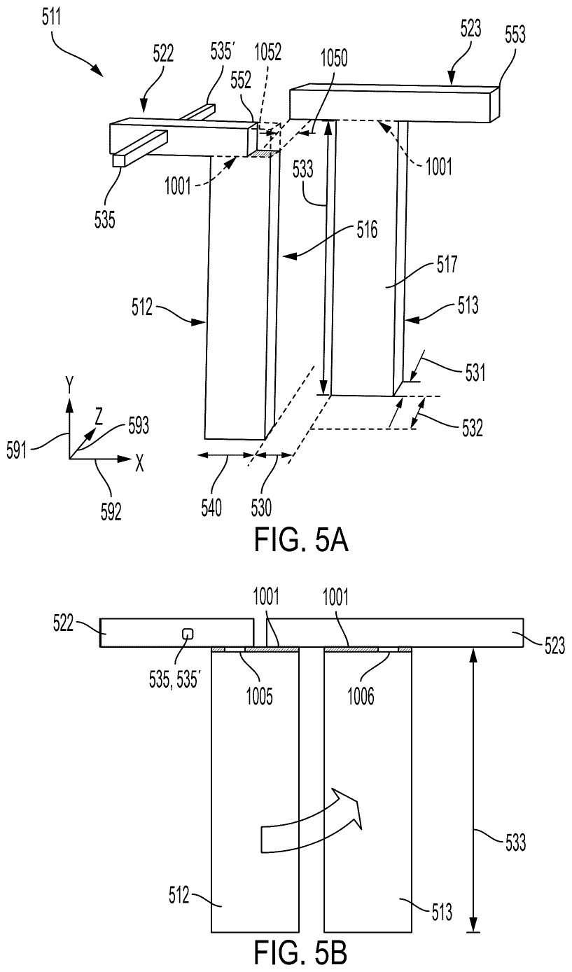

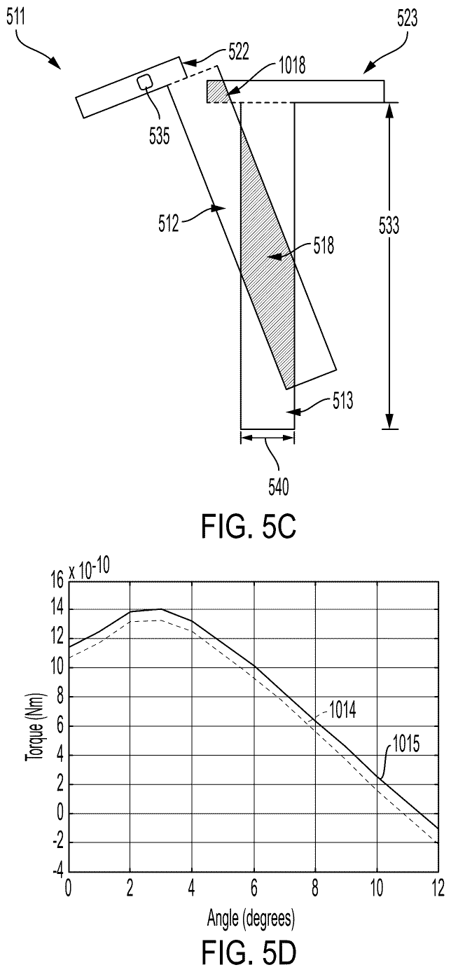

FIG. 5A shows a perspective view of a blade actuator 511 in accordance with some implementations of the present disclosure.

Blade actuator 511 includes a blade 512, that is part of structure 522, to be actuated. In this example, structure 522 (also referred to as a first blade base) may be a segment of a stage (e.g., stage 140). As shown, in this example, a buried insulation layer 1001 (e.g., buried oxide layer) is disposed between blade 512 and structure 522. Similarly, buried insulation layer 1001 is disposed between blade 513 and structure 523. In this example, buried insulation layer 1001 includes silicon dioxide. As depicted in FIG. 5A, a dotted first portion 1052 (e.g., dotted first portion 1022 in FIG. 4A), positioned on blade 512, has been removed from structure 522. This removal may be accomplished through one or more silicon etching processes that terminate at the buried insulation layer 1001. In this example, the removed first portion 1052 has a cubic or rectangular prism shape. As a result, a notch is created defined by exposed portion of insulation layer 1001 on blade 512 and a side surface of structure 522. Also, the notch defines an opening that overlaps at least partially with a first blade base.

Blade actuator 511 also includes blade 513 that is part of structure 523. In this example, structure 523 (also referred to as a second blade base) may be a segment of a frame (e.g., frame 135). Buried insulation layer 1001 (e.g., buried oxide layer) is disposed between blade 513 and structure 523, which is fixed. As described above, buried insulation layer 1001 may include silicon dioxide. Referring to FIG. 2A and FIG. 5A, structure 523 has been extended in relative to structure 223 of FIG. 2A to at least partially overlap with the dotted first portion 1052 (or opening defined by the notch) in the Z-direction 593. In this example, the extent of the overlap 1050 is less than or equal to the length of the dotted first portion 1052 which was removed from structure 522. As shown, in this example, structure 523 and blade 513 define a T-shaped configuration.

The removal of first portion 1052 may result in a reduction of the overall mass of blade actuator 511. For example, blade 513 corresponds to blade 125 in FIG. 1A, and blade 512 corresponds to blade 120 in FIG. 1A. Blade 513 may be coupled to frame 135, while blade 512 may be coupled to stage 140. The removal of the dotted first portions 1052 reduces the mass associated with stage 140. Conversely, the extension of structure 523 increases the mass associated with frame 135. Consequently, the resonant frequency of frame 135 may decrease, while the resonant frequency of stage 140 may increase.

FIG. 5B shows a cross-sectional side view of blade actuator 511 in accordance with some implementations of the present disclosure.

In this example, a via 1005 (e.g., one or more conductive vias such as polysilicon vias) electrically connects structure 522 (e.g., silicon structure 522) to blade 512 (e.g., silicon blade 512) through buried insulation layer 1001. Via 1006 (e.g., one or more conductive vias such as polysilicon vias) electrically connects structure 523 (e.g., silicon structure 523) to blade 513 (silicon blade 513) through buried insulation layer 1001.

As a voltage potential is applied between blades 512 and 513, the blade 512 is moveably attracted toward blade 513, which is fixed, and structure 522 pivots about flexures 535, 535′. The greater the height 533 of the blades 512 and 513, the greater the torque that is generated on structure 522. In this example, the height of the blades 512 is the same as the height of the blade 513. Alternatively, the height of the blade 512 may be greater or less than the height of the blade 513. The generation of a greater torque decreases the amount of voltage potential required to pivot structure 522. Because structure 522 (to which blade 512 is coupled) is constrained to pivot on flexures 535, 535′, blade 512 is moveable in X-direction 592 and Y-direction 591 toward blade 513 until blades 512 and 513 overlap (e.g., surface areas of blades 512 and 513 overlap), as illustrated in FIG. 5C. The area of overlap 518 between blades 512 and 513 is not the sole region generating torque in this example. Blade 512 also overlaps with structure 523 (specifically, an extension of structure 523 in this example) at area 1018. This additional region of overlap contributes further actuating torque.

FIG. 5D presents results from a finite element analysis of the electrostatics associated with the blade actuators 211, 511. The graph illustrates the net torque (defined as the electrostatic torque minus the mechanical restoring torque provided by flexures 535, 535′) as a function of rotation angle (in degrees) under a constant applied voltage potential of 100V. Curve 1014 represents the results for blade actuator 211 depicted in FIG. 2A with a specified set of dimensions. Curve 1015 corresponds to blade actuator 511 as shown in FIG. 5A, having the same dimensions but with dotted first portion 1052 removed and structure 523 extended. The presence of the additional overlap area 1018 leads to an increased electrostatic force generated by blade actuator 511 throughout the entire range of motion.

### (b) Fine Torque Adjustment by Application of Different Electrical Voltages

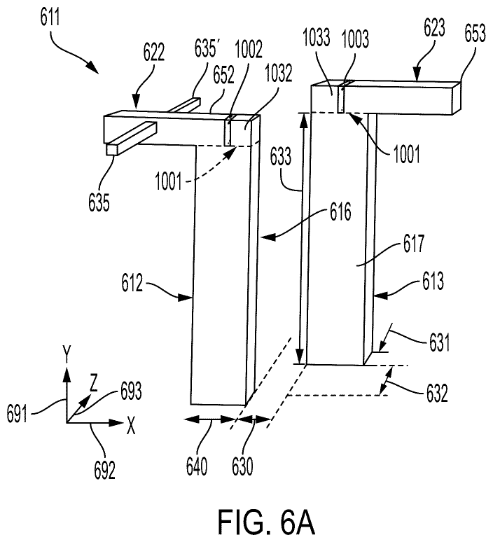

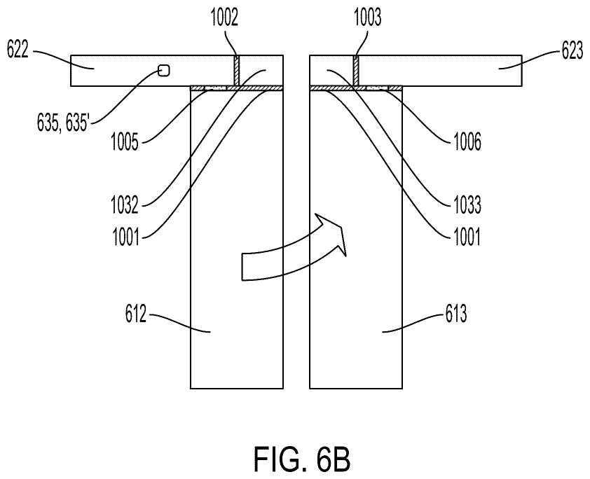

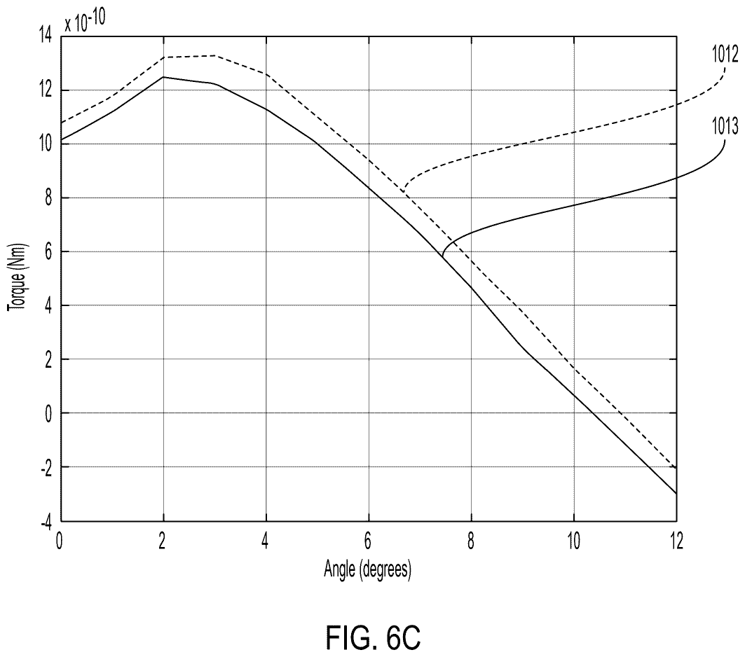

FIG. 6A shows a perspective view of a blade actuator 611 in accordance with some implementations of this disclosure.

Blade actuator 611 includes a blade 612, that is part of structure 622, to be actuated. In this example, structure 622 (also referred to as a first blade base) may be a segment of a stage (e.g., stage 140). As shown, in this example, a buried insulation layer 1001 (e.g., buried oxide layer) is disposed between blade 612 and structure 622. Similarly, buried insulation layer 1001 (e.g., buried oxide layer) is disposed between blade 613 and structure 623. In this example, buried insulation layer 1001 includes silicon dioxide. As depicted in FIG. 6A, a first portion 1032 of structure 622, a portion disposed on blade 612, is electrically isolated from the rest of structure 622 by isolation trench 1002 (and buried insulation layer 1001). Isolation trench 1002 may be an isolation trench described in U.S. Pat. No. 7,728,339. In this example, first portion 1032 of structure 622 has a cubic or rectangular prism shape.

Blade actuator 611 also includes blade 613, which is a part of structure 623. In this example, structure 623 (also referred to as a second blade base) may be a segment of a frame (e.g., frame 135). Buried insulation layer 1001 is disposed between blade 613 and structure 623. As described above, buried insulation layer 1001 may include silicon dioxide. As shown in FIG. 6A, a second portion 1033 of structure 623, a portion disposed on blade 613, is electrically isolated from the rest of structure 623 by isolation trench 1003 (and buried insulation layer 1001). Isolation trench 1003 may be an isolation trench described in U.S. Pat. No. 7,728,339. In this example, first portion 1032 and second portion 1033 are substantially the same size. In other examples, the dimension of first portion 1032 may be greater than the dimension of second portion 1033, or the dimension of second portion 1033 may be greater than the dimension of first portion 1032.

FIG. 6B shows a cross-sectional side view of blade actuator 611 in accordance with some implementations of the present disclosure.

In this example, a via 1005 (e.g., one or more conductive vias such as polysilicon vias) electrically connects structure 622 (e.g., silicon structure 622) to blade 612 (e.g., silicon blade 612) through buried insulation layer 1001. First portion 1032 of structure 622 is electrically isolated from the rest of structure 622 by isolation trench 1002 and electrically isolated from blade 612 by buried insulation layer 1001. A via 1006 (e.g., one or more conductive vias such as polysilicon vias) electrically connects structure 623 (e.g., silicon of structure 623) to blade 613 (e.g., silicon of blade 613) through buried insulation layer 1001. Second portion 1033 of structure 623 is electrically isolated from the rest of structure 623 by isolation trench 1003 and electrically isolated from blade 613 by buried insulation layer 1001.

As a voltage potential is applied between blades 612 and 613, blade 612 is moveably attracted toward blade 613 and structure 622 pivots about flexures 635, 635′.

FIG. 6C illustrates the results of a finite element analysis of the electrostatic behavior of the blade actuators 211, 611. The graph plots the torque sum (defined as the electrostatic torque minus the mechanical restoring torque provided by flexures 635 and 635′) as a function of rotation angle, in degrees, for a constant applied voltage potential of 100 V. Curve 1012 represents the performance of blade actuator 211 shown in FIG. 2A for a given set of dimensions. Curve 1012 reflects the angle of deflection (in degrees) resulting from torque (in Nm) for blade actuator 611, under the condition that the voltage applied to the first portion 1032 of structure 622 (as shown in FIG. 6A) is equal to the voltage applied to the rest of structure 622 and blade 612, and the voltage applied to the second portion 1033 of structure 623 is equal to the voltage applied to the rest of structure 623 and blade 613. Curve 1013 represents results for blade actuator 611 of FIG. 6A, with the same dimensions, under a different condition where the voltage applied to first portion 1032 of structure 622 equals the voltage applied to structure 623 (that is not second portion 1033) and blade 613, and the voltage applied to second portion 1033 of structure 623 equals the voltage applied to structure 622 (that is not first portion 1032) and blade 612. Curve 1013 shows a reduction in force compared to Curve 1012. These results demonstrate that the force or angle of the blade actuator can be tuned by adjusting applied voltages independently of the drive voltages supplied to blades 612 and 613, which may be advantageous for implementing fine angular corrections.

### (c) Torque Enhancement Through Material Mismatch

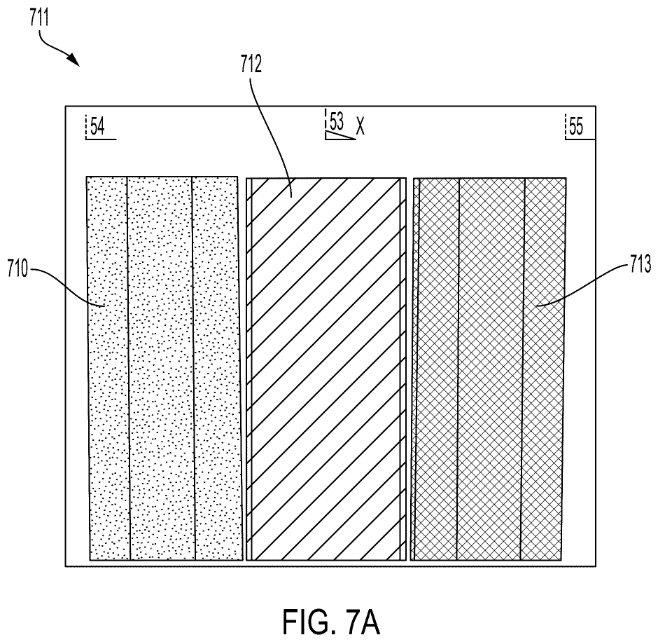

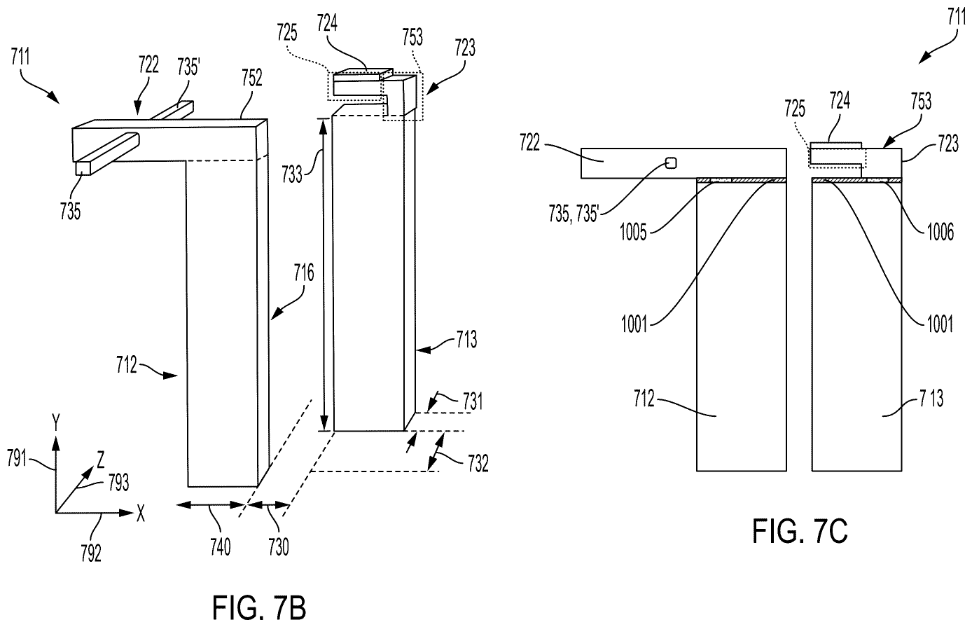

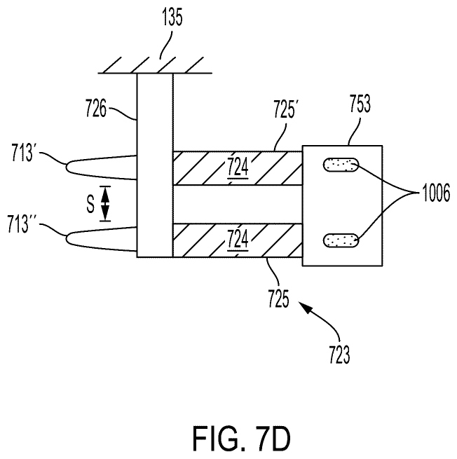

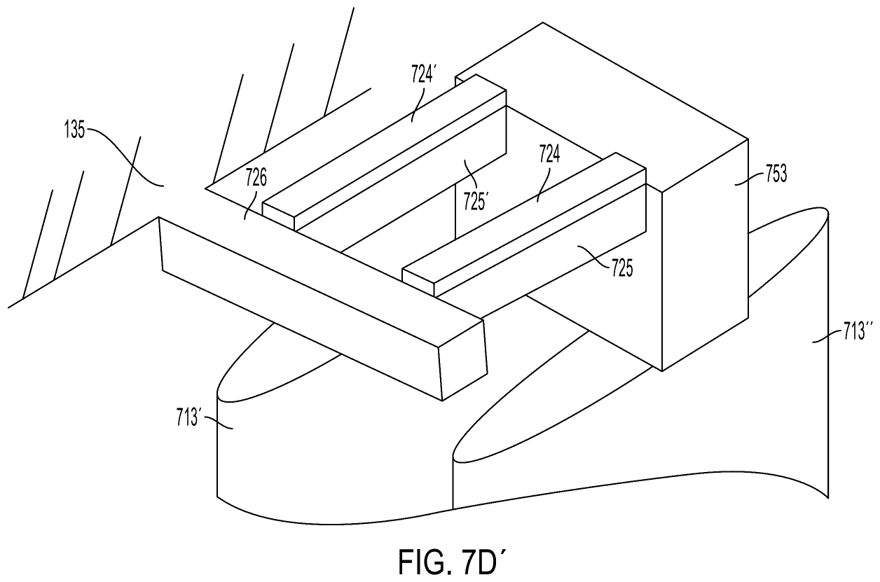

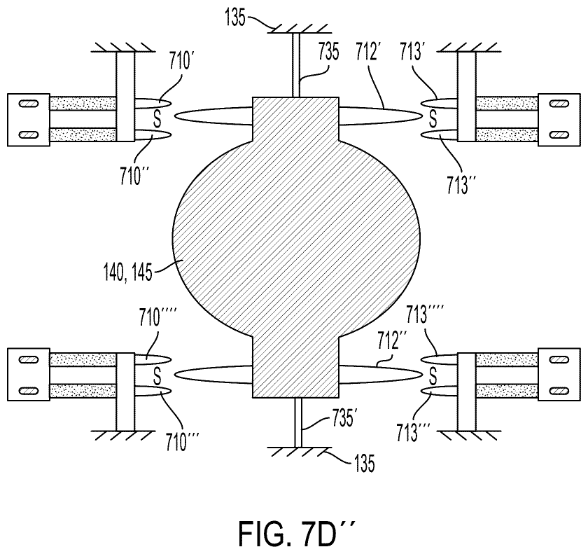

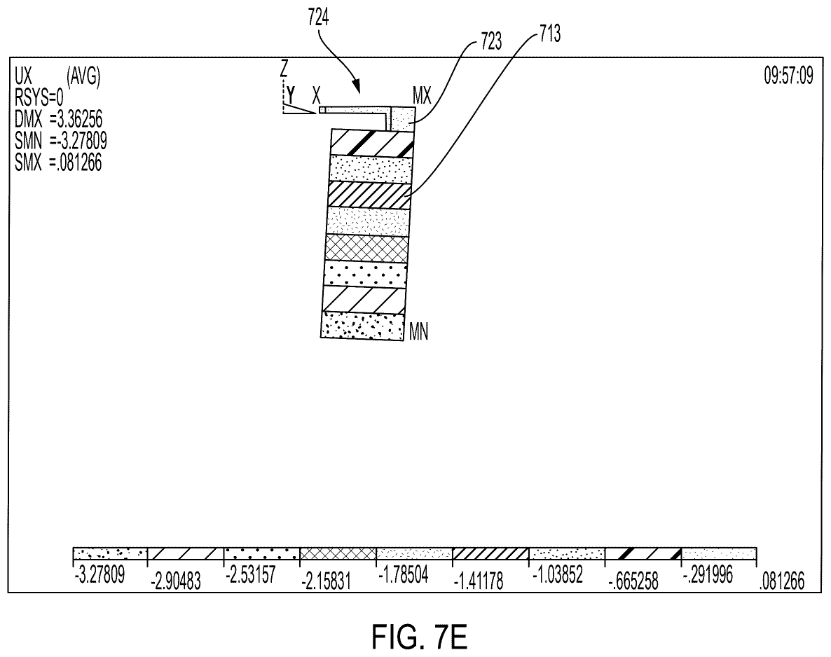

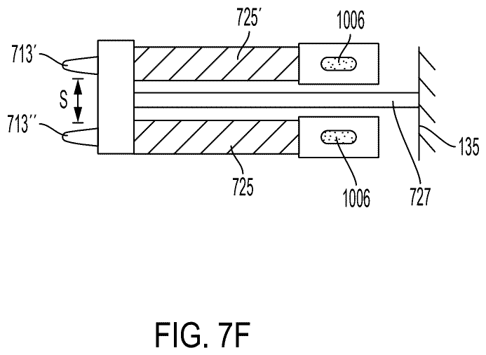

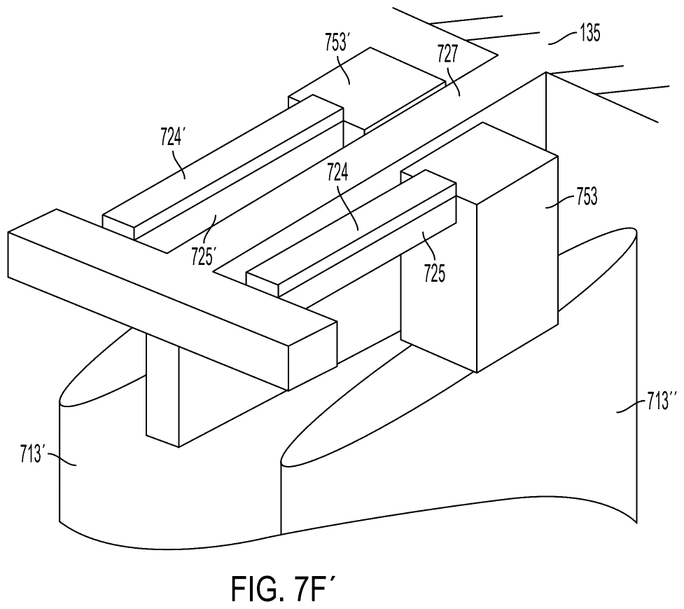

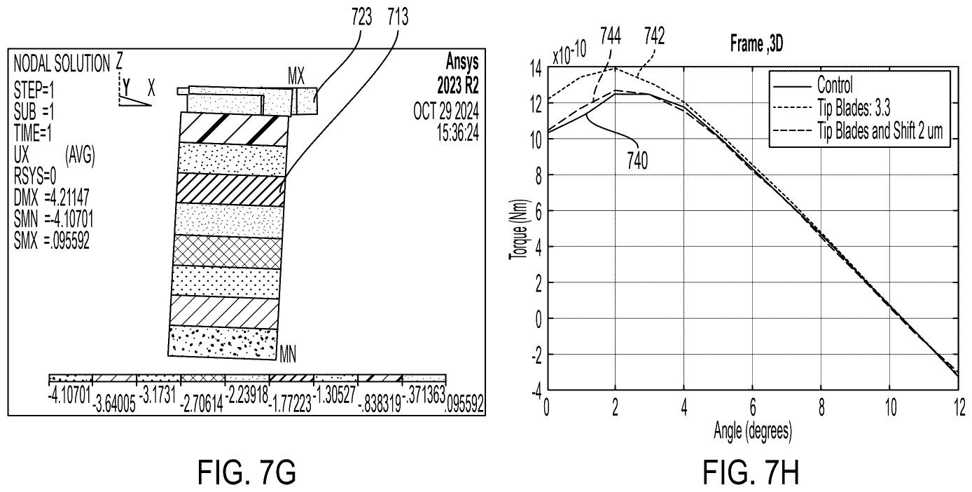

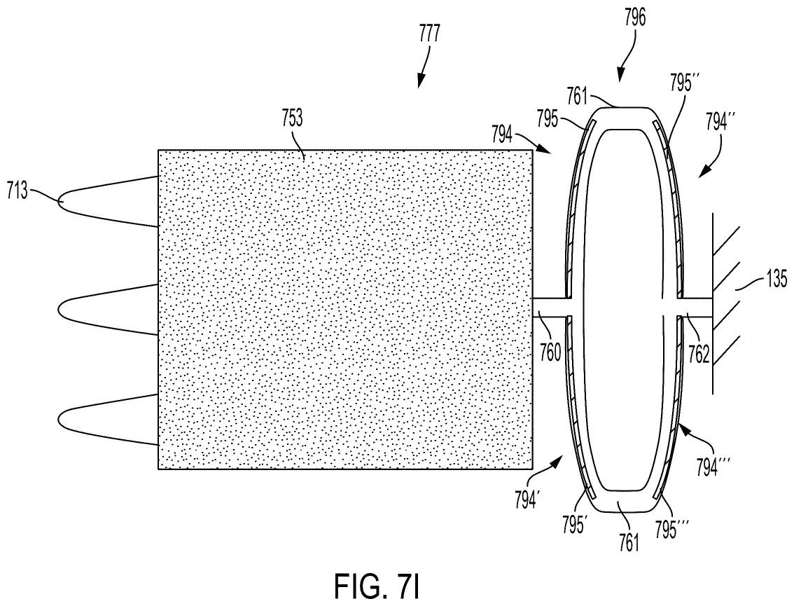

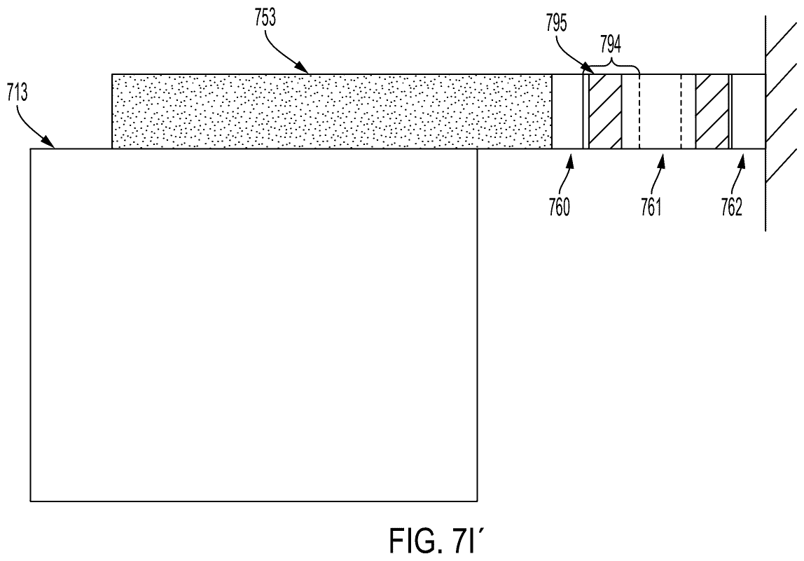

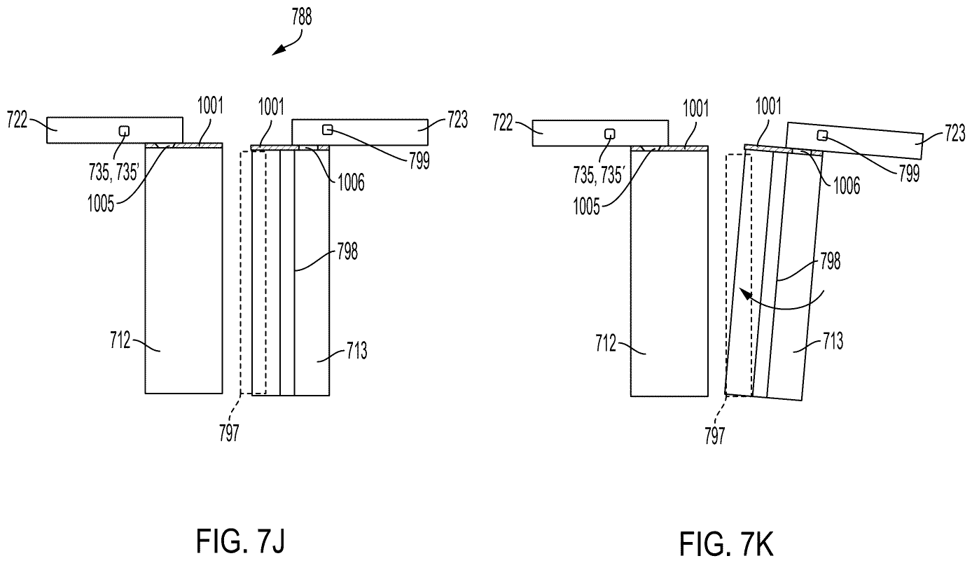

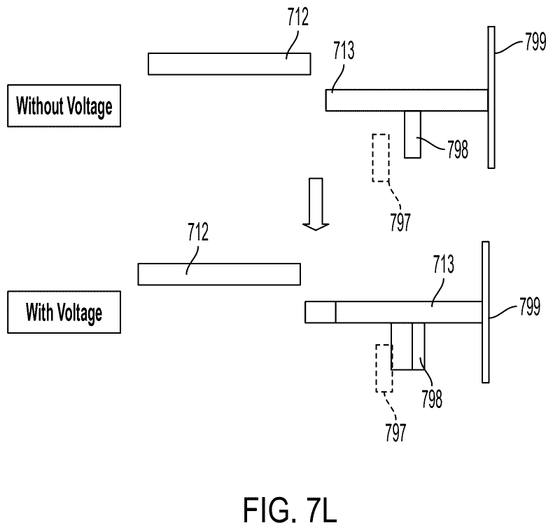

FIGS. 7A-7I′ illustrate a blade actuator 711 in accordance with some implementations of the disclosure.

The blade actuator 711 is configured to induce movement of the blades toward an engaged state, such as an overlapping arrangement, by utilizing a material mismatch that produces a tilt in the blades, thereby causing the blades to move into engagement or into closer proximity to engagement.

FIG. 7A shows blades 710, 712, 713 of blade actuator 711 in a thermal simulation.

Blade actuator 711 includes a first blade 710 (which is movable in relative to blade 712) and a second blade 713 (which is movable in relative to blade 712). Both first and second blades 710, 713 may be attached to a frame (e.g., frame 135 in FIG. 1A). Blade actuator 711 further includes blade 712 (which is movable in relative to blade 710 and blade 713). Blade 712 may be attached to a stage (e.g., stage 140 in FIG. 1A).

Unlike other examples described in the present disclosure, in this example, each of first blade 710 and second blade 713 is associated with at least one additional layer having a material different from that of the structure (e.g., structure 723) connecting the blade to the frame. In this example, at least one additional layer possesses a coefficient of thermal expansion that differs from that of the connecting structure (e.g., structure 723). As shown in FIGS. 7B-7C, at least one additional layer (e.g., silicon dioxide layer 724) is disposed on the structure (e.g., structure 723) that is between the frame and the structure. In this example, at least one additional layer is silicon dioxide layer 724.

The bimorph bending may arise from differences in the coefficients of thermal expansion, which generate stress as the material cools from the fabrication temperature, as well as from intrinsic stress variations introduced during the fabrication process.

As a consequence of these induced bimorph bendings, the tilting of blades 710 and 713 causes the respective gaps between these blades and blade 712 to change along their lengths. Specifically, gap 730 between blade 713 and blade 712 decreases progressively along the length of blade 713 toward the blade tips. Similarly, the gap between blade 710 and blade 712 decreases progressively along the length of blade 712, also narrowing toward the blade tips.

FIG. 7B is a perspective view of blade actuator 711, illustrating primarily blades 712 and 713 in accordance with some implementations of the present disclosure.

Blade actuator 711 includes blade 712, that is part of structure 722, to be actuated. In this example, structure 722 (also referred to as a first blade base) may be a segment of a stage (e.g., stage 140). Structure 722 may be constrained from vertical or lateral motion but remains free to pivot on flexures 735, 735′. Flexures 735, 735′ are rectangularly shaped. Alternatively, flexures 735, 735′ can be any other shape that provides rotational compliance and that can be fabricated with integrated circuit fabrication techniques, for example. The rotation of structure 722 allows for blade 712 to rotate within the X-Y plane (792, 791). By the design of flexures 735. 735′, the motion of blade 712 is constrained in the Z-direction 793 (into/out of the page).

Blade actuator 711 also includes blade 713 that is part of structure 723. In this example, structure 723 (also referred to as a second blade base) may be a segment of a frame (e.g., frame 135). For example, blade 713 corresponds to blade 125 of FIG. 1A and blade 712 corresponds to blade 120 of FIG. 1A. Blade 713 can, for example, be attached to frame 135. Given that blade 712 rotates within the X-Y plane 792, 791 relatives to blade 713, blade 712 is referred to as a movable blade and blade 713 is referred to as a fixed blade.

Unlike FIG. 2B, FIG. 7B illustrates the second blade 713 is configured with a layer of silicon dioxide 724 on top that induced a bimorph bending. As shown, silicon dioxide layer 724 is deposited on the top surface of lateral portion 725 (also referred to as thin portion) connected through vertical portion 753 (also referred to as thick portion) to blade 713. The width of the lateral portion 725 could be 7 μm (in the Y-direction 791) while the width of the thick portion could be 30 μm (in the Y-direction 791). Due to the mismatch of internal stress between the silicon dioxide layer 724 and the lateral portion 725 (e.g., a silicon lateral portion), bimorph bending occurs around the silicon dioxide layer 724 and lateral portion 725, causing the vertical portion 753 and second blade 713 to tilt. Lateral portion 725 may be a portion of a frame. Vertical portion 753 may be a portion of the frame. The difference in stress of silicon dioxide layer 724 and lateral portion 725 comes from intrinsic stress in the silicon dioxide layer 724 when fabricates as well as the differing coefficients of thermal expansion of the silicon dioxide and silicon. When the device cools from the fabrication temperature, the two materials would normally contract different amounts. Since they are affixed to one another, this also results in stress in the materials that produce the bimorph bending.

FIG. 7C is a cross-section view of the blade actuator 711 in accordance with some implementations of the disclosure.

In this example, a via 1005 (e.g., one or more conductive vias such as polysilicon vias) electrically connects structure 722 (e.g., silicon structure 722) to blade 712 (e.g., silicon blade 712) through buried insulation layer 1001. A via 1006 (e.g., one or more conductive vias such as polysilicon vias) electrically connects structure 723 (e.g., silicon structure 723) to blade 713 (e.g., silicon blade 713) through buried insulation layer 1001.

Silicon dioxide layer 724 may be positioned between the lateral portion 725 of structure 723 and a frame (e.g., frame 135). The length of the silicon dioxide layer 724 may be identical or substantially similar to the length of lateral portion 725 of structure 723. In some configurations, silicon dioxide layer 724 does not extend to or overlap with vertical portion 753 of structure 723 (along the Y-direction 791).

Unlike blade 212 and 213 in FIG. 2B, when there is no voltage potential (e.g., voltage difference) between blades 712 and 713, surface 752 of structure 722 may not be substantially parallel with surface 753 of structure 723. Instead, the bottom of blades 713 tilts in the X direction 792. Distance 730, which is at the bottom of the blades, can either be positive or negative, indicating the bottom portion blades 712 and 713 may overlap or non-overlap. When a voltage potential exists between blades 712, 713, blade 712 is moveably attracted toward blade 713, and structure 722 pivots about flexures 735, 735′. The greater the height 733 of the blades 712 and 713, the greater the torque that is generated on structure 722. The generation of a greater torque decreases the amount of voltage potential required to pivot the structure 722. Because structure 722 (to which blade 712 is coupled) is constrained to pivot on flexures 735, 735′, blade 712 is operable to move in X-direction 792 and Y-direction 791 toward blade 713 until blades 712 and 713 overlap (e.g., surface areas of blades 712 and 713 overlap), similar to blade 212 and blade 213 in FIG. 2B.

Upon application of a voltage potential between blades 712 and 713, blade 712 is electrostatically attracted toward blade 713, thereby causing structure 722 to pivot about flexures 735 and 735′. Due to the bimorph bend effect either bringing the blades closer together or increasing overlap, under an equivalent applied voltage potential, blade 712 may be drawn toward blade 713 at a greater torque.

FIG. 7D shows a top view of an example structure 723 and blade 713 configuration in accordance with some implementations of the present disclosure. FIG. 7D′ show a perspective view of an example structure 723 and blade 713 configuration in accordance with some implementations of the present disclosure.

The configuration shown in FIG. 7D includes a pair of blades 713′, 713″ mounted to a single vertical portion 753 connected by two lateral portions 725, 725′ of structure 723 to another lateral portion 726 which is mounted structure 723 (asymmetrically) to a frame (e.g., frame 135).

Space S between blades 713′ and 713″ is allocated for blade 712. Upon application of a voltage potential between blade 712 and the pair of blades 713′, 713″, blade 712 pivots toward space S between the pair, overlapping with blades 713′ and 713″ without making direct contact.

In this example, silicon dioxide layer 724 (or a layer having a different material) may be disposed on lateral portions 725,725′ which are between lateral portion 726 and vertical portion 753.

FIG. 7D″ illustrates a top view of an example implementing of the asymmetric mount configuration shown in FIG. 7D, in accordance with some implementations of the present disclosure.

As illustrated, flexures 735 and 735′ suspend stage 140 within a cavity defined by frame 135. Stage 140 includes a surface on which a reflective element 145 is disposed. First blade 712′, positioned adjacent to flexure 735, and second blade 712″, positioned adjacent to flexure 735′, extend substantially perpendicularly from stage 140. Blades 712′ and 712″ are arranged parallel to one another.

As illustrated, a first pair of blades 713′, 713″ is arranged such that, when a voltage potential is applied to both the first pair of blades 713′, 713″ and the first blade 712′ (e.g., applying a first voltage to first pair of blades 713′, 713″ and a second voltage to first blade 712′), first blade 712′ pivots toward the space S defined between the first pair of blades 713′ and 713″.

As shown, a second pair of blades 713′″, 713″″ is arranged such that, upon application of a voltage potential to both the second pair of blades 713′″, 713″″ and the second blade 712″ (e.g., applying a first voltage to second pair of blades 713′″, 713″″ and a second voltage to second blade 712″), the second blade 712″ pivots toward the space S defined between the second pair of blades 713′ and 713″.

As shown, in this example, the second pair of blades 713′″, 713″″ is a mirror image of the first pair of blades 713′, 713″.

As illustrated, a third pair of blades 710′, 710″ is arranged such that, when a voltage potential is applied to both the third pair of blades 710′, 710″ and first blade 712′ (e.g., applying a first voltage to third pair of blades 710′, 710″ and a second voltage to first blade 712′), first blade 712′ pivots toward space S defined between the third pair of blades 710′ and 710″.

As shown, in this example, the third pair of blades 710′, 710″ is a mirror image of the first pair of blades 713′, 713″.

As shown, a fourth pair of blades 710′″, 710″″ is arranged such that, upon application of a voltage potential to both the fourth pair of blades 710′″, 710″″ and the second blade 712″ (e.g., applying a first voltage to fourth pair of blades 710′″, 710″″ and a second voltage to second blade 712″), second blade 712″ pivots toward space S defined between the fourth pair of blades 710′″ and 710″″.

As shown, in this example, the fourth pair of blades 710′″, 710″″ is a mirror image of the second pair of blades 713′″, 713″″.

In some implementations, the same voltage difference is applied between first blade 712′ and the first pair of blades 713′, 713″, as well as between the second blade 712″ and the second pair of blades 713′, 713″, thereby imparting a rotation or tilt to reflective element 145 in one direction.

In some implementations, the same voltage difference is applied between the first blade 712′ and the third pair of blades 710′, 710″, as well as between the second blade 712″ and the fourth pair of blades 710′″, 710″″, resulting in rotation or tilt of reflective element 145 in the opposite direction.

In some implementations, first blade 712′ may include two first blades 712′ similar to blade 121 and blade 120 in FIG. 1A. In some implementations, second blade 712′ may include two second blades 712′ similar to blade 121 and blade 120 in FIG. 1A.

FIG. 7E shows blade 713 and structure 723 associated with blade 713 during a thermal simulation. In this example, adding one or more layers—such as silicon oxide layer 724 in FIG. 7C—with a material different from associated structure 723, and placing the one or more layers between structure 723 and frame where the structure 723 is attached to, causes the tip of blade 713 to tilt in one direction (leftward direction in this example) when a an internal stress is applied to silicon oxide layer 724. The stress value is based on the difference of silicon and silicon oxide coefficient of thermal expansions and the assumptions that the system is stress free at the temperature of silicon oxide growth, approximately 1000° C., and the modeled state is room temperature, approximately 25° C. As a result, blade 713 inclines toward blade 712, bringing their tips close together or even overlapping. This arrangement increases the net torque (the electrostatic torque minus the mechanical restoring torque from flexures 735 and 735′) in the initial angular range of 0 to 5 degrees, compared to blade 213 in FIG. 2A, which does not move.

FIG. 7F shows a top view of an example configuration featuring structure 723 and blade 713, according to some implementations of this disclosure. FIG. 7F′ shows a perspective view of an example configuration featuring structure 723 and blade 713, according to some implementations of this disclosure.

In this example, rather than using second lateral portion 726 to mount structure 723 asymmetrically to the frame (such as frame 135) as shown in FIG. 7D, the second vertical portion 727 mounts the blades symmetrically to the frame. This approach not only establishes a symmetric mount for blades 713′ and 713″, but also allows a larger layer having the different material—such as silicon dioxide on layer 724—on the lateral portion (e.g., lateral portion 725, lateral portion 725′), resulting in increased deflection.

FIG. 7G depicts blade 713 and structure 723 associated with blade 713 during a thermal simulation. The presence of a layer having a different material—such as silicon dioxide on layer 724—positioned on structure 723 causes the tip of blade 713 to tilt leftward. Consequently, the tip of the second blade 713 moves 4 μm closer to blade 712, nearing engagement or overlap, in contrast to blade 213 in FIG. 2A.

FIG. 7H shows the results of a finite element analysis of the electrostatics of the blade actuators in different configurations. The graph shows the torque sum (defined as the electrostatic torque minus mechanical restoring torque provided by flexures 735, 735′) as a function of rotation angle (in degrees) for a constant applied voltage potential of 100V. Curve 740 shows the results for the blade actuator 211 shown in FIG. 2A. Curve 742 shows the results for the blade actuator shown in FIG. 7G. As shown, for the initial 0-5 degrees, the blade actuator 711 provides a higher torque since the tip of blade 713 is closer to blade 712. Curve 744 shows the results for the blade actuator 711 shown in FIG. 7E, with a gap that is 2 μm wider than the gap in FIG. 2A. Even with the wider gap, the torque sum of the blade actuator 711 is similar to that of the blade actuator 211. In other words, by implementing tip tilting, the etch lag issue during the manufacturing of the blade actuator can be resolved by adjusting the gap (e.g., widening the gap by 2 μm) without affecting the performance of the blade actuator.

FIG. 7I is a top view of blade actuator 777, according to some implementations of the disclosure. FIG. 7I′ is a side view of blade actuator 777, according to some implementations of the disclosure.

Blade actuator 777 comprises at least one blade 713 (three blades 713 are shown in this example), a support member 753, and a connection body 796. In the depicted example, three blades 713 are secured to a lower surface of support member 753, with each blade 713 arranged in parallel with the others.

Connection body 796 is positioned between support member 753 and a frame (for example, frame 135). As depicted, connection body 796 is connected to support member 753 by a first connector 760 disposed on a first side of connection body 796, and to the frame by a second connector 762 disposed on a second side that is an opposite side of the first side. In this example, first connector 760 and second connector 762 each comprise silicon. In this example, connection body 796 is generally circular, oval, or rectangular in shape with an opening at the center. As a result, connection body 796 has a ring shape.

As shown, in this example, connection body 796 includes a plurality of ribs 794-794′″(portions of ring shaped connection body 796) and additional connections 761 (upper connection 761 and lower connection 761 in this example). Each rib 794-794′″ includes a silicon oxide trench 795-795′″. Silicon oxide trenches 795-795′″ are similar in composition and fabrication to 1002,1003 in FIG. 6B, but differ in purpose. Where as 1002,1003 are used for electrical isolation of neighboring portions of silicon, these silicon oxide trenches 795-795′″ are used for bimorph bending. Two silicon oxide trenches 795,795′ adjacent to support member 753 face support member 753 and two silicon oxide trenches 795′,795′″ adjacent to the frame face the frame.

As shown, first connector 760 is disposed between rib 794 and rib 794′. Likewise, second connector 762 is disposed between rib 794″ and rib 794′″.

Each of ribs 794′-794′″(four ribs in this example) includes a material that differs from a remainder of connection body 796. This material can be silicon oxide and it forms silicon oxide trenches 795-795′″. In this example, the height of silicon oxide trenches 795-795′″ is substantially equal to the height of the ribs 794-794′″ and the height of the remainder of connection body 796. Owing to the mismatch of coefficients of thermal expansion between the silicon oxide and the silicon as well as intrinsic stress of the silicon oxide when fabricated, bimorph bending is induced and support member 753 and blades 713 are brought into enhanced engagement with one or more blades attached to stage.

### (d) Torque Enhancement Through Voltage Actuation of Fixed Blade

FIG. 7J illustrates a blade actuator 788, according to some implementations of the disclosure.

The blade actuator 788 is configured to facilitate increased engagement—such as overlapping or near-overlapping of blades—by enabling blade 713 to move into close proximity with blade 712 during operation. In other examples described herein, the movement of blade 713 relative to blade 712 (which is directly coupled to a stage) is typically restricted or fixed. In the example presented in FIG. 7J, blade 713 is connected to structure 723, which is in turn secured to a frame (e.g., a fixed silicon edge) via flexure 799. Flexure 799 is compliant silicon flexures in this example. Application of a voltage differential between blades 712 and 713 generates an electrostatic attraction that induces rotation of structure 723 and blade 713 about flexures 799 in the direction toward blade 712.

In this example, structure 722 (also referred to as a first blade base) may be a segment of a stage (e.g., stage 140). In this example, structure 723 (also referred to as a second blade base) may be a segment of a frame (e.g., frame 135).

In this example, to regulate the movement of blade 713, blade 713 is provided with an elongated protrusion 798 (also referred to as an orthogonal blade member or bar) on its side. In the illustrated example, blade 713 and protrusion 798 are oriented at a right angle to one another.

As further shown, stopper 797 (also referred to as a stopper blade or fixed location blade) is disposed parallel to the elongated protrusion 798. The greater the distance between stopper 797 and elongated protrusion 798, the closer blade 713 can move (e.g., rotate or pivot) toward blade 712. Conversely, when the distance between stopper 797 and protrusion 798 is less, the movement of blade 713 toward blade 712 is more limited.

FIG. 7K illustrates the state of the blades of FIG. 7J upon application of a voltage differential between blades 712 and 713. Structure 723 and blade 713 rotate about flexure 799 until elongated protrusion 798 contacts stopper 797. In this example, flexure 799 is highly compliant in torsion yet stiff in bending, ensuring that the upper portion of blade 713 experiences minimal displacement as voltage increases. The translational stiffness of flexure 799 and the presence of stopper 797 maintain structure 723 and blade 713 in a fixed position. Accordingly, blade 713 is brought into increased engagement with moving blade 712.

FIG. 7L is a top view illustrating the configurations of FIGS. 7J and 7K, according to some implementations of the disclosure.

As depicted, when no voltage differential is applied between blades 712 and 713, stopper 797 and protrusion 798 are spaced apart from each other. Upon application of a voltage differential, blade 713 rotates toward blade 712 such that protrusion 798 moves into proximity with stopper 797. Rotation of blade 713 ceases when protrusion 798 physically contacts stopper 797.

### (e) Torque Optimization Through Rotational Comb Fingers

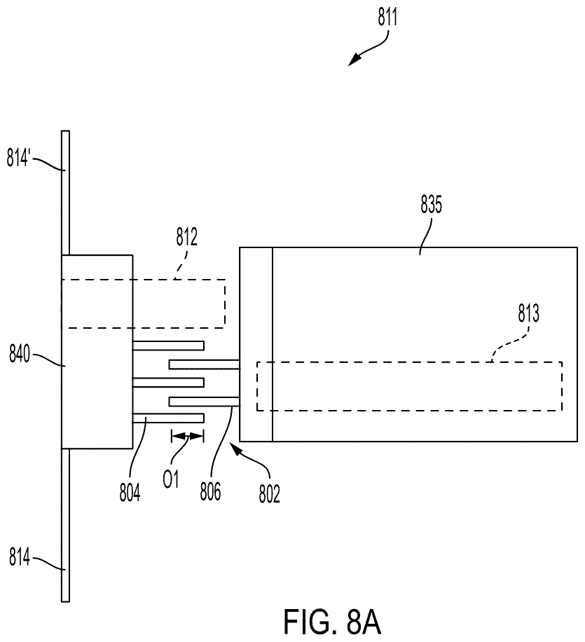

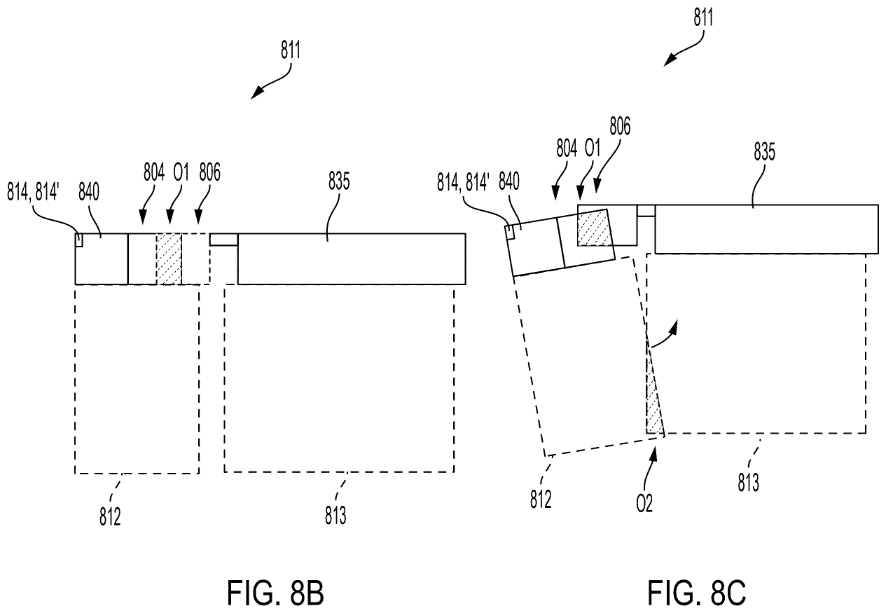

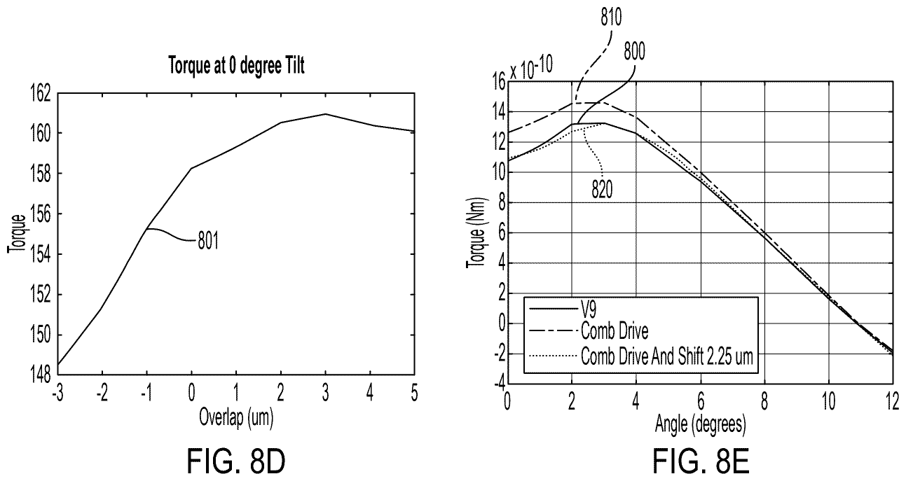

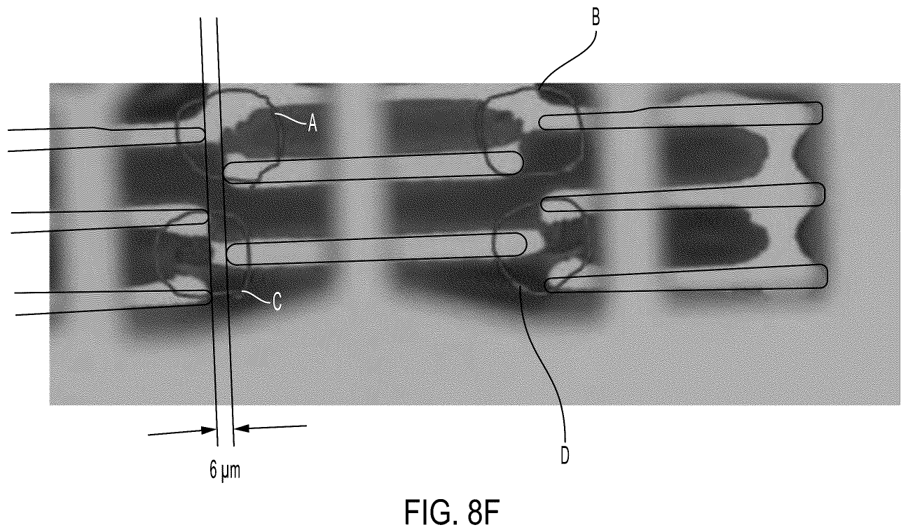

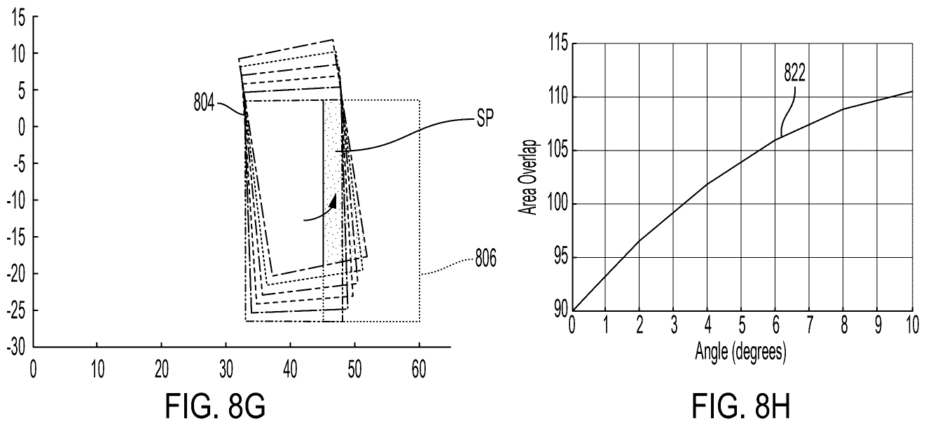

FIGS. 8A-8G illustrate a blade actuator 811 incorporating an overlapping comb finger arrangement 802 according to some implementations of the present disclosure.

In this example, blade actuator 811 includes blade actuator 211 in FIG. 2A configured with comb finger arrangement 802.

In this example, overlapping comb finger arrangement 802 includes a plurality of first fingers 804 coupled to a stage 840 (e.g., stage 140) and a plurality of second fingers 806 coupled to a frame 835 (e.g., frame 135). First fingers 804 and second fingers 806 are positioned such that first fingers 804 and second fingers 806 overlap with each other. In this example, first and second flexures 814, 814′ (e.g., flexures 235, 235′) suspend the stage 840 within a cavity defined by frame 835.

In the illustrated configuration in FIG. 8A-8C, first fingers 804 extend from stage 840 toward frame 835, and the second fingers 806 extend from frame 835 toward stage 840. As shown, a tip of second finger of the plurality of second fingers 806 is positioned between two tips of two adjacent first fingers of the plurality of first fingers 804, and a tip of first finger of the plurality of first fingers 804 is positioned between two tips of two adjacent second fingers of the plurality of second fingers 806. This arrangement (e.g., interleaved configuration), when implemented in blade actuator 211, enhances torque of moving blade 812 (212) in operation.

In some examples, blade actuator 811 comprises a single first finger 804, wherein the tip of first finger 804 overlaps with either the tip of second finger 806 or with the tips of a plurality of second fingers 806. In other examples, blade actuator 811 comprises a single second finger 806, wherein the tip of second finger 806 overlaps with either the tip of a first finger 804 or with the tips of a plurality of first fingers 804.

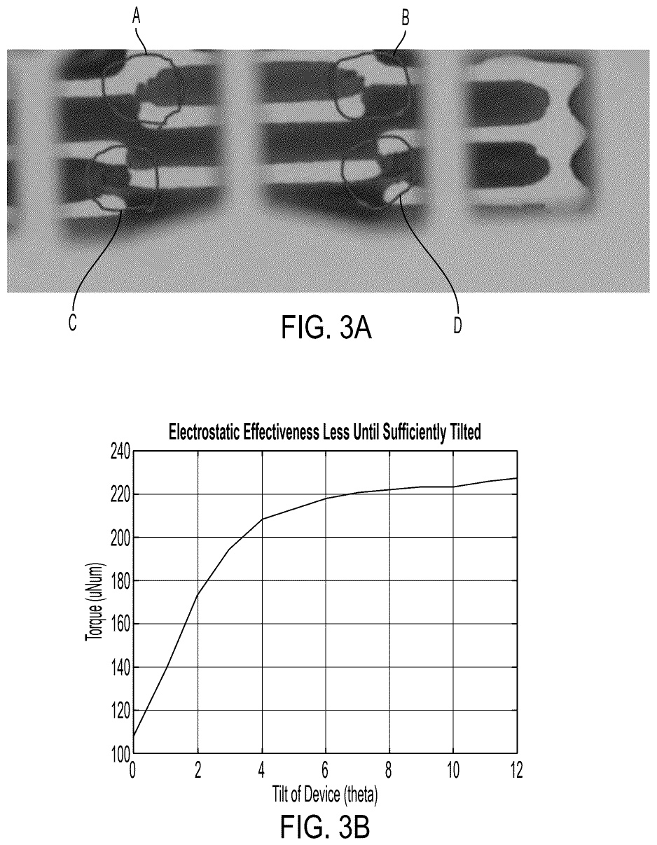

As a result of this configuration, blade actuator 811 can accommodate larger gaps between blades 812 (movable blade 212) and 813 (fixed blade 213) without adversely affecting blade performance (e.g., torque generation). Increasing the permissible blade gap improves manufacturing yield of blade actuators by reducing sensitivity to fabrication defects as shown in FIG. 3A.

FIG. 8A shows a simplified partial top view overlapping comb finger arrangement 802 in blade actuator 811 in accordance with some implementations of the disclosure.

In contrast to other blade arrangements disclosed herein, which remain non-overlapping prior to the application of differing voltage potentials to the movable and fixed blades, first fingers 804 and second fingers 806 in arrangement 802 are configured to overlap before any tilting, rotation, or pivoting of the movable blade 812 (movable blade 212) occurs. This initial overlap O1 produces electrostatic torque that enhances the torque available for blade movement.

Electrostatic attraction generated by the overlap O1 between first fingers 804 and second fingers 806 assists in the initial movement of blade 812, thereby facilitating tilting of stage 840 (e.g., stage 140). First fingers 804 and second fingers 806 overlap by a distance of overlap O1.

FIG. 8B presents a simplified partial side view of blade actuator 811 before the movement of movable blade 812, and FIG. 8D shows the same view with blade actuator 811 in motion.

As shown, movable blade 812 extends from stage 840 and fixed blade 813 extends from frame 835. Prior to movement of blade 812 toward blade 813, blade 812 and blade 813 are substantially in parallel.

In FIGS. 8B and 8C, overlap area O1 is defined by the interleaving of first fingers 804 with second fingers 806. In FIG. 8C, overlap area O2 is defined by overlapping region between blade 812 and blade 813 under the application of voltage potential to the movable and fixed blades 812, 813. As shown, blade 812 tilts as blade 812 is attracted to blade 813. As a result, overlap area O1 becomes greater and overlap area O2 is defined by overlapping region between blade 812 and blade 813. As blade 812 tilts towards blade 813, overlap area O2 also becomes greater.

FIG. 8D illustrates a graph of torque (μN·μm, without initial tilt) versus finger overlap distance O1. Curve 801 shows that the maximum torque occurs when the overlap distance O1 between first fingers 804 and second fingers 806 is approximately 3 μm, prior to movement of movable blade 812.

FIG. 8E presents results of a finite element electrostatic analysis of different blade actuators.

The data shows torque sum (electrostatic torque minus mechanical restoring torque from flexures) versus rotation angle, under a constant voltage potential of 100 V. Curve 800 corresponds to a blade actuator 211 from FIG. 2A without overlapping comb finger arrangement 802. Curve 810 corresponds to actuator 211 with overlapping comb finger arrangement 802 (overlap distance O1=3 μm). This configuration yields higher torque in the 0°-5° range due to increased electrostatic effectiveness. Curve 820 corresponds to the same overlapping comb finger configuration corresponding to curve 802 but with a blade gap increased by 2.25 μm relative to FIG. 2A. Even with the increased gap, torque performance remains comparable to the original design, demonstrating that the overlapping comb finger arrangement permits gap widening to mitigate etch lag manufacturing issues without sacrificing performance (e.g., torque performance).

FIG. 8F illustrates a gap comparison demonstrating the condition when the blade gap reaches 6 μm. As discussed, the greater the blade gap, it is easier to fabricate or produce the blade actuator.

FIG. 8G depicts comb finger rotation about the (0,0) origin rather than around the center of the comb fingers 804, 806. In the example shown, the comb fingers rotate about the center of a 7 μm deep spring, while the comb fingers 804, 806 themselves are 30 μm in height. The shaded polygon SP illustrates an overlapping area at 10° deflection. Traditionally, comb fingers 804, 806 that completely overlap in the direction of motion cannot generate rotational torque if fabricated from the same silicon layer unless they are laterally displaced. In the present implementation, the comb fingers overlap in the Y-direction (FIG. 8G) and rotate about an off-center axis. When the rotation center is shifted from the geometric center of the fingers (e.g., from (0, −11.5) in FIG. 8G), the overlap area changes with tilt direction, enabling generation of force. This feature allows the comb fingers to be fabricated in the same silicon layer while producing rotational torque.

As illustrated, in this example, the top surface of the first finger 804 is positioned higher than the top surface of the second fingers 806 as the blade 812, which is associated with the first fingers 804, becomes increasingly tilted.

FIG. 8H illustrates a curve 822 that shows the relationship between overlap area and tilt angle. Electrostatic torque is proportional to the slope of this curve. The slope decreases as tilt angle increases, showing that maximum torque is generated at 0°. This configuration delivers additional torque at small deflection angles, where it is most beneficial for blade motion.

The overlapping comb finger arrangement permits widening of the inter-blade gap to improve manufacturability and reduce etch defects, thereby increasing yield. Additionally, due to improved electrostatic coupling, the blade actuator can operate at reduced voltage for small deflections without loss of torque.

The benefits of blade actuators 511 and 811 can be combined when the first finger and last finger of second fingers 806 are on the outside of first and last finger of first fingers 804. The last finger of 806, which is now next to moving blade 812 acts similarly to the protrusion of 523 next to moving blade 512. This has the primary electrostatic torque of blades 812 and 813, the supplemental torque from first fingers 804 and second 806 and now the supplemental torque from outer fingers of second fingers 806 and moving blade 812.

### (f) Torque Enhancement by Base Bonded Blade

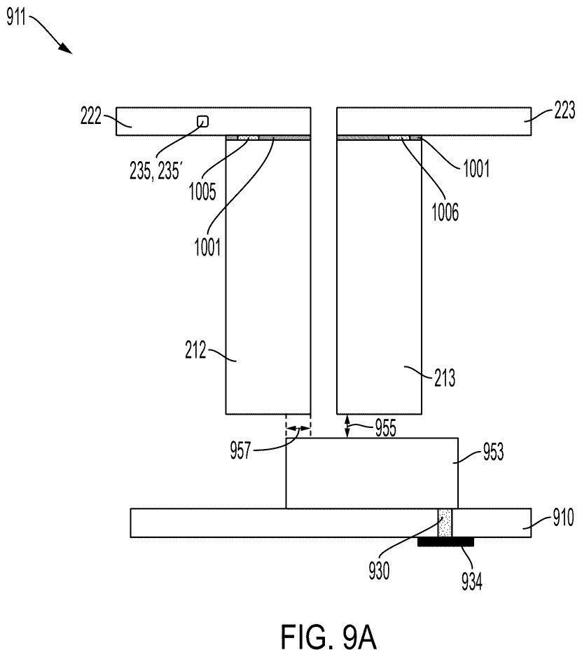

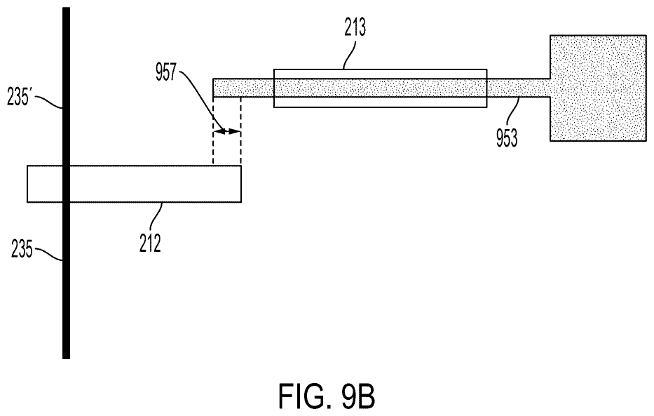

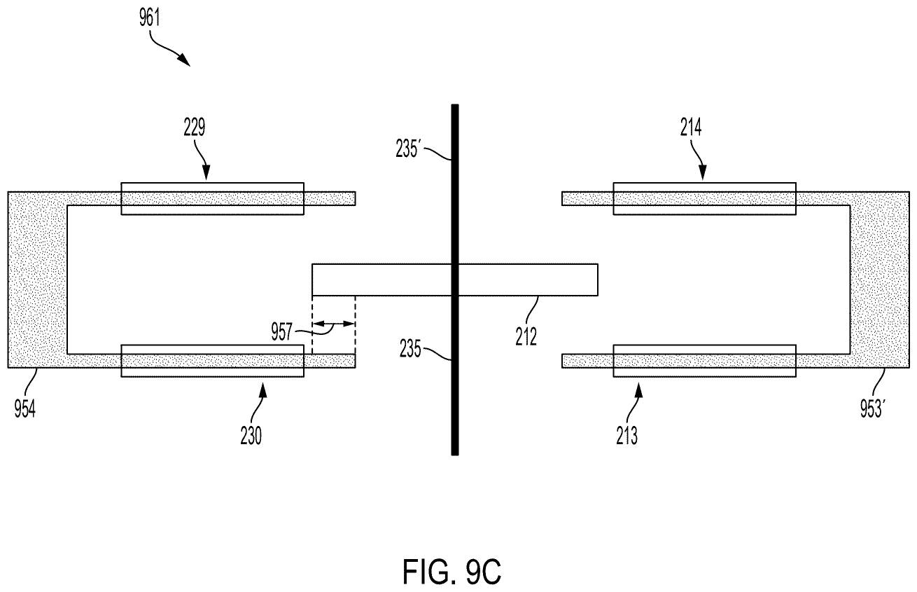

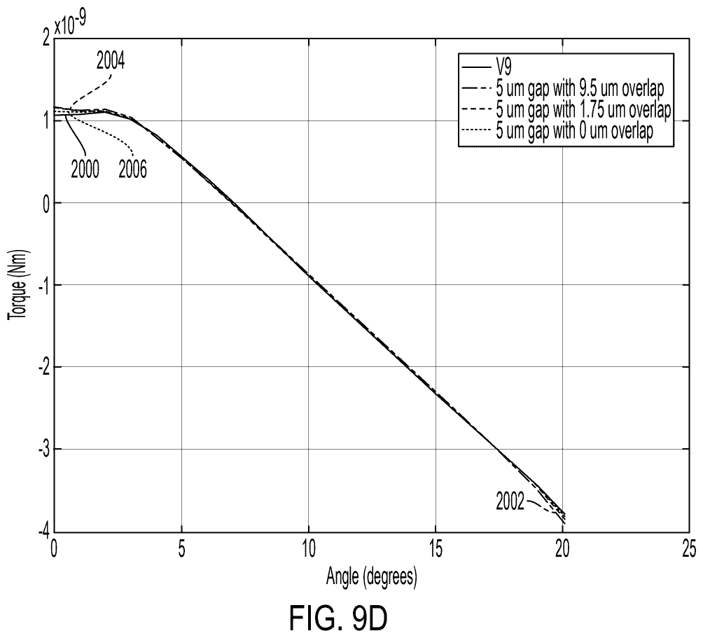

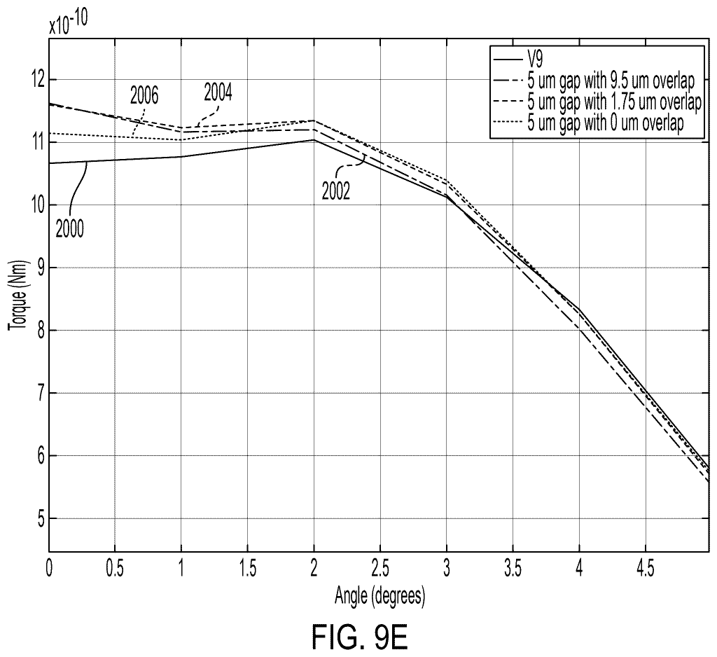

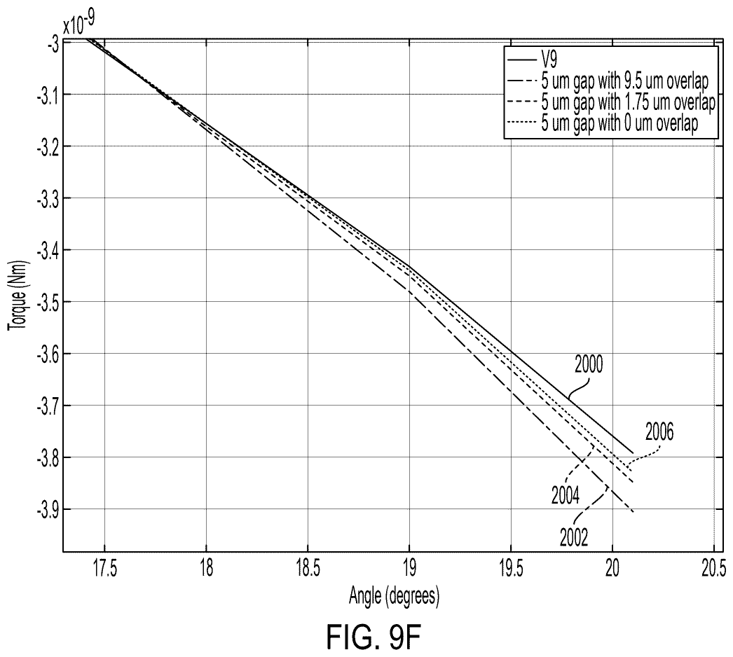

FIG. 9A illustrates a cross-sectional side view of blade actuator 911, configured with blade actuator 211′ (similar to blade actuator 211 depicted in FIG. 2A but configured with vias 1005, 1006 and buried insulation layer 1001) and base blade 953 which enhances rotational actuation of blade actuator 211′ in accordance with some implementations of the present disclosure.

As shown, blade actuator 211′ includes blade 212 which is part of structure 222 and is arranged for rotational actuation (e.g., pivotal actuation) about flexures 235, 235′. In this example, a buried insulation layer 1001 (e.g., buried oxide layer) is disposed between blade 212 and structure 222. In this example, buried insulation layer 1001, between blade 212 and structure 222, includes silicon dioxide.

Blade actuator 211′ includes blade 213, which is part of structure 223. Buried insulation layer 1001 is disposed between blade 213 and structure 223. In this example, buried insulation layer 1001, between blade 213 and structure 223, includes silicon dioxide.

In this example, structure 222 (also referred to as a first blade base) may be a segment of a stage (e.g., stage 140). In this example, structure 223 (also referred to as a second blade base) may be a segment of a frame (e.g., frame 135).

As shown, blade actuator 911 includes a base blade 953. Base blade 953 may be fabricated on a separate wafer 910 (e.g., a substrate). In a side-view perspective, the base blade 953 is positioned beneath blade 213, which is fixed relative to blade 212, and is separated from blade 213 by a gap 955. In this example, the side-view perspective also illustrates that base blade 953 lies beneath a portion of blade 212, which is movable relative to blade 213. Gap 955 may range from approximately 5 μm to approximately 15 μm.

As shown in this example, in the side-view perspective, base blade 953 extends toward blade 212 such that an edge portion of base blade 953 is positioned near an edge portion of blade 212. As a result, the edge of base blade 953 may overlap (e.g., obliquely overlap) the edge of blade 212. In this example, the overlapping width 957 between blade 212 and base blade 953 (measured in the side-view perspective) ranges from approximately 0 μm to approximately 15 μm. Even when the overlapping width 957 is 0, the edge of base blade 953 remains adjacent to the blade 212. Accordingly, during operation, the blade 212 is attracted toward base blade 953. Furthermore, in this example, the side-view perspective shows that a portion of base blade 953 extends beyond an edge of blade 213 (edge on the right side of blade 213 in this example).

In this example, via 1005 (e.g., one or more polysilicon vias) electrically connects structure 222 (e.g., silicon of structure 222) to blade 212 (e.g., silicon of movable blade 212) through buried insulation layer 1001. Similarly, via 1006 (e.g., one or more polysilicon vias) electrically connects structure 223 (e.g., silicon of structure 223) to blade 213 through the buried insulation layer 1001. In addition, via 906 (e.g., a silicon via) formed through wafer 910 connects base blade 953 (bottom side of base blade 953 in this example) to contact pad 934, which is disposed on the bottom side of wafer 910. Applying an electrical voltage to contact pad 934 allows a corresponding voltage to be applied to the base blade 953.

FIG. 9B illustrates a top view of blade 212, blade 213, and base blade 953 as arranged in FIG. 9A. Base blade 953 is disposed beneath blade 213. As shown in this example, from the top-view perspective, base blade 953 overlaps with blade 212. In this configuration, the width of a first portion of base blade 953 that overlaps with blade 213 is narrower than the width of blade 213 at the region of overlap. This arrangement provides a margin to accommodate potential misalignment between base wafer 910 and the device wafer (e.g., a device substrate that includes blade actuator 211′). In another example, at least part of the first portion of base blade 953 and blade 213 may instead have a substantially identical width.

In operation, when a voltage potential V1 is applied between blades 212 and 213, blade 212 is electrostatically attracted toward blade 213, causing structure 222 to pivot about flexures 235 and 235′. Similarly, when a voltage potential V2 is applied between blade 212 and base blade 953, blade 212 is attracted toward the base blade 953, resulting in additional pivoting of structure 222 about flexures 235 and 235′. A large-angle displacement of blade actuator 211 can be achieved when V1 and V2 are applied simultaneously with equal magnitudes. Independent adjustment of V2 relative to V1, or V1 relative to V2, allows precise control of the angular positioning of blade 212.

The sequence of voltage application between V1 and V2 may also vary. For example, voltage potential V2 may be applied between blade 212 and base blade 953 either prior to or during the application of voltage potential V1 between blade 212 and blade 213. Due to the initial overlap 957 between base blade 953 and blade 212, this sequencing can facilitate the initiation of blade motion.

FIG. 9C shows a top view of another example of blade actuator 961, featuring an additional fixed blade 214 as illustrated in FIG. 2D, along with a base blade 953′ that overlaps with both blades 213 and 214. This configuration increases the electrostatic attraction exerted on blade 912 and thereby lowers the actuation voltage (e.g., voltage potential) needed. In this case, base blade 953′ is designed as a U-shaped structure. The first portion of base blade 953′ overlaps with blade 213, while the second portion overlaps with blade 214. Both the first and second ends of base blade 953′ obliquely overlap with an edge portion of the blade 212.

Additionally, blade actuator 961 includes blade 229 shown in FIG. 2E and blade 230, as well as a U-shaped base blade 954, enabling bidirectional movement of blade 212. In this configuration, blades 229 and 230, along with the U-shaped base blade 954, are arranged as the mirror counterpart of blades 213, 214, and base blade 953′.

FIG. 9D illustrates finite element analysis (FEA) results of the electrostatic performance for blade actuators 211, 911, and 961 shown respectively in FIG. 2A, FIG. 9A, and FIG. 9C. The plotted graph represents total torque (defined as the electrostatic torque minus the restoring mechanical force provided by the flexures) as a function of rotation angle in degrees under a constant applied voltage potential of 100V. Curve 2000 shows simulation results for blade actuator 211 with specific design parameters. Curve 2002 illustrates actuator 911 (in FIG. 9A) with identical design parameters, with gap 955 set to 5 μm and overlap 957 set to 9.5 μm. Curve 2004 illustrates actuator 911 with the same gap 955 (5 μm) but a smaller overlap 957 of 1.75 μm. Curve 2006 illustrates actuator 911 with gap 955 equal to 5 μm and no overlap 957. The influence of base blade 953 is most evident at small and large deflection angles.

FIG. 9E depicts a close-up of the torque-angle response in the 0°-5° range. Configurations with initial overlap 957 (curves 2002 and 2004) exhibit greater torque generation compared to the no-overlap case (curve 2006). The different response profiles converge at approximately 3° of actuator rotation.

FIG. 9F shows a close-up of the torque-angle response in the 17.5°-20.5° range. Curves begin diverging around the 18° mark: cases with initial overlap 957 (curves 2002 and 2004) produce lower net torque compared to the no-overlap case (curve 2006). Increasing overlap 957 reduces overall torque due to opposing torque contributions from base blade 953.

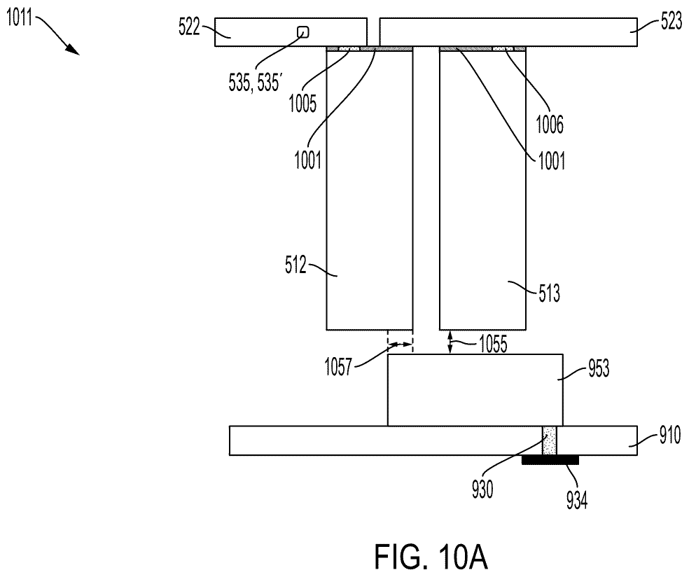

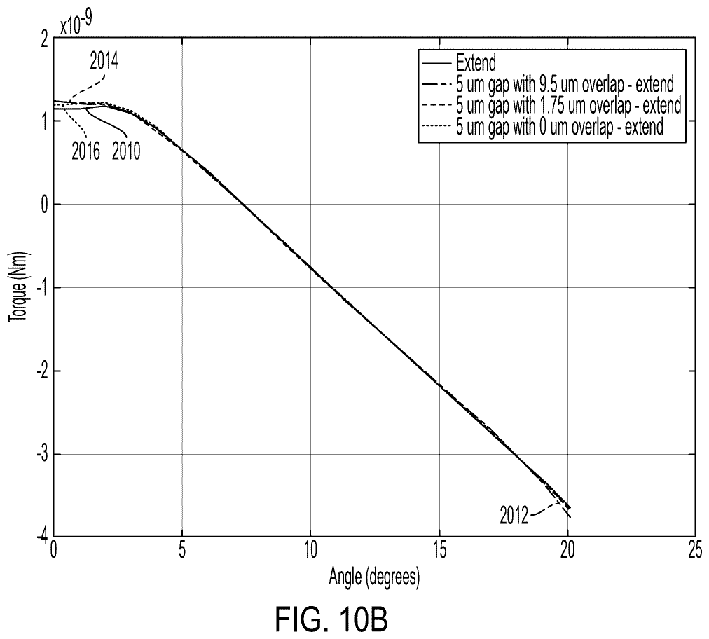

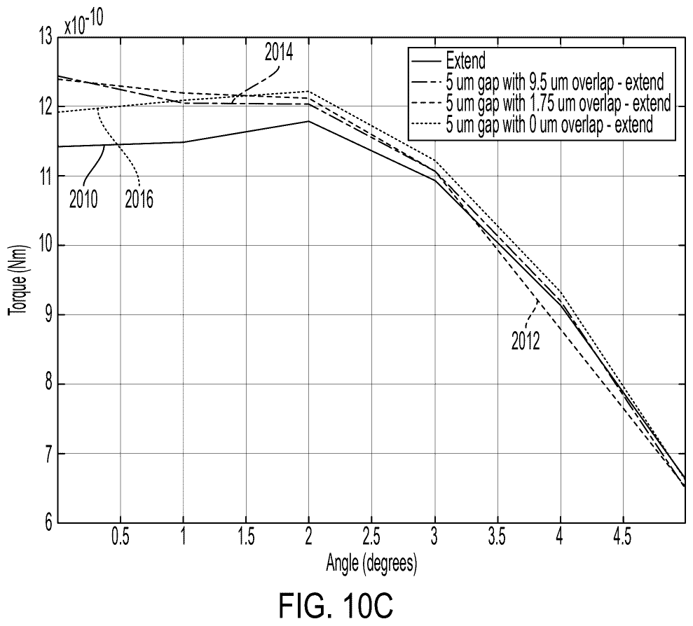

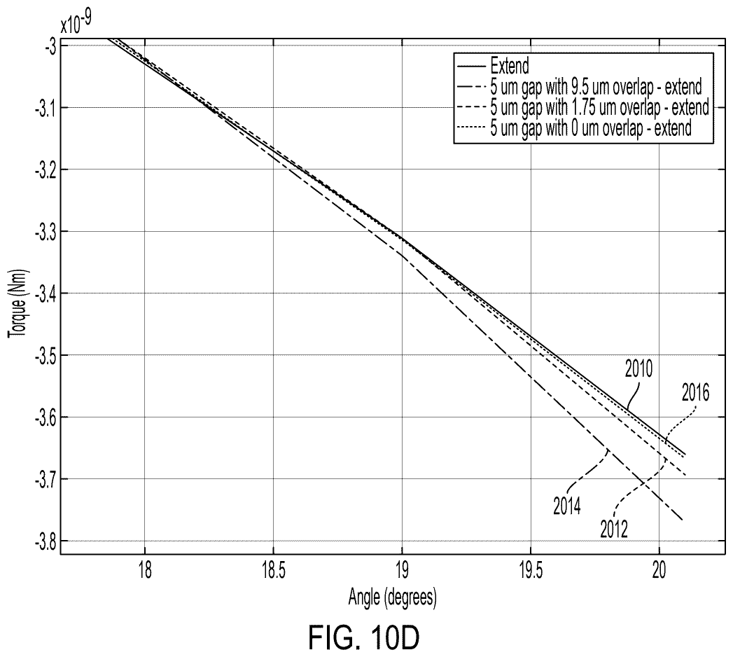

FIG. 10A shows a cross-sectional side view of blade actuator 1011 in accordance with some implementations of the present disclosure.

Blade actuator 1011 includes blade actuator 511 shown in FIGS. 5A-5B and base blade 953 shown in FIG. 9A. Base blade 954 enhances rotational actuation of blade actuator 511.

As shown, blade actuator 1011 includes a base blade 953. Base blade 953 may be fabricated on a separate wafer 910 (e.g., a substrate). In a side-view perspective, the base blade 953 is positioned beneath blade 513, which is fixed relative to blade 512, and is separated from blade 513 by a gap 1055. In this example, the side-view perspective also illustrates that base blade 953 lies beneath a portion of blade 512, which is movable relative to blade 513. Gap 1055 may range from approximately 5 μm to approximately 15 μm.

As shown in this example, in the side-view perspective, base blade 953 extends toward blade 512 such that an edge portion of base blade 953 is positioned near an edge portion of blade 512. As a result, the edge of base blade 953 may overlap (e.g., obliquely overlap) the edge of blade 512. In this example, the overlapping width 1057 between blade 512 and base blade 953 (measured in the side-view perspective) ranges from approximately 0 μm to approximately 15 μm. Even when the overlapping width 1057 is 0, the edge of base blade 953 remains adjacent to the blade 512. Accordingly, during operation, the blade 512 is attracted toward base blade 953. Furthermore, in this example, the side-view perspective shows that a portion of base blade 953 extends beyond an edge of blade 513 (edge on the right side of blade 513 in this example).

In this example, via 1005 (e.g., one or more polysilicon vias) electrically connects structure 522 (e.g., silicon of structure 522) to blade 512 (e.g., silicon of movable blade 512) through the buried insulation layer 1001. Similarly, via 1006 (e.g., one or more polysilicon vias) electrically connects structure 523 (e.g., silicon of structure 523) to blade 513 through the buried insulation layer 1001. In addition, via 906 (e.g., a silicon via) formed through wafer 910 connects base blade 953 (bottom side of base blade 953 in this example) to contact pad 934, which is disposed on the bottom side of wafer 910. Applying an electrical voltage to contact pad 934 allows a corresponding voltage to be applied to the base blade 953.

In operation, when a voltage potential V1 is applied between blades 512 and 513, blade 512 is electrostatically attracted toward blade 513, causing structure 522 to pivot about flexures 535 and 535′. Similarly, when a voltage potential V2 is applied between blade 512 and base blade 953, blade 512 is attracted toward the base blade 953, resulting in additional pivoting of structure 522 about flexures 535 and 535′. A large-angle displacement of blade actuator 511 can be achieved when V1 and V2 are applied simultaneously with equal magnitudes. Independent adjustment of V2 relative to V1, or V1 relative to V2, allows precise control of the angular positioning of blade 512.

The sequence of voltage application between V1 and V2 may also vary. For example, voltage potential V2 may be applied between blade 512 and base blade 953 either prior to or during the application of voltage potential V1 between blade 512 and blade 513. Due to the initial overlap 1057 between base blade 953 and blade 512, this sequencing can facilitate the initiation of blade motion.

FIG. 10B illustrates the results of a finite element analysis evaluating the electrostatic behavior of the blade actuators shown in FIG. 10A. The graph presents the net torque (defined as the electrostatic torque minus the mechanical restoring force provided by flexures 535, 535′) as a function of rotation angle (measured in degrees) under a constant applied voltage potential of 100 V. Curve 2010 represents blade actuator 211 shown in FIG. 2A, modeled with a specific set of dimensions. Curve 2012 represents the blade actuator 1011 of FIG. 10A with the same dimensions, a gap 1055 of 5 μm, and an overlap 1057 of 9.5 μm. Curve 2014 corresponds to the same blade actuator 1011 with a gap 1055 of 5 μm and an overlap 1057 of 1.75 μm. Curve 2016 corresponds to the same blade actuator 1011 with a gap 1055 of 5 μm and an overlap 1057 of 0. The influence of the base blade 953 is evident both in the small-angle and large-angle operating ranges.

FIG. 10C provides a magnified view of the net torque curve within the 0° to 5° range of rotational motion. As shown by curves 2012 and 2014, introducing an initial overlap 1057 between base blade 953 and blade 512 enhances the net torque relative to the case of zero overlap (curve 2016). By approximately 3° of rotation, the torque curves converge to nearly equivalent values.

FIG. 10D provides a magnified view of the net torque curve within the 17.5° to 20.5° rotation range. Beginning around 18°, the torque curves diverge. As shown in curves 2012 and 2014, the presence of initial overlap 1057 between base blade 953 and blade 512 results in reduced torque relative to the zero-overlap condition (curve 2016). Increasing the initial overlap further decreases the generated torque, reflecting the effect of a counteracting torque contribution from the base blade 953. In this operating region, the zero-overlap configuration (overlap 1057=0) provides increased torque near 0° rotation and does not significantly diminish torque performance near 20° rotation.

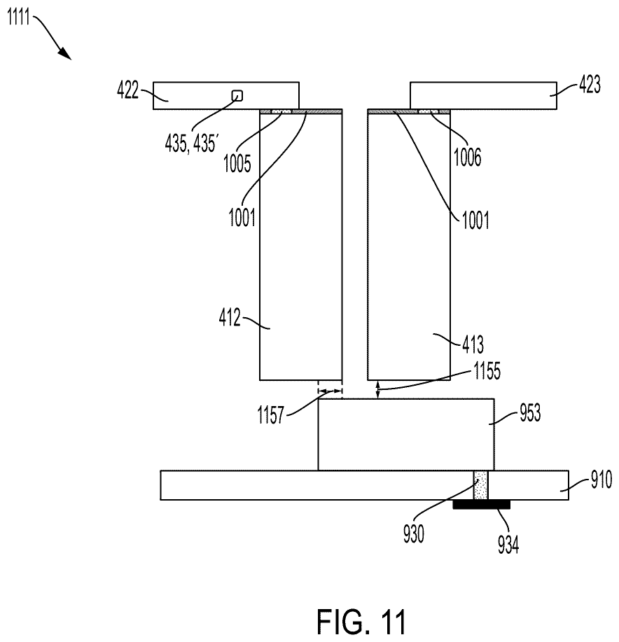

FIG. 11 shows a cross-sectional side view of blade actuator 1111 in accordance with some implementations of the present disclosure.

Blade actuator 1111 includes blade actuator 411 shown in FIGS. 4A-4B and base blade 953 shown in FIG. 9A. Base blade 954 enhances rotational actuation of blade actuator 411.

As shown, blade actuator 1111 includes abase blade 953. Base blade 953 may be fabricated on a separate wafer 910 (e.g., a substrate). In a side-view perspective, the base blade 953 is positioned beneath blade 413, which is fixed relative to blade 412, and is separated from blade 413 by a gap 1155. In this example, the side-view perspective also illustrates that base blade 953 lies beneath a portion of blade 412, which is movable relative to blade 413. Gap 1155 may range from approximately 5 μm to approximately 15 μm.

As shown in this example, in the side-view perspective, base blade 953 extends toward blade 412 such that an edge portion of base blade 953 is positioned near an edge portion of blade 412. As a result, the edge of base blade 953 may overlap (e.g., obliquely overlap) the edge of blade 412. In this example, the overlapping width 1157 between blade 412 and base blade 953 (measured in the side-view perspective) ranges from approximately 0 μm to approximately 15 μm. Even when the overlapping width 1157 is 0, the edge of base blade 953 remains adjacent to the blade 412. Accordingly, during operation, the blade 412 is attracted toward base blade 953. Furthermore, in this example, the side-view perspective shows that a portion of base blade 953 extends beyond an edge of blade 413 (edge on the right side of blade 413 in this example).

In this example, via 1005 (e.g., one or more polysilicon vias) electrically connects structure 422 (e.g., silicon of structure 422) to blade 412 (e.g., silicon of movable blade 412) through the buried insulation layer 1001. Similarly, via 1006 (e.g., one or more polysilicon vias) electrically connects structure 423 (e.g., silicon of structure 423) to blade 413 through the buried insulation layer 1001. In addition, via 906 (e.g., a silicon via) formed through wafer 910 connects base blade 953 (bottom side of base blade 953 in this example) to contact pad 934, which is disposed on the bottom side of wafer 910. Applying an electrical voltage to contact pad 934 allows a corresponding voltage to be applied to the base blade 953.

In operation, when a voltage potential V1 is applied between blades 412 and 413, blade 412 is electrostatically attracted toward blade 413, causing structure 422 to pivot about flexures 435 and 435′. Similarly, when a voltage potential V2 is applied between blade 412 and base blade 953, blade 412 is attracted toward the base blade 953, resulting in additional pivoting of structure 422 about flexures 435 and 435′. A large-angle displacement of blade actuator 411 can be achieved when V1 and V2 are applied simultaneously with equal magnitudes. Independent adjustment of V2 relative to V1, or V1 relative to V2, allows precise control of the angular positioning of blade 412.

The sequence of voltage application between V1 and V2 may also vary. For example, voltage potential V2 may be applied between blade 412 and base blade 953 either prior to or during the application of voltage potential V1 between blade 412 and blade 413. Due to the initial overlap 1157 between base blade 953 and blade 412, this sequencing can facilitate the initiation of blade motion.

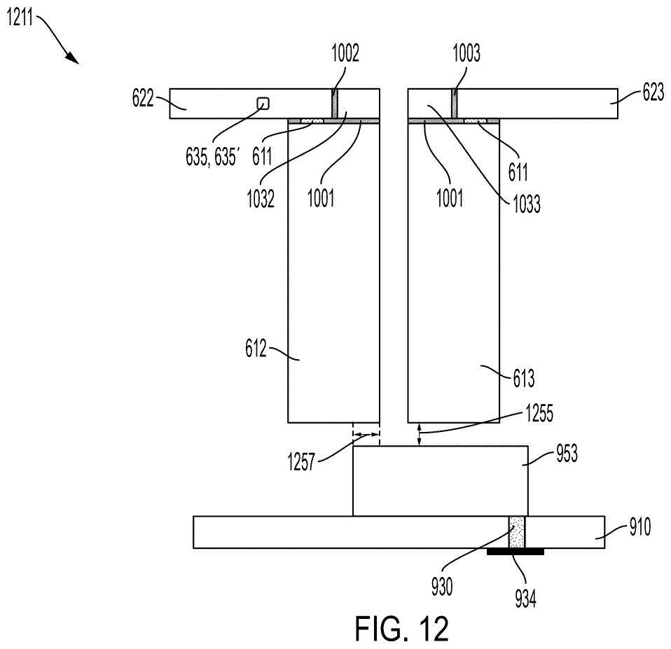

FIG. 12 shows a cross-sectional side view of blade actuator 1211 in accordance with some implementations of the present disclosure.

Blade actuator 1211 includes blade actuator 611 shown in FIGS. 6A-6B and base blade 953 shown in FIG. 9A. Base blade 954 enhances rotational actuation of blade actuator 611.

As shown, blade actuator 1211 includes a base blade 953. Base blade 953 may be fabricated on a separate wafer 910 (e.g., a substrate). In a side-view perspective, the base blade 953 is positioned beneath blade 613, which is fixed relative to blade 612, and is separated from blade 613 by a gap 1255. In this example, the side-view perspective also illustrates that base blade 953 lies beneath a portion of blade 612, which is movable relative to blade 613. Gap 1255 may range from approximately 5 μm to approximately 15 μm.

As shown in this example, in the side-view perspective, base blade 953 extends toward blade 612 such that an edge portion of base blade 953 is positioned near an edge portion of blade 612. As a result, the edge of base blade 953 may overlap (e.g., obliquely overlap) the edge of blade 612. In this example, the overlapping width 1257 between blade 612 and base blade 953 (measured in the side-view perspective) ranges from approximately 0 μm to approximately 15 μm. Even when the overlapping width 1257 is 0, the edge of base blade 953 remains adjacent to the blade 612. Accordingly, during operation, the blade 612 is attracted toward base blade 953. Furthermore, in this example, the side-view perspective shows that a portion of base blade 953 extends beyond an edge of blade 613 (edge on the right side of blade 613 in this example).

In this example, via 1005 (e.g., one or more polysilicon vias) electrically connects structure 622 (e.g., silicon of structure 622) to blade 612 (e.g., silicon of movable blade 612) through the buried insulation layer 1001. Similarly, via 1006 (e.g., one or more polysilicon vias) electrically connects structure 623 (e.g., silicon of structure 623) to blade 613 through the buried insulation layer 1001. In addition, via 906 (e.g., a silicon via) formed through wafer 910 connects base blade 953 (bottom side of base blade 953 in this example) to contact pad 934, which is disposed on the bottom side of wafer 910. Applying an electrical voltage to contact pad 934 allows a corresponding voltage to be applied to the base blade 953.

In operation, when a voltage potential V1 is applied between blades 612 and 613, blade 612 is electrostatically attracted toward blade 613, causing structure 622 to pivot about flexures 635 and 635′. Similarly, when a voltage potential V2 is applied between blade 612 and base blade 953, blade 612 is attracted toward the base blade 953, resulting in additional pivoting of structure 622 about flexures 635 and 635′. A large-angle displacement of blade actuator 611 can be achieved when V1 and V2 are applied simultaneously with equal magnitudes. Independent adjustment of V2 relative to V1, or V1 relative to V2, allows precise control of the angular positioning of blade 612.

The sequence of voltage application between V1 and V2 may also vary. For example, voltage potential V2 may be applied between blade 612 and base blade 953 either prior to or during the application of voltage potential V1 between blade 612 and blade 613. Due to the initial overlap 1257 between base blade 953 and blade 612, this sequencing can facilitate the initiation of blade motion.

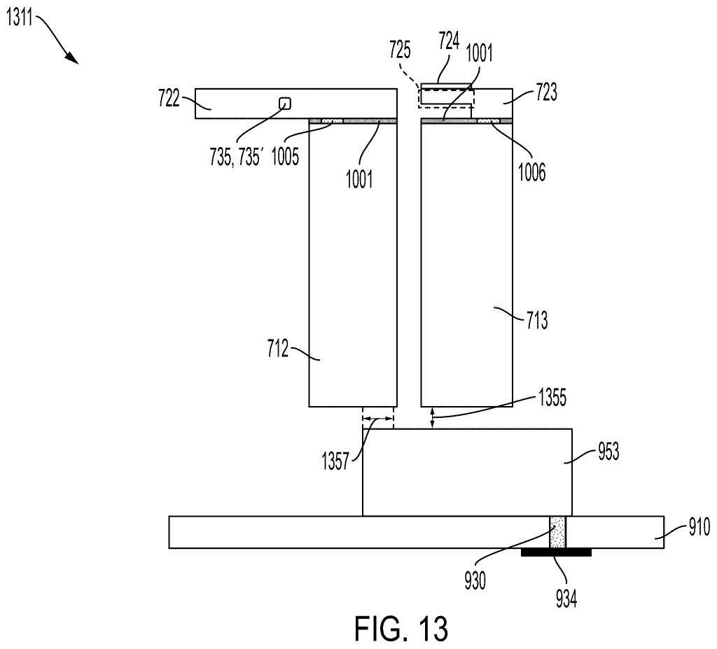

FIG. 13 shows a cross-sectional side view of blade actuator 1311 in accordance with some implementations of the present disclosure.

Blade actuator 1311 includes blade actuator 711 shown in FIGS. 7A-7C and base blade 953 shown in FIG. 9A. Base blade 954 enhances rotational actuation of blade actuator 711.

As shown, blade actuator 1311 includes a base blade 953. Base blade 953 may be fabricated on a separate wafer 910 (e.g., a substrate). In a side-view perspective, the base blade 953 is positioned beneath blade 713, which is fixed relative to blade 712, and is separated from blade 713 by a gap 1355. In this example, the side-view perspective also illustrates that base blade 953 lies beneath a portion of blade 712, which is movable relative to blade 713. Gap 1355 may range from approximately 5 μm to approximately 15 μm.

As shown in this example, in the side-view perspective, base blade 953 extends toward blade 712 such that an edge portion of base blade 953 is positioned near an edge portion of blade 712. As a result, the edge of base blade 953 may overlap (e.g., obliquely overlap) the edge of blade 712. In this example, the overlapping width 1357 between blade 712 and base blade 953 (measured in the side-view perspective) ranges from approximately 0 μm to approximately 15 μm. Even when the overlapping width 1357 is 0, the edge of base blade 953 remains adjacent to the blade 712. Accordingly, during operation, the blade 712 is attracted toward base blade 953. Furthermore, in this example, the side-view perspective shows that a portion of base blade 953 extends beyond an edge of blade 713 (edge on the right side of blade 713 in this example).

In this example, via 1005 (e.g., one or more polysilicon vias) electrically connects structure 722 (e.g., silicon of structure 722) to blade 712 (e.g., silicon of movable blade 712) through the buried insulation layer 1001. Similarly, via 1006 (e.g., one or more polysilicon vias) electrically connects structure 723 (e.g., silicon of structure 723) to blade 713 through the buried insulation layer 1001. In addition, via 906 (e.g., a silicon via) formed through wafer 910 connects base blade 953 (bottom side of base blade 953 in this example) to contact pad 934, which is disposed on the bottom side of wafer 910. Applying an electrical voltage to contact pad 934 allows a corresponding voltage to be applied to the base blade 953.

In operation, when a voltage potential V1 is applied between blades 712 and 713, blade 712 is electrostatically attracted toward blade 713, causing structure 722 to pivot about flexures 735 and 735′. Similarly, when a voltage potential V2 is applied between blade 712 and base blade 953, blade 712 is attracted toward the base blade 953, resulting in additional pivoting of structure 722 about flexures 735 and 735′. A large-angle displacement of blade actuator 711 can be achieved when V1 and V2 are applied simultaneously with equal magnitudes. Independent adjustment of V2 relative to V1, or V1 relative to V2, allows precise control of the angular positioning of blade 712.

The sequence of voltage application between V1 and V2 may also vary. For example, voltage potential V2 may be applied between blade 712 and base blade 953 either prior to or during the application of voltage potential V1 between blade 712 and blade 713. Due to the initial overlap 1357 between base blade 953 and blade 712, this sequencing can facilitate the initiation of blade motion.

### II. Methods of Manufacture (MEMS Array)

The methods for fabricating a microelectromechanical (MEMS) array. The fabricating method comprises: forming a layer of dielectric material on a first side of a substrate; forming on the first side of the substrate vertical isolation trenches containing dielectric material; patterning a masking layer on a second side of the substrate that is opposite to the first side of the substrate; forming vias on the first side of the substrate; metallizing the first side of the substrate; depositing a second metal layer on the first side of the substrate to form a reflective surface; forming second trenches on the first side of the substrate to define structures; deeply etching the second side of the substrate to form narrow blades; bonding a base wafer to the second side of the substrate after forming the narrow blade; and etching through the second trenches on the first side of the substrate to release the structures and to provide electrical isolation. A lid can be placed on the first side of the substrate (e.g., top side of the substrate) providing a hermetic seal. The substrate may include a silicon-on-insulator (SOI) wafer. The substrate may include a cavity silicon-on-insulator (CSOI) wafer. Additionally, the dielectric material can be silicon dioxide. Additionally, the method can include one or more of forming a passivation dielectric layer on the first side of the substrate after metallizing the first side of the substrate and attaching the lid wafer to the first side of the substrate. The lid wafer may include glass.

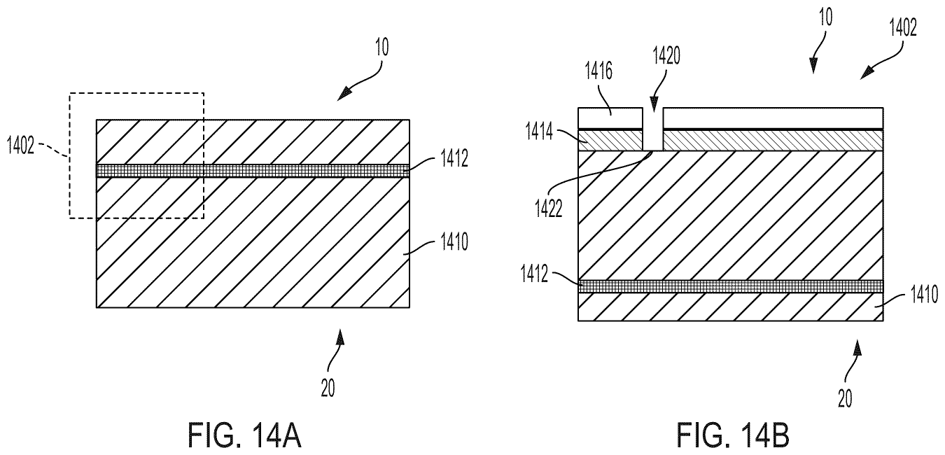

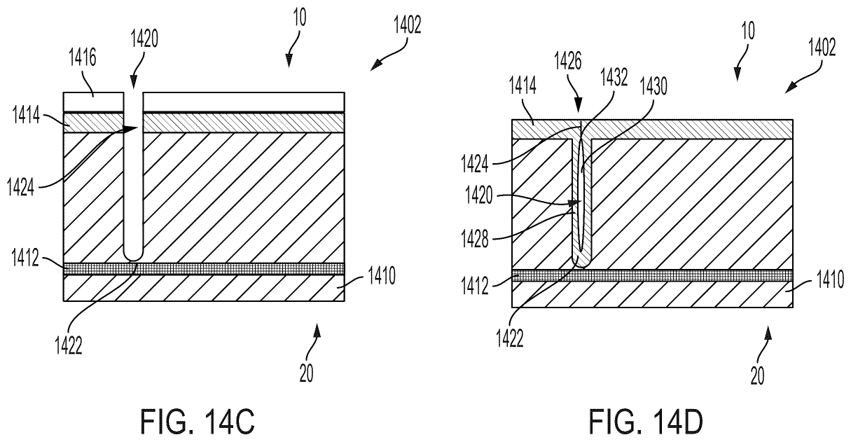

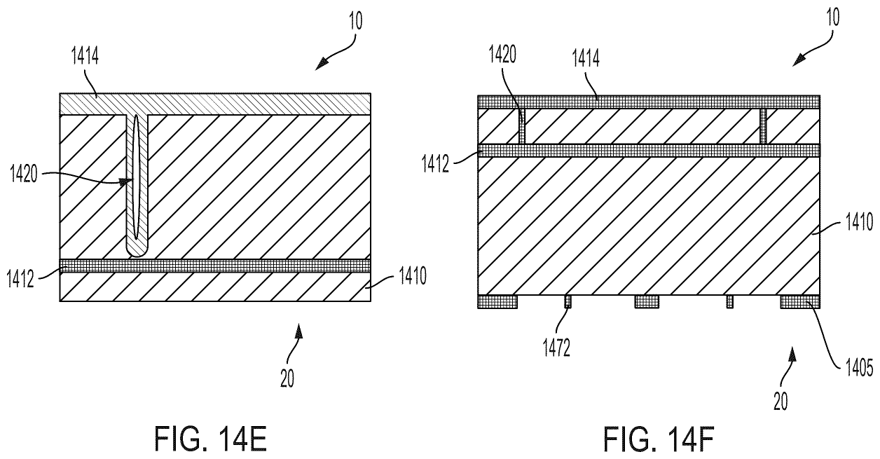

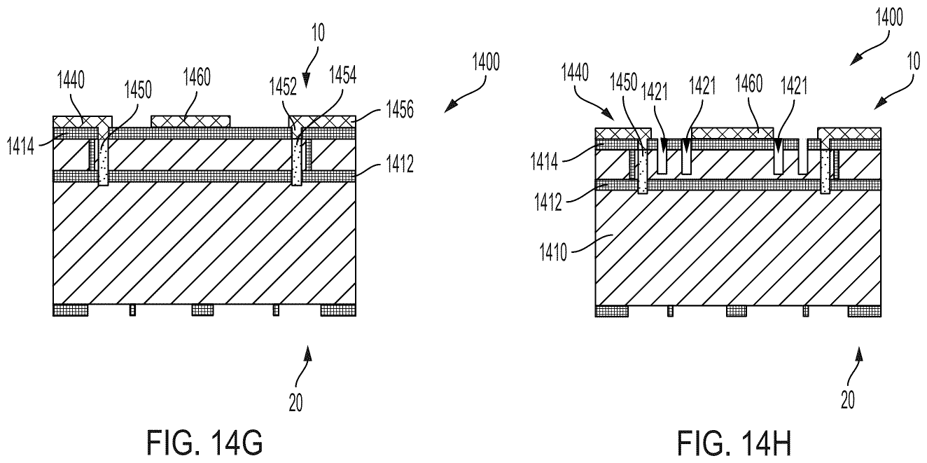

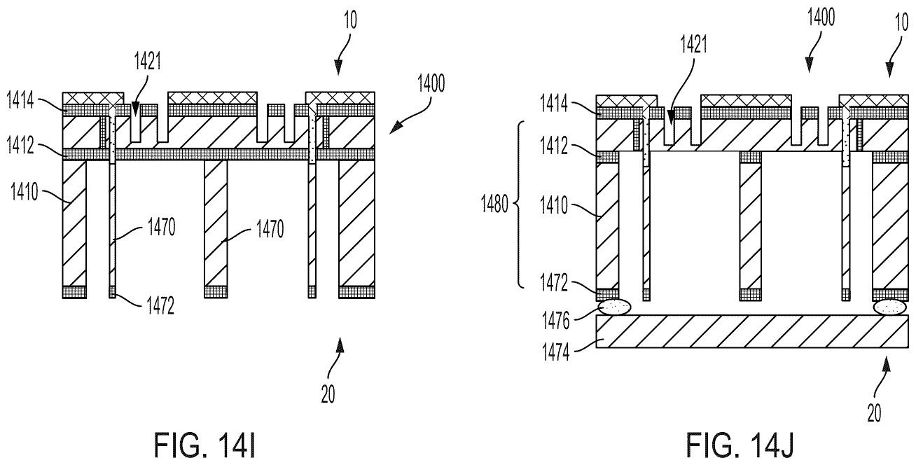

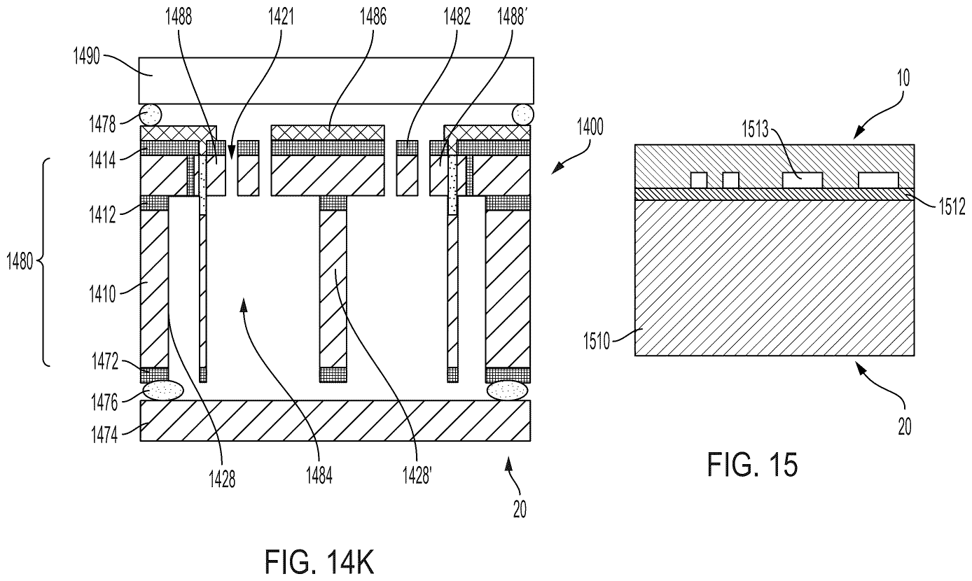

In one example, the disclosure utilizes a single device wafer, and the corresponding method is described with reference to FIGS. 14A-14K.

FIG. 14A illustrates a cross-section of a silicon-on-insulator (SOI) wafer 1410. The silicon wafer 1410 may have a thickness in a range between 300 μm and 600 μm. The silicon wafer 1410 has a top side 10 (or device side or simply a top) and a backside or bottom side 20. The upper left hand portion 1402 is marked. In some examples, the buried oxide layer 1412 may have a thickness between 0.5 μm and 1 μm. The buried oxide layer 1412 may be positioned 10-50 μm from the top side 10.

FIGS. 14B-14E illustrate the upper left hand portion 1402 of the silicon wafer 1410 in a MEMS actuator which illustrates fabrication techniques for isolation trenches 1420 on the top side 10 of silicon wafer 1410. The isolation trenches 1420 are vertically positioned on the silicon wafer substrate and filled with a dielectric material. The dielectric material may include silicon dioxide. Once filled, the isolation trenches 1420 provide electrical isolation between blades after the mirror is released. A masking layer 1414 also remains on the surface of the silicon wafer 1410 and is planarized after the isolation trench fill process to ease subsequent lithographic patterning and eliminate surface discontinuities. The isolation trench 1002 and isolation trench 1003 in FIG. 6A may be formed using this process.

Referring to FIG. 14B, a silicon wafer 1410 is provided with a masking layer 1414. The masking layer 1414 may include one or more silicon dioxide layers (e.g., an oxide layer). The silicon wafer 1410 can have arbitrary doping, resistivity, and crystal orientation, as the process relies solely on reactive ion etching to carve and form the structures. The masking layer 1414 serves the function of protecting the upper surface of the silicon wafer 1410 during the isolation trench etching process, and thus represents a masking layer. This masking layer 1414 can be formed from any number of techniques, including thermal oxidation of silicon or chemical vapor deposition (CVD). A thickness of the masking layer 1414 may be between 0.5 μm and 1.0 μm. A photoresist layer 1416 is then spun onto the silicon wafer 1410 and exposed and developed using standard photolithography techniques to define the isolation trench pattern for the isolation trench 1420. Reactive ion etching may be used to transfer the photoresist pattern to the masking layer 1414, exposing the top surface of the silicon wafer 1410 (i.e., the bottom 1422 of the isolation trench 1420). For example, the silicon dioxide mask is etched using Freon gas mixture (e.g., CHF₃, CF₄). High etch rates for silicon dioxide etching are achieved using a high-density plasma reactor, such as an inductively coupled plasma (ICP) chamber. These ICP chambers use a high-power RF source to sustain the high-density plasma and a low-power RF bias on the wafer to achieve high etch rates at low ion energies. Oxide etch rates of 200 nm/min and selectivities to photoresist greater than 1:1 are common for this hardware configuration.

As illustrated in FIG. 14C, an isolation trench 1420 is formed in the silicon wafer 1410 by deep reactive ion etching of silicon using high etch rate and high selectivity etching. The trench is commonly etched in a high-density plasma using a sulfur hexafluoride (SF₆) gas mixture as described in U.S. Pat. No. 5,501,893. Preferably, etching is controlled so that the isolation trench 1420 profile is reentrant, or tapered, with the top 1424 of the isolation trench 1420 being narrower than the bottom 1422 of the isolation trench 1420. Tapering of the isolation trench 1420 ensures that good electrical isolation is achieved in subsequent processing. Profile tapering can be achieved in reactive ion etching by tuning the degree of passivation, or by varying the parameters (power, gas flows, pressure) of the discharge during the etching process. Because the isolation trench 1420 is filled with dielectric material, the opening at the top 1424 of the isolation trench 1420 is typically less than 2 μm in width. The isolation trench 1420 depth is typically in the range 10-50 μm. In some examples, the isolation trench 1420 etch stops at the buried oxide layer 1412. A common procedure for etching the isolation trench 1420 is to alternate etch steps (SF₆ and argon mixture) with passivation steps (Freon with argon) in an ICP plasma to achieve etch rates in excess of 2 μm/min at high selectively to photoresist (>50:1) and oxide (>100:1). The power and time of the etch cycles are increased as the trench deepens to achieve the tapered profile. Although the trench geometry is preferably reentrant, arbitrary trench profiles can be accommodated with adjustments in microstructure processing. Good isolation results can be achieved with any of a number of known trench etch chemistries. After the silicon trench is etched, the photoresist layer 1416 is removed with a suitable process (e.g., wet chemistry technique, dry ashing technique).

Referring to FIG. 14D, the isolation trench 1420 is then filled with an insulating dielectric material (e.g., silicon dioxide). The filling procedure results in the mostly solid isolation segment in the isolation trench 1420, and serves to deposit a layer of dielectric material on the top side 10 (top surface) of the silicon wafer 1410 and dielectric layers on the sidewall 1428 and bottom 1422 of the isolation trench 1420. The thickness of the deposited layer is usually in excess of 1 μm. This fill can be accomplished with chemical vapor deposition (CVD) techniques or by oxidizing silicon at high temperatures. In thermal oxidation, the wafer is exposed to an oxygen rich environment at temperatures between 900° C. and 1150° C. This oxidation process consumes silicon surfaces to form silicon dioxide. The resulting volumetric expansion from this process causes the sidewalls of the trenches to encroach upon each other, eventually closing the trench opening. In a CVD fill, some dielectric is deposited on the walls but filling also occurs from deposition on the bottom of the trench. CVD dielectric fill of trenches has been demonstrated with TEOS or silane mixtures in plasma enhanced CVD chambers and low-pressure CVD furnace tubes. Another option is to coat the sides of isolation trench 1420 with silicon oxide and fill it with another material such as polysilicon or material similar to polysilicon.

During the isolation trench 1420 filling process, it is common for most isolation trench profiles to be incompletely filled, causing an interface 1432 and a void 1430 to be formed in the isolation trench 1420. A local concentration of stress in the void 1430 can cause electrical and mechanical malfunction in some devices but is generally unimportant for micromechanical devices due to the enclosed geometry of the isolation trench 1420. The interface 1432 and void 1430 can be eliminated by shaping the isolation trench 1420 to be wider at the isolation trench opening located at the top 1424 of the isolation trench 1420 than the bottom 1422 of the isolation trench 1420. However, good electrical isolation would then require additional tapering of the microstructure trench etch in the later steps. Another artifact of the isolation trench filling process is an indentation 1426 that is created in the surface of the masking layer 1414 centered over the isolation trench 1420. This indentation is unavoidable in most trench filling processes, and can be as deep as 0.5 μm, depending on the thickness of the deposition. To remove the indentation 1426, the surface is planarized to form a flat, or substantially flat, surface, as illustrated in FIG. 14E, for subsequent lithographic and deposition steps. Planarization is performed either by chemical-mechanical polishing (CMP) or by depositing a viscous material, which can be photoresist, spin-on glass, or polymide, and flowing the material to fill the indentation 1426 to a smooth finish. During etchback of the viscous material, which is the second step of planarization, the surface is etched uniformly, including the filled indentation. Therefore, by removing part of the surface oxide layer, the indentation 1426 is removed to create a uniform thickness layer. For example, if the masking layer 1414 is originally 2 μm in thickness, then planarization to remove the indentation 1426 leaves a masking layer 1414 having a final thickness of less than 1 μm. The top side 10 (e.g., upper surface) of silicon wafer 1410 is free from imperfection and is ready for further lithography and deposition.

FIG. 14F shows silicon wafer 1410 with masking layer 1414 and isolation trenches 1420. After the isolation trenches 1420 are fabricated, standard front-to-back alignment is used to lithographically pattern the masking layer for the blades on the bottom side 20 (backside) of the silicon wafer 1410. The blade pattern 1472 is exposed and etched into a masking layer 1405. The masking layer 1405 is typically a layer comprised of a combination of thermally grown silicon oxide and oxide deposited by chemical vapor deposition. It may also be comprised of a metal layer such as aluminum. The lithography pattern is transferred in the masking layer by reactive ion etching, yet the silicon blade etching is not completed until later in the process. Without the blades etched, the wafer is easily processed through the remaining device layers. The backside of the blade pattern 1472 is typically aligned topside to the isolation trenches 1420 to within several microns.

Metallization on the top side 10 of the silicon wafer 1410 then proceeds as illustrated in FIG. 14G. In order to make contact to the underlying silicon wafer 1410 vias 1452 are patterned and etched into the masking layer 1414 using standard lithography and reactive ion etching. In some areas, the vias may be etched through the buried oxide layer 1412 and filled with polysilicon to produce polysilicon vias 1450 and 1454. After the vias 1452 are etched, metallization is deposited to form a metal layer 1440 and patterned to form a metal interconnect 1456 and a contact 1454 to the silicon wafer 1410 through the via 1452. For one embodiment, the metal is aluminum and is patterned using wet etching techniques. In mirror arrays with high interconnect densities, it is advantageous to pattern the metal using dry etching or evaporated metal lift-off techniques to achieve finer linewidths. The metal layer 1440 is used to provide bond pads and interconnects, which connect electrical signals from control circuitry to each mirror to control mirror actuation.

Deposition of a second metal layer 1460 provides a reflective mirror surface. This metal is tuned to provide high mirror reflectivities at the optical wavelengths of interest and is typically evaporated and patterned using lift-off techniques to allow a broader choice of metallization techniques. For example, the metallization is comprised of 500 nm of aluminum. However, additional metal stacks such as Cr/Pt/Au may be used to increase reflectivities in the wavelength bands common to fiber optics. Because the metals are deposited under stress and will affect the eventual mirror flatness, it is advantageous to reduce the thickness of the masking layer 1414 in the region of the mirror. This can be accomplished through the use of dry etching of the underlying dielectric prior to evaporation.

In FIG. 14H, the topside processing is completed. First, a passivation dielectric layer (not shown) may be applied to protect the metallization during subsequent processing. The passivation dielectric layer is removed in the region of the bonding pads and from the actuator region. At this step, the silicon dioxide layer 724 in FIG. 7B may be deposited. Second, the mirror structure including frame, mirror, and supports are defined using multiple etches that define trenches 1421 separating the structural elements. At this step, the first portion 1022 and the second portion 1023 in FIG. 4A may be mostly removed. The first portion 1052 in FIG. 5A may be mostly removed, and the structure 523 in FIG. 5A may be defined at this step. The etches are self-aligned and proceed through the various metal, dielectric, and silicon wafers 1410. A further blanket deposition is applied to the topside which passivates the sidewalls of the trenches 1421 and prepares the topside for mechanical release.

As shown in FIG. 14I, backside silicon etching transfers the blade pattern 1472 into the silicon wafer 1410 substrate to obtain the blades 1470. The etching is performed using deep silicon etching at high selectivity to oxide using the techniques disclosed in U.S. Pat. No. 5,501,893. The deep silicon etching achieves near vertical profiles in the blades 1470, which can be nominally 5-20 μm wide and in excess of 300 μm deep. The etch stops on the buried oxide layer 1412 to provide a uniform depth across the wafer while not punching through the top side 10 surface of the silicon wafer 1410. All blades 1470 can be etched simultaneously across the mirror element and across the mirror array. Buried oxide layer 1412 may be etched at this time.

Referring to FIG. 14J, because the device wafer is now prepared for microstructure release, the device wafer 1480 becomes more susceptible to yield loss due to handling shock or air currents. In order facilitate handling and aid in hermetically sealing the mirror array, a silicon wafer 1474 is bonded to the device wafer 1480 to protect the blades after release. For one embodiment, the bonding is accomplished through the use of a bonding element 1476, such as a frit glass material bonding element, that is heated to its flow temperature and then cooled. In this manner, a 400° C. temperature bonding elements 1476 produces a hermetic seal to surround the entire mirror array. The separation between the device wafer 1480 and the silicon wafer 1474 using the bonding elements 1476, such as a frit glass material bonding element, allows the blades 1470 to swing through high rotation angles without impedance. Typically, the standoff required is greater than 25 μm.

Final structure release is accomplished on the wafer topside in FIG. 14K using a combination of dry etching of silicon dioxide and silicon, which punctures through the trenches 1421 to suspend the movable elements of the mirror 1486 and the frame 1482. At this step, the first portion 1022 and the second portion 1023 in FIG. 4A may be completely removed. The first portion 1052 in FIG. 5A may be completely removed at this step. In addition, the release etch promotes electrical isolation by separating, for example, the silicon of the frame 1482 from the silicon of surrounding members 1488, 1488′ and device wafer 1480. The vias 1452 serve to connect the regions of silicon to the metal interconnects 1456 (shown in FIG. 14G). To completely seal the mirrors from the outside environment, a lid wafer 1490 is bonded to the device wafer 1480, preferably through the bonding element 1478 (e.g., frit glass seal). The lid wafer 1490 is typically made of glass, which allows incoming light to be transmitted with low loss in the mirror cavity 1484, reflect off the upper surface of the mirror 1486, and then transmit out of the mirror cavity 1484.

FIG. 15 shows a cross-section view of a cavity silicon-on-insulator (CSOI) wafer 1510 in accordance with some embodiments. In some examples, it is necessary to start with a different silicon substrate. The silicon wafer 1510 may have a thickness between 300 μm and 600 μm. The silicon wafer 1510 has a top side 10 (also referred to as device side or simply a top) and a bottom side 20 (also referred to as a backside). Each layer within the MEMS actuator 100 formed from the silicon wafer 1510 has a layer top surface oriented towards top side 10 and a bottom surface oriented towards bottom side 20. In some examples, the buried oxide layer 1512 is disposed 10-50 μm below from the top side 10. The buried oxide layer 1512 may have a thickness between 0.5 μm and 1 μm. As shown, the cavities 1513 are formed (e.g., etched or pre-etched) in the silicon above the buried oxide layer 1512 at pre-determined locations. The cavities 1513 may be created using one or more etching processes. The cavities 1513 extend from the buried oxide layer 1512 upward to the top side 10 of the of the silicon wafer 1510. In some examples, the height of the cavities 1513 may be between 5 μm and 45 μm. The fabrication of the MEMS actuators follows the steps illustrated in FIGS. 14A to 14K.

### III. Methods of Manufacture (Base Blade Wafer)

The methods for fabricating a base blade wafer. The fabricating method comprises: forming a deep silicon via trench on a first side of a substrate; forming a layer of dielectric material on the substrate; growing a layer of polysilicon to fill the deep silicon trench on the first side; planarizing the first side of the substrate; forming a layer of dielectric material on the first side of the substrate; back grinding and polishing the second side of the substrate to reveal the through silicon vias; forming a layer of dielectric material on the second side of the substrate; patterning and etching contact openings in the dielectric material on the second side of the substrate; metallizing the second side of the substrate; forming a passivation dielectric material on the second side of the substrate; polishing the second side of the substrate to planarize the surface; etching contact openings on the first side of the substrate; depositing and patterning a metal on the first side of the substrate that will serve as a bond metal and a seed metal; applying a thick photoresist on the first side of the substrate and exposing the areas where base blades will be; electroplating a metal on the first side of the substrate; and removing the thick photoresist from the first side of the substrate. The substrate may include a double side polished silicon wafer.

The methods for fabricating a microelectromechanical (MEMS) array. The fabricating method comprises: forming a layer of dielectric material on a first side of a substrate; forming on the first side of the substrate vertical isolation trenches containing dielectric material; patterning a masking layer on a second side of the substrate that is opposite to the first side of the substrate; forming vias on the first side of the substrate; metallizing the first side of the substrate; depositing a second metal layer on the first side of the substrate to form a reflective surface; forming second trenches on the first side of the substrate to define structures; deeply etching the second side of the substrate to form narrow blades; bonding a base blade wafer to the second side of the substrate after forming the narrow blade; and etching through the second trenches on the first side of the substrate to release the structures and to provide electrical isolation. A lid can be placed on the first side of the substrate (e.g., top side of the substrate) providing a hermetic seal. The substrate may include a silicon-on-insulator (SOI) wafer. The substrate may include a cavity silicon-on-insulator (CSOI) wafer. Additionally, the dielectric material can be silicon dioxide. Additionally, the method can include one or more of forming a passivation dielectric layer on the first side of the substrate after metallizing the first side of the substrate and attaching the lid wafer to the first side of the substrate. The lid wafer may include glass.

### (a) Fabrication of the Base Wafer

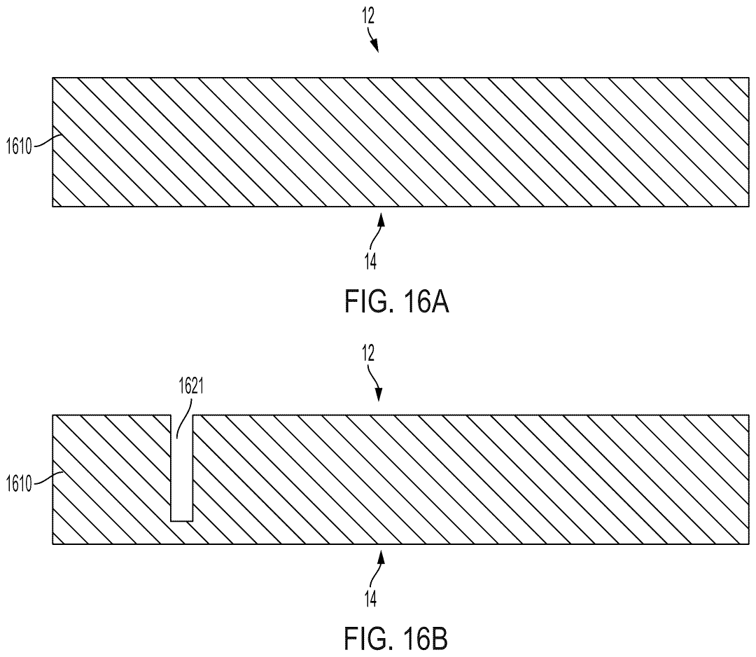

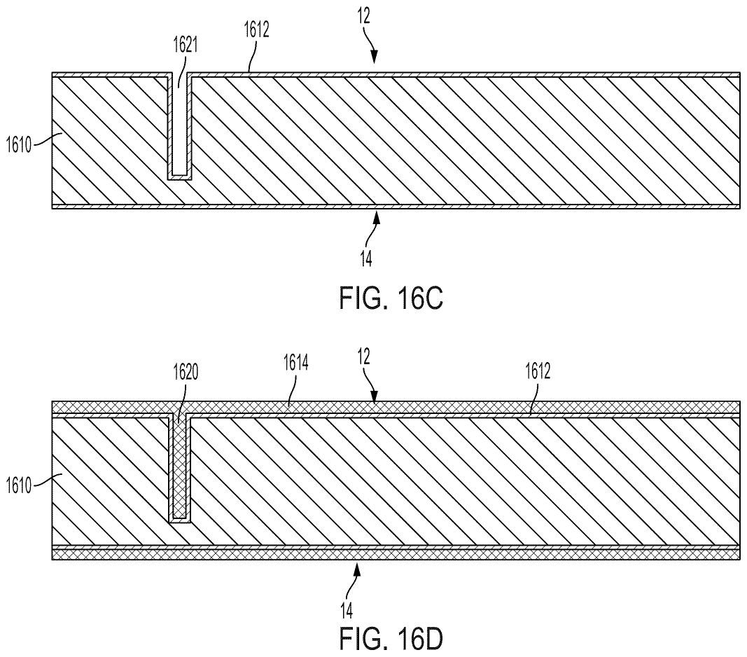

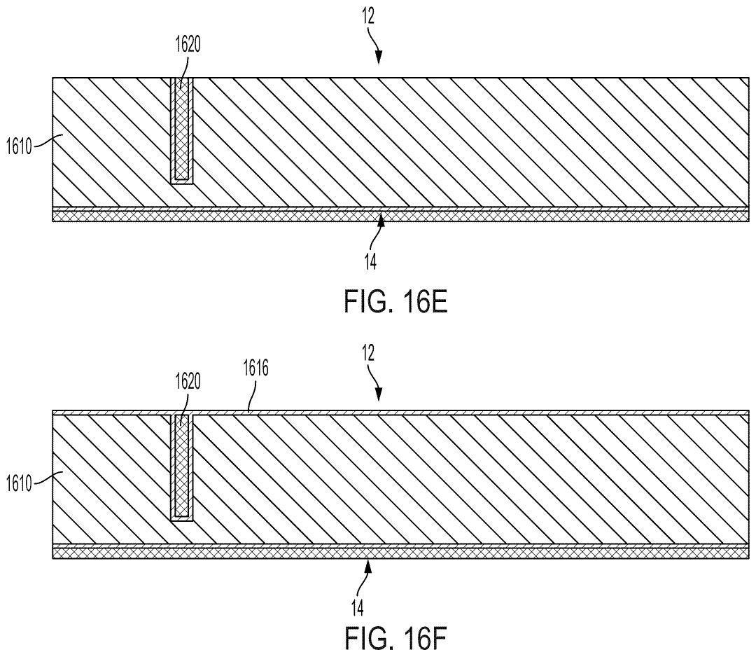

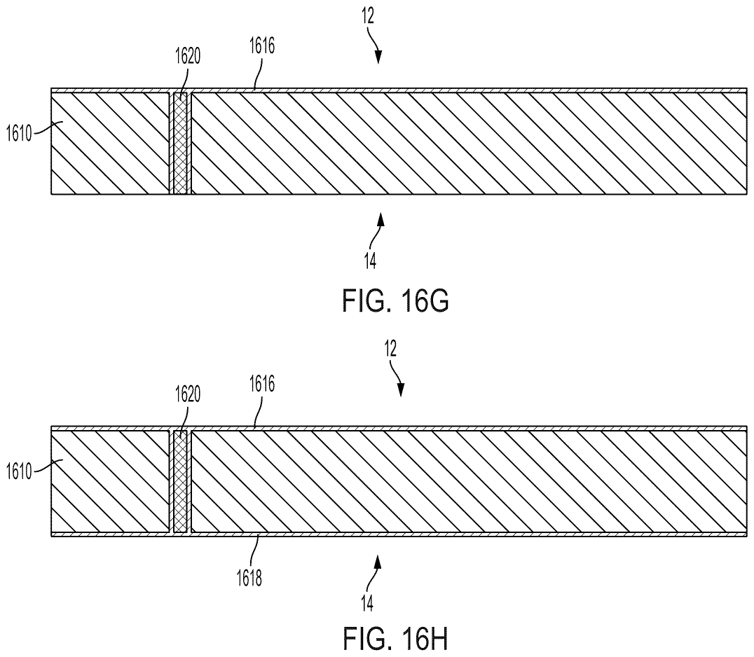

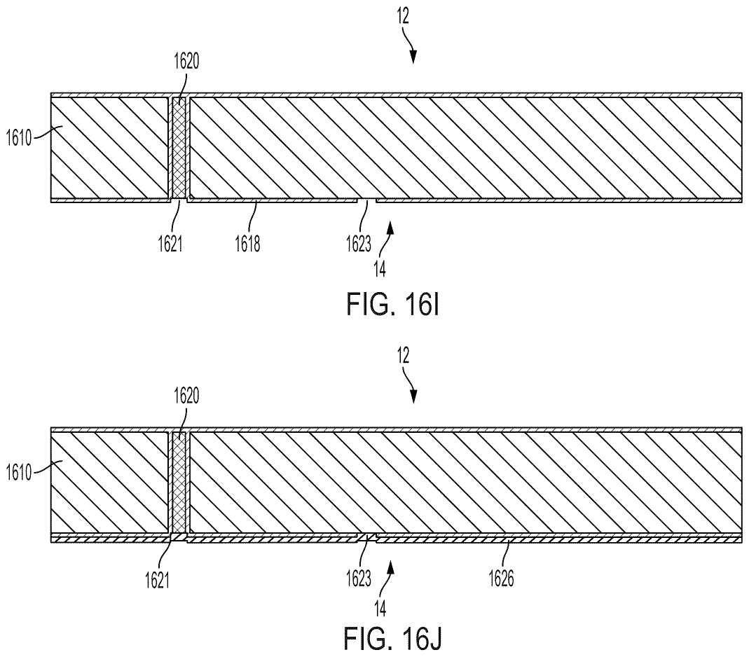

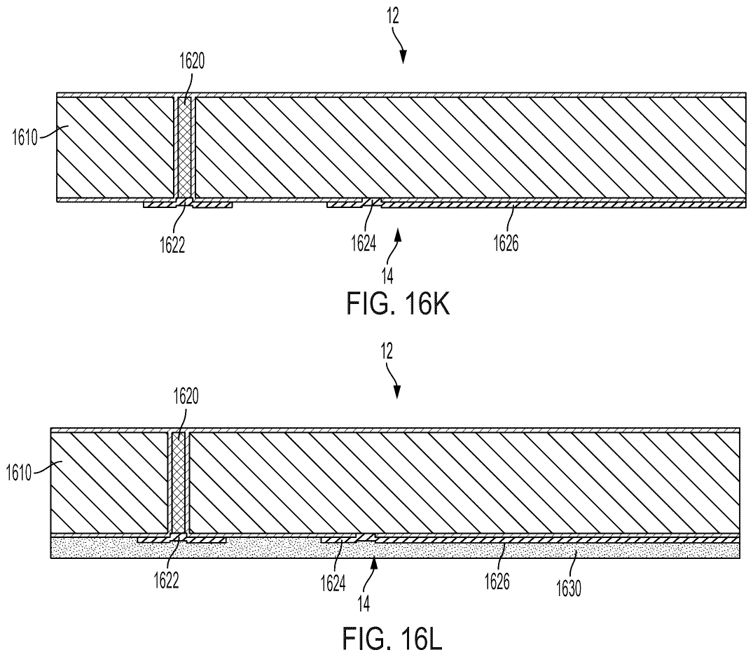

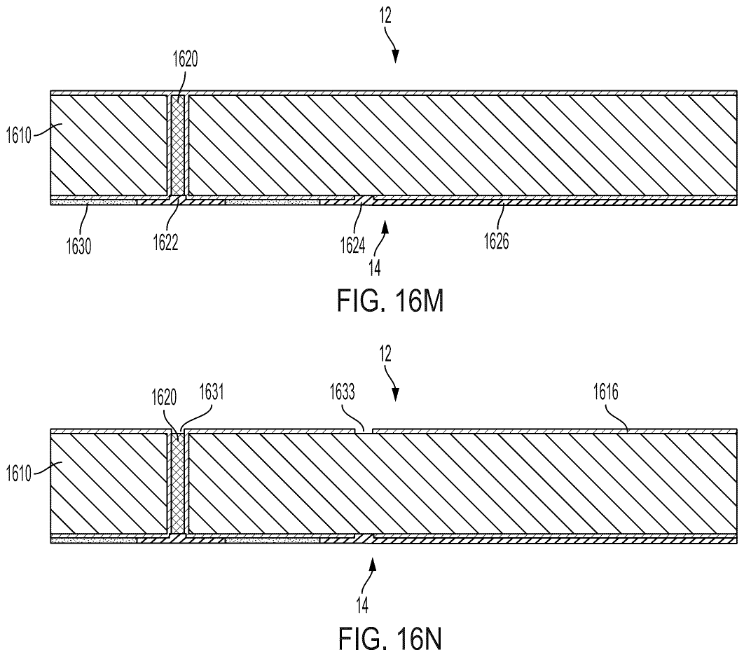

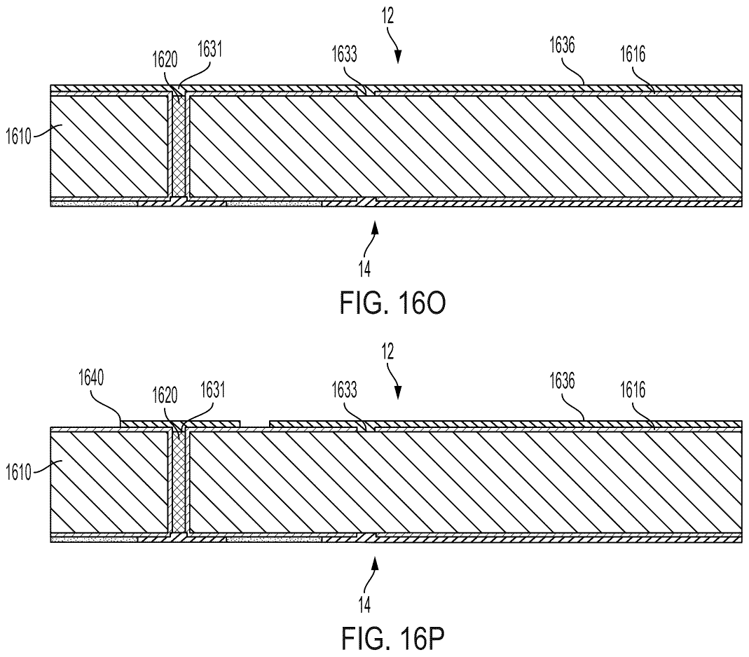

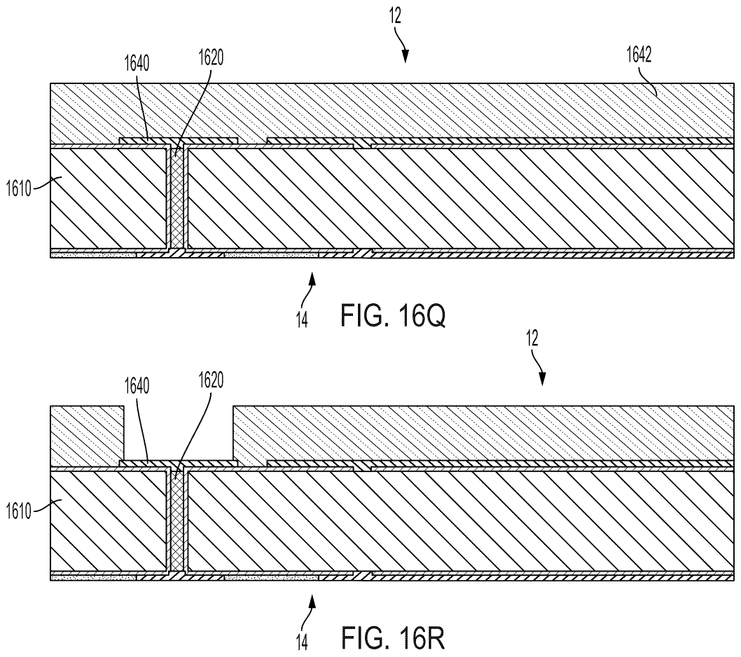

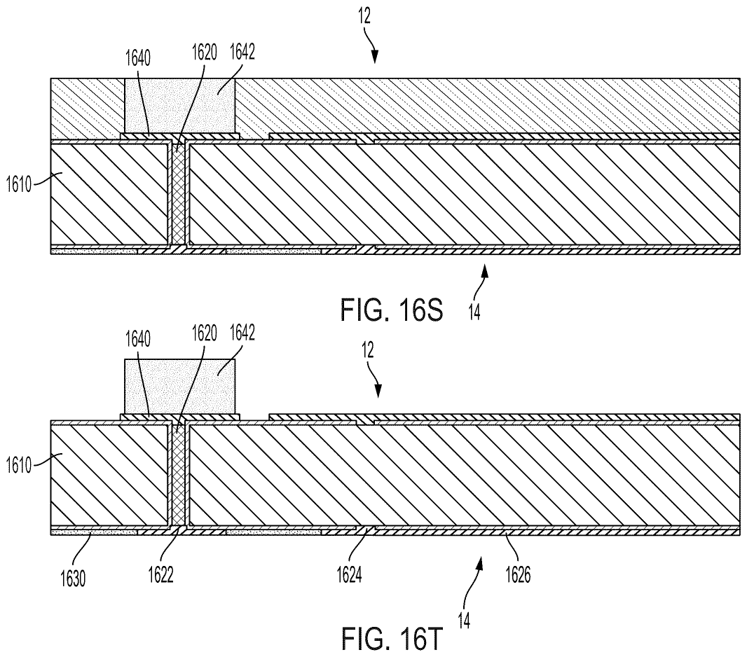

A frication method of the base wafer, in accordance with some implementations of the disclosure, is described with reference to FIG. 16A-FIG. 16T.

FIG. 16A illustrates a cross-section of a silicon wafer 1610 (e.g., substrate). The silicon wafer 1610 may be a wafer that has been polished on both sides. The silicon wafer 1610 may have a thickness in a range between 300 μm and 725 μm. The silicon wafer 1610 has a top side 12 (or device side or simply a top) and a backside or bottom side 14.

FIGS. 16B-FIG. 16H illustrate fabrication techniques for through wafer vias 1620 on the top side 12 of silicon wafer 1610. Trenches 1621 for forming the vias 1621 are vertically positioned on the silicon wafer 1610 and lined (e.g., coated or deposited) with a dielectric material 1612. The dielectric material 1612 may include silicon dioxide. Once lined with the dielectric material 1612, the trenches 1621 (and through wafer vias 1620 formed by filing the trenches 1621 with conductive material 1614 in a subsequent step) are electrically isolated from the bulk wafer material. The trenches 1621 are then filled with conductive material 1614. The conductive material 1614 may include polysilicon. The conductive material 1614 (conductive material layer) and the dielectric material 1612 (dielectric material layer) also remain on the surface of the silicon wafer 1610 (on the top side 12 and bottom side 14) and are polished and planarized after the trench fill process to ease subsequent lithographic patterning and eliminate surface discontinuities. A dielectric material 1616 (dielectric material layer) is deposited on the top surface 12. The dielectric material 1616 may include silicon dioxide. The backside 14 of the wafer 1610 is ground or polished back to expose the through wafer via 1620. A dielectric material 1618 is deposited on the bottom surface 14.

Referring to FIG. 16B, the silicon wafer 1610 (e.g., double side polished silicon wafer) is provided with arbitrary doping, resistivity, and crystal orientation, as the process relies solely on reactive ion etching to carve and form the structures. A photoresist layer is then spun onto the silicon wafer 1610 and exposed and developed using standard photolithography techniques to define the through wafer via pattern (pattern for trench 1621) for the through wafer via 1620. A trench 1621 for forming the through wafer via 1620 is formed in the silicon wafer 1610 by deep reactive ion etching of silicon using high etch rate and high selectivity etching. The trench 1621 can be form by etching in a high-density plasma using a sulfur hexafluoride (SF6) gas mixture as described in U.S. Pat. No. 5,501,893. Etching can be carefully controlled to create the trench 1621 so that the profile of trench 1621 is vertical or slightly tapered. Slight tapering of the trench 1621 ensures that a void free fill is achieved in subsequent processing when creating through wafer via 1620. Profile tapering can be achieved in reactive ion etching by tuning the degree of passivation, or by varying the parameters (power, gas flows, pressure) of the discharge during the etching process. The trench 1621 depth is typically in the range 100 μm-600 μm with diameters 5 μm-100 μm with aspect ratios pf about 10:1 or higher. The depth of the trench 1621 is chosen such that the etch does not completely etch through the thickness of wafer 1610. A procedure for etching for creating the trench 1621 may include alternating etch steps (SF6 and argon mixture) with passivation steps (Freon with argon) in an ICP plasma to achieve etch rates in excess of 2 μm/min at high selectively to photoresist (>50:1) and oxide (>100:1). The power and time of the etch cycles are increased as the trench deepens to achieve the tapered profile. Although the trench geometry is preferably slightly tapered, arbitrary trench profiles can be accommodated with adjustments in microstructure processing. After the trench 1621 for creating the through wafer via 1620 is formed, the photoresist layer is removed with a suitable process (e.g., wet chemistry technique, dry ashing technique).

As illustrated in FIG. 16C, the trench 1621 is then lined (e.g., coated, deposited) with an insulating dielectric material (e.g., silicon dioxide). The lining procedure serves to deposit a dielectric layer (layer of dielectric material 1612) on the top side 12 (top surface) of the silicon wafer 1610 and dielectric layer (layer of dielectric material 1612) on the sidewalls and bottom of the trench 1621. The thickness of the deposited dielectric layer may be between 0.5 μm and 2 μm. This dielectric layer deposition can be accomplished with chemical vapor deposition (CVD) techniques or by oxidizing silicon at high temperatures. In thermal oxidation, the wafer is exposed to an oxygen rich environment at temperatures between 900° C. and 1150° C. This oxidation process consumes silicon surfaces to form silicon dioxide. In a CVD fill, some dielectric is deposited on the walls but filling also occurs from deposition on the bottom of the trench. CVD dielectric lining of trenches has been demonstrated with TEOS or silane mixtures in plasma enhanced CVD chambers and low-pressure CVD furnace tubes.

Referring to FIG. 16D, the trench 1621 is then filled with a conductive material (e.g., metal or polysilicon). The filling procedure results in the mostly solid conductive segment in the trench 1621, and serves to deposit a layer of conductive material 1614 on the top side 12 (top surface) of the silicon wafer 1610. The thickness of the deposited layer with conductive material 1614 is usually in excess of 1 μm. This fill can be accomplished with electroplating for metals or with chemical vapor deposition (CVD) techniques for polysilicon. In low pressure chemical vapor deposition (LPCVD), the wafer is exposed to silane (SiH4) gas environment at temperatures from 560° C. to 650° C. The addition of gases such as phosphine (PH3) or diborane (B2H6) into the process allow the polysilicon to be doped. The resulting polysilicon is conductive.

As illustrated in FIG. 16E, the conductive material 1614 (layer with conductive material 1614) and the dielectric material 1612 (layer with dielectric material 1612) on the top side 12 (top surface) of the silicon wafer 1610 are removed and the surface planarized. This is typically done using chemical mechanical polishing (CMP).

Referring to FIG. 16F, a layer of dielectric material 1616 is deposited on the top side 12 (top surface) of the silicon wafer 1610. The thickness of the deposited layer (layer of dielectric material 1616) is usually 0.5-2 μm. This material deposition can be accomplished with chemical vapor deposition (CVD) techniques or by oxidizing silicon at high temperatures.

FIG. 16G illustrates the cross section of wafer 1610 after the bottom side (back side) 14 has been ground and polished to reveal the through wafer via 1620.

In FIG. 16H, a dielectric material 1618 (layer of dielectric material 1618) is deposited on the bottom surface 14 of silicon wafer 1610. The dielectric material 1618 may include silicon dioxide.

Referring to FIG. 16I, a photoresist layer is then spun onto the bottom side 14 of wafer 1610, exposed and developed using standard photolithography techniques to define contact openings 1621 and 1623 where electrical contacts 1622 and 1624 will be made, respectively. Reactive ion etching may be used to transfer the photoresist pattern to the layer 1618. For example, the silicon dioxide mask is etched using Freon gas mixture (e.g., CHF3, CF4). High etch rates for silicon dioxide etching are achieved using a high-density plasma reactor, such as an inductively coupled plasma (ICP) chamber. These ICP chambers use a high-power RF source to sustain the high-density plasma and a low-power RF bias on the wafer to achieve high etch rates at low ion energies. Oxide etch rates of 200 nm/min and selectivities to photoresist greater than 1:1 are common for this hardware configuration. Contact opening 1621 is made to the through wafer via 1620. Contact opening 1623 is made to the silicon wafer 1610.

Metallization on the bottom side 14 of the silicon wafer 1610 then proceeds as illustrated in FIG. 16J. Metal is deposited to form a metal layer 1626. For one example, the metal (e.g., metal including aluminum) is patterned using wet etching techniques. For another example, the metal is an under-bump metallization. Contact to the underlying silicon wafer 1610 is established through contact opening 1623. Contact to the underlying through wafer via 1620 is established through contact opening 1621.

FIG. 16K illustrates the patterning of metal layer 1626 on the bottom side 14 of silicon wafer 1610. The patterning is done using photolithography and etching. In this example, the contact 1622 adjacent to the contact opening 1621, and the contact 1624 adjacent to the contract opening 1623 are defined. Solder bumping can be applied to contacts 1622 and 1624.

Referring to FIG. 16L, a layer of insulating dielectric material (e.g., silicon dioxide) 1630 is deposited on the bottom side 14 of wafer 1610. The thickness of dielectric layer 1630 should be at least the same thickness as metal layer 1626. In this example, the thickness of dielectric layer 1630 is thicker, to allow for the planarization of the surface.

As illustrated in FIG. 16M, the dielectric layer 1630 on the bottom side 14 of the silicon wafer 1610 is partially removed and the surface planarized. This process can be accomplished using chemical mechanical polishing (CMP). Contacts 1622 and 1624 are exposed and the remainer of dielectric layer 1630 fills in the space between contacts 1622 and 1624.

Referring to FIG. 16N, a photoresist layer is then spun onto the top side 12 of wafer 1610, exposed and developed using standard photolithography techniques to define where contact openings 1631 and 1633. Reactive ion etching may be used to transfer the photoresist pattern to the layer 1616. Contact opening 1631 is made to the through wafer via 1620. Contact opening 1633 is made to the silicon wafer 1610.

Metallization on the top side 12 of the silicon wafer 1610 then proceeds as illustrated in FIG. 16O. Metal is deposited to form a metal layer 1636. For example, the metal to form the metal layer 1636 is a stack of titanium tungsten (TiW) and gold (Au). TiW serves as an adhesion layer while Au serves as a conductive bondable layer. In this example, contact to the underlying silicon wafer 1610 is done through contact opening 1633. Contact to the underlying through wafer via 1620 is done through contact opening 1631.

FIG. 16P illustrates the patterning of metal layer 1636 on the top side 12 of silicon wafer 1610. The patterning can be accomplished using photolithography and wet etching. The patterning defines the shape and location of capacitive sense electrode area 1640.

As shown in FIG. 16Q, a photoresist layer 1642 is applied to the top surface 12 of silicon wafer 1610. In this example, the photoresist layer 1642 includes SU-8. SU-8 is a commonly used epoxy-based negative photoresist. The thickness of the photoresist layer 1642 ranges between 50 μm and 200 μm.

In FIG. 16R, the photoresist layer 1642 has been patterned to expose the region above capacitive sense electrode area 1640.

Referring to FIG. 16S, a layer of metal 1642 has been deposited in the exposed region above capacitive sense electrode area 1640. The thickness of the deposited layer substantially matches the thickness of the photoresist layer 1642 (50-200 μm). This material deposition can be accomplished with electroplating techniques. In this example, the metal layer 1642 includes nickel (Ni).

After the metal layer 1642 deposition process is complete, the photoresist layer 1642 is removed with a suitable process (e.g., wet chemistry technique, dry ashing technique) as shown in FIG. 16T.

### (b) Fabrication of the Device Wafer

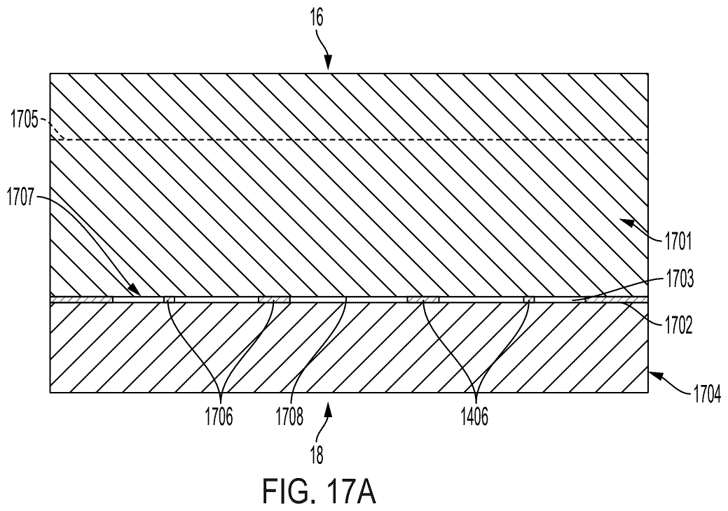

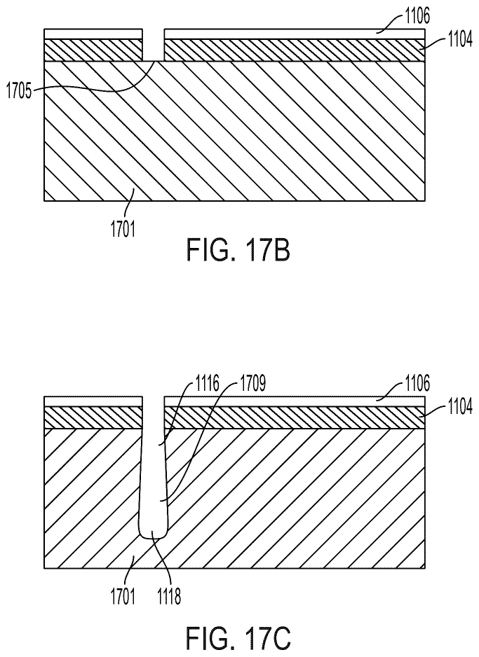

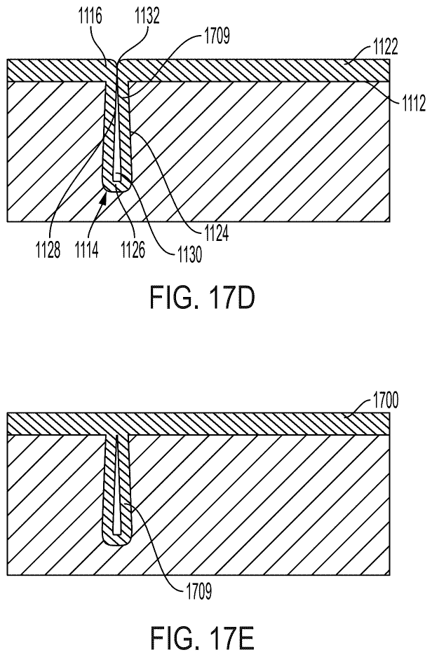

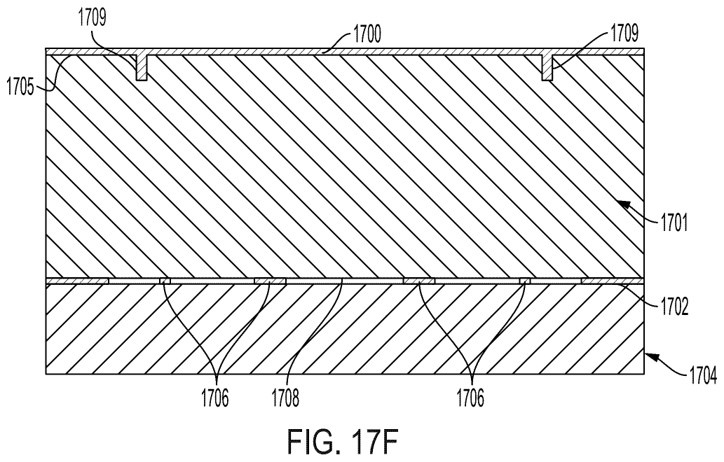

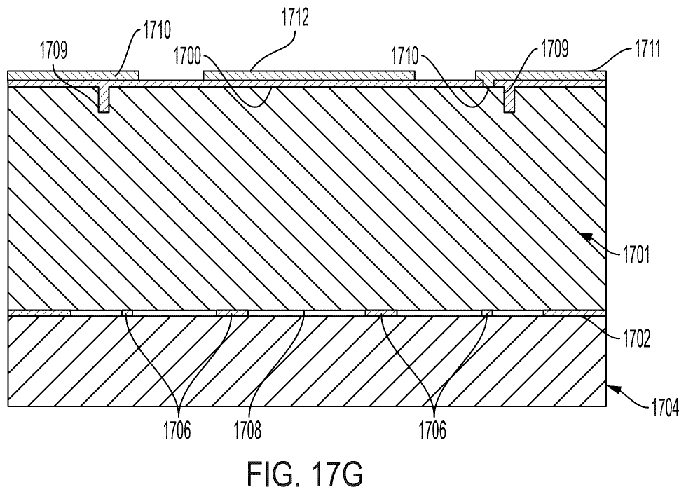

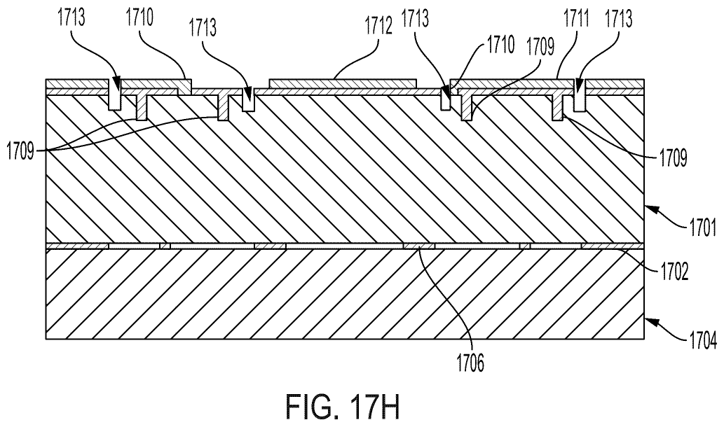

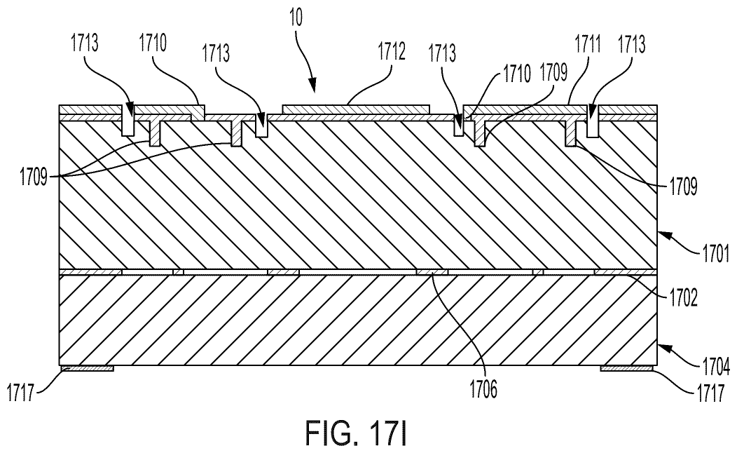

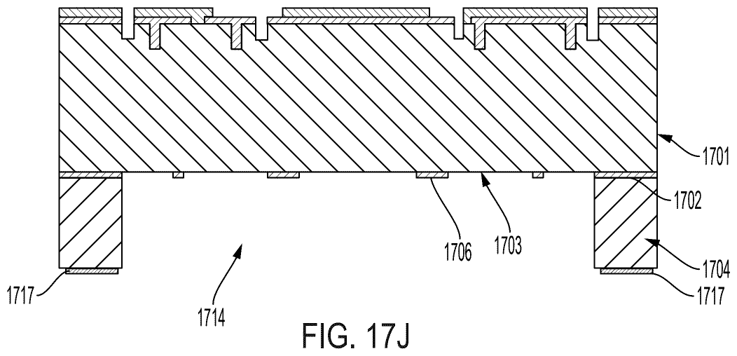

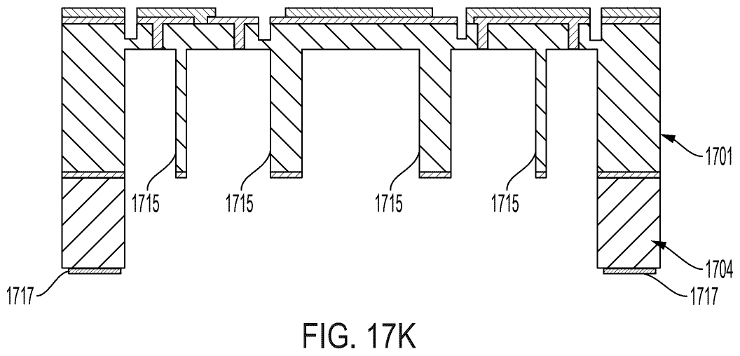

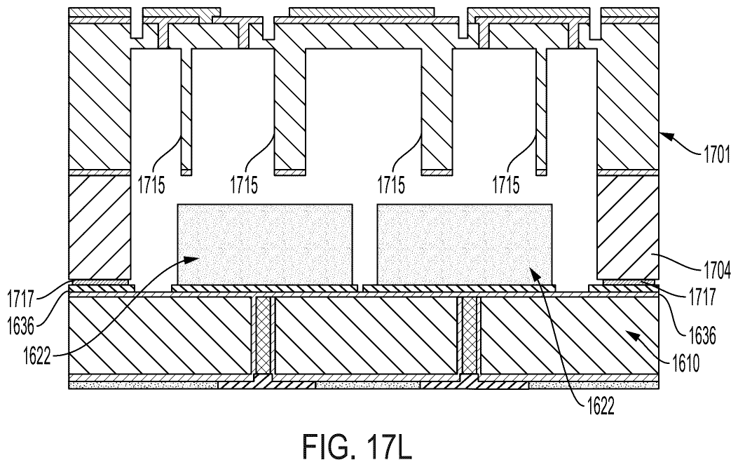

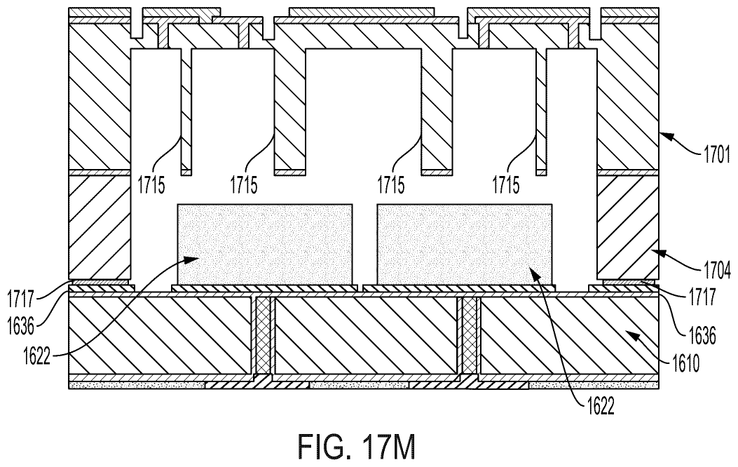

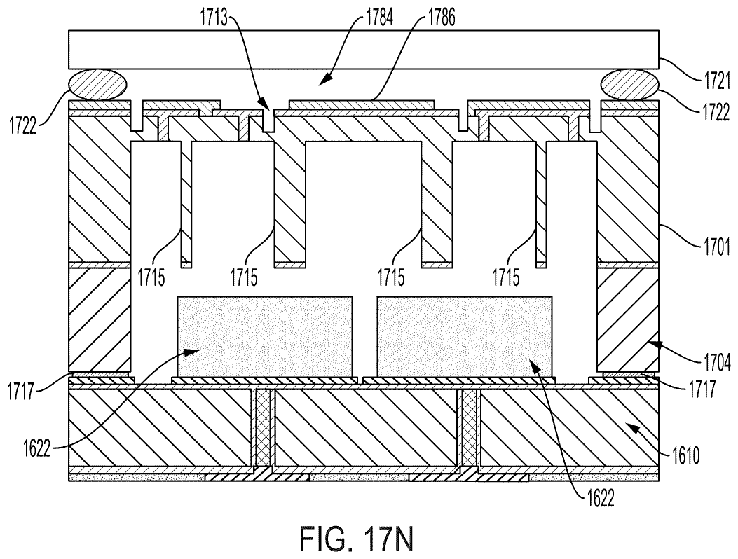

A fabrication method of the device wafer, in accordance with some implementations of the disclosure, is described with reference to FIG. 17A-FIG. 17M.

For this approach, a masking dielectric layer is patterned in the outline of the blades before fusion bonding of a spacer wafer, yet the blades themselves are not etched until later in the process. This enables the wafer stack to proceed through polishing and trench isolation processes without compromising wafer fragility or introducing problematic membrane structures. In FIG. 17A, a silicon device wafer 1701 may have a thickness in a range between 300 μm and 725 μm. The silicon wafer 1701 has a top side 16 (e.g., top orientation) and a backside or bottom side 18 (e.g., back orientation). A backside dielectric layer 1702 of the device wafer 1701 is patterned and etched to define the blade masking layer 1706. The etch is not completed to the backside silicon surface 1707. Instead, a small amount of the dielectric layer 1703 is left. In this example, the thickness of the dielectric layer 1703 is 500 nm, and the total thickness of masking layer 1706 is 3 μm. The device wafer 1701 is then fusion bonded to a spacer wafer 1704, bonding only at the masking layer 1706 (blade patterns). Sealed cavities 1708 remain at the bond interface after the bond anneal. Next, the device wafer 1701 is polished to interface 1705 to match the desired blade depth.

FIG. 17B-FIG. 17E illustrate a portion of the upper interface 1705 of the silicon device wafer 1701 in a MEMS actuator which illustrates fabrication techniques for isolation trenches 1709 on the top side 16 of silicon wafer 1701. The isolation trenches 1709 are vertically positioned on the silicon wafer substrate and filled with a dielectric material. The dielectric material may include silicon dioxide. Once filled, the isolation trenches 1709 provide electrical isolation between blades after the mirror is released. A layer 1700 also remains on the surface of the silicon wafer 1701 and is planarized after the isolation trench fill process to ease subsequent lithographic patterning and eliminate surface discontinuities.

Referring to FIG. 17B, a masking layer 1104 is deposited on silicon wafer 1701. The masking layer 1104 may include one or more silicon dioxide layers (e.g., an oxide layer). The silicon wafer 1701 can have arbitrary doping, resistivity, and crystal orientation, as the process relies solely on reactive ion etching to carve and form the structures. The masking layer 1104 serves the function of protecting the upper surface of the silicon wafer 1701 during the isolation trench etching process, and thus represents a masking layer. This masking layer 1104 can be formed from any number of techniques, including thermal oxidation of silicon or chemical vapor deposition (CVD). A thickness of the masking layer 1104 may be between 0.5 μm and 1.0 μm. A photoresist layer 1106 is then spun onto the silicon wafer 1701 and exposed and developed using one or more photolithography techniques to define the isolation trench pattern for the isolation trench 1709. Reactive ion etching may be used to transfer the photoresist pattern to the masking layer 1104, exposing the top surface 1705 of the silicon wafer 1701. For example, the masking layer 1104 (silicon dioxide mask) is etched using Freon gas mixture (e.g., CHF3, CF4). High etch rates for silicon dioxide etching are achieved using a high-density plasma reactor, such as an inductively coupled plasma (ICP) chamber. These ICP chambers use a high-power RF source to sustain the high-density plasma and a low-power RF bias on the wafer to achieve high etch rates at low ion energies. Oxide etch rates of 200 nm/min and selectivities to photoresist greater than 1:1 are common for this hardware configuration.

As illustrated in FIG. 17C, an isolation trench 1709 is formed in the silicon wafer 1701 by deep reactive ion etching of silicon using high etch rate and high selectivity etching. The trench is commonly etched in a high-density plasma using a sulfur hexafluoride (SF6) gas mixture as described in U.S. Pat. No. 5,501,893. Etching can be controlled so that the isolation trench 1709 profile is reentrant, or tapered, with the top 1116 of the isolation trench 1709 being narrower than the bottom 1118 of the isolation trench 1709. Tapering of the isolation trench 1709 ensures that good electrical isolation is achieved in subsequent processing. Profile tapering can be achieved in reactive ion etching by tuning the degree of passivation, or by varying the parameters (power, gas flows, pressure) of the discharge during the etching process. Because the isolation trench 1709 is filled with dielectric material, the opening at the top 1116 of the isolation trench 1709 is less than 2 μm in width in this example. The isolation trench 1709 depth is in the range 10-50 μm in this example. A procedure for etching for creating the isolation trench 1709 may include alternating etch steps (SF6 and argon mixture) with passivation steps (Freon with argon) in an ICP plasma to achieve etch rates in excess of 2 μm/min at high selectively to photoresist (>50:1) and oxide (>100:1). The power and time of the etch cycles are increased as the trench deepens to achieve the tapered profile. Although the trench geometry is preferably reentrant, arbitrary trench profiles can be accommodated with adjustments in microstructure processing. Good isolation results can be achieved with any of a number of known trench etch chemistries. After the silicon trench is etched, the photoresist layer 1106 is removed with a suitable process (e.g., wet chemistry technique, dry ashing technique).

Referring to FIG. 17D, the isolation trench 1709 is then filled with an insulating dielectric material (e.g., silicon dioxide). The filling procedure results in the mostly solid isolation segment in the isolation trench 1709, and serves to deposit a layer of dielectric material 1122 on the top side 16 (top surface) of the silicon wafer 1701 and dielectric layers on the sidewalls 1124 and bottom 1126 of the isolation trench 1709. The thickness of the deposited layer is usually in excess of 1 μm. This fill can be accomplished with chemical vapor deposition (CVD) techniques or by oxidizing silicon at high temperatures. In thermal oxidation, the wafer is exposed to an oxygen rich environment at temperatures between 900° C. and 1150° C. This oxidation process consumes silicon surfaces to form silicon dioxide. The resulting volumetric expansion from this process causes the sidewalls of the trenches to encroach upon each other, eventually closing the trench opening. In a CVD fill, some dielectric is deposited on the walls but filling also occurs from deposition on the bottom of the trench. CVD dielectric fill of trenches has been demonstrated with TEOS or silane mixtures in plasma enhanced CVD chambers and low-pressure CVD furnace tubes. Another option is to coat the sides of trench 1709 with silicon oxide and fill it with another material such as polysilicon or material similar to polysilicon.

During the isolation trench 1709 filling process, it is common for most isolation trench profiles to be incompletely filled, causing an interface 1128 and a void 1130 to be formed in the isolation trench 1709. A local concentration of stress in the void 1130 can cause electrical and mechanical malfunction in some devices but is generally unimportant for micromechanical devices due to the enclosed geometry of the isolation trench 1709. The interface 1128 and void 1130 can be eliminated by shaping the isolation trench 1709 to be wider at the isolation trench opening located at the top 1116 of the isolation trench 1709 than the bottom of the isolation trench 1709. However, good electrical isolation would then require additional tapering of the microstructure trench etch in the later steps. Another artifact of the isolation trench filling process is an indentation 1132 that is created in the surface of the dielectric layer 1122 centered over the isolation trench 1709. This indentation is unavoidable in most trench filling processes, and can be as deep as 0.5 μm, depending on the thickness of the deposition.

To remove the indentation 1132, the surface is planarized to form a flat, or substantially flat, surface, as illustrated in FIG. 17E, for subsequent lithographic and deposition steps. Planarization is performed either by chemical-mechanical polishing (CMP) or by depositing a viscous material, which can be photoresist, spin-on glass, or polymide, and flowing the material to fill the indentation 1132 to a smooth finish. During etchback of the viscous material, which is the second step of planarization, the surface is etched uniformly, including the filled indentation. Therefore, by removing part of the surface oxide layer, the indentation 1132 is removed to create a uniform thickness layer. For example, if the dielectric layer 1122 is originally 2 μm in thickness, then planarization to remove the indentation 1132 leaves a dielectric layer 1700 having a final thickness of less than 1 μm. The top side 16 (e.g., upper surface) of silicon wafer 1701 is free from imperfection and is ready for further lithography and deposition.

FIG. 17F shows silicon wafer 1701 with dielectric layer 1700 and isolation trenches 1709.

Metallization on the top side 16 of the silicon wafer 1701 then proceeds as illustrated in FIG. 17G. In order to make contact to the underlying silicon wafer 1701 vias 1710 are patterned and etched into the dielectric layer 1700 using standard lithography and reactive ion etching. After the vias 1710 are etched, metallization is deposited to form a metal layer and patterned to form a metal interconnect 1711 and a contact to the silicon wafer 1701 through the via 1710. For example, the metal is aluminum and is patterned using wet etching techniques. In mirror arrays with high interconnect densities, it is advantageous to pattern the metal using dry etching or evaporated metal lift-off techniques to achieve finer linewidths. The metal layer 1711 is used to provide bond pads and interconnects, which connect electrical signals from control circuitry to each mirror to control mirror actuation.

Deposition of a second metal layer 1712 provides a reflective mirror surface. This metal is tuned to provide high mirror reflectivities at the optical wavelengths of interest and is typically evaporated and patterned using lift-off techniques to allow a broader choice of metallization techniques. For example, the metallization is comprised of 500 nm of aluminum. However, additional metal stacks such as Cr/Pt/Au may be used to increase reflectivities in the wavelength bands common to fiber optics. Because the metals are deposited under stress and will affect the eventual mirror flatness, it is advantageous to reduce the thickness of the masking layer 1700 in the region of the mirror. This can be accomplished through the use of dry etching of the underlying dielectric prior to evaporation.

In FIG. 17H, the topside processing is completed. A passivation dielectric layer (not shown) may be applied to protect the metallization during subsequent processing. The passivation dielectric layer is removed in the region of the bonding pads and from the actuator region. The mirror structure including frame, mirror, and supports are defined using multiple etches that define trenches 1713 separating the structural elements. The etches are self-aligned and proceed through the various metal, dielectric, and silicon wafer 1701. A further blanket deposition is applied to the topside which passivates the sidewalls of the trenches 1713 and prepares the topside for mechanical release.

Metallization on the bottom side 18 of the spacer wafer 1704 then proceeds as illustrated in FIG. 17I. Metal is deposited to form a metal layer 1717. For example, the metal is a stack of titanium tungsten (TiW) and gold (Au). TiW serves as an adhesion layer while Au serves as a conductive bondable layer. Patterning is done using photolithography and wet etching. The patterning defines the shape and location of bond regions.

Referring to FIG. 17J, a window or opening 1714 is patterned and etched through the silicon of spacer wafer 1704, which exposes the blade pattern 1706 in dielectric layer 1702. The silicon etch is highly selective and will stop on the blade pattern 1706 and the remaining dielectric mask 1703.

In FIG. 17K, the partially etched dielectric 1703 is removed in a blanket etching. The blades 1715 are now etched to the desired depth. The etching is performed using deep silicon etching at high selectivity to oxide using the techniques disclosed in U.S. Pat. No. 5,501,893. The deep silicon etching achieves near vertical profiles in the blades 1715, which can be nominally 5-20 μm wide and in excess of 300 μm deep.

Because the device wafer is now prepared for microstructure release, the device wafer 1701 becomes more susceptible to yield loss due to handling shock or air currents. In order facilitate handling, to aid in hermetically sealing the mirror array, and to allow for base blades, silicon wafer 1610 is bonded to the device wafer 1701 to protect mirrors after release, as shown in FIG. 17L. For example, the bonding is accomplished through the use of bonding element 1717 and metal layer 1636. These materials can be bonded by using eutectic or thermocompression bonding techniques. The wafers 1701 and 1610 are aligned and brought together. Heat and pressure are applied until the materials 1717 and 1636 bond together. In this manner, a hermetic seal is made to surround the entire mirror array. The separation between the device wafer 1701 and the silicon wafer 1610 using the spacer wafer 1704, allows the blades 1715 to swing through high rotation angles without impedance. Base blades 1622 are fabricated to maintain a gap between the blades 1715 and the electrodes 1622 to allow the blades to swing through high rotation angles without impedance. Typically, the gap required is greater than 25 μm.

Final structure release is accomplished on the wafer topside in FIG. 17M using a combination of dry etching of silicon dioxide and silicon, which punctures through the trenches 1713 to suspend the movable elements of to suspend the movable elements of the mirror 1786. To completely seal the mirrors from the outside environment, a lid wafer 1721 is bonded to the device wafer 1701, preferably through the bonding element 1722 (e.g., frit glass seal) as shown in FIG. 17N. The lid wafer 1721 is typically made of glass, which allows incoming light to be transmitted with low loss in the mirror cavity 1784, reflect off the upper surface of the mirror 1786, and then transmit out of the mirror cavity 1784.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the claims define the scope of the invention and that methods and structures within the scope of these claims and their equivalents be covered thereby.

What is claimed:

1. An actuator, comprising:
a frame defining a cavity, the frame including a first base;
a stage including a second base;
a first flexure and a second flexure suspending the stage within the cavity;
a first blade coupled to the first base;
a second blade coupled to the second base; and
an insulation layer comprising a first portion disposed between the first base and the first blade, a second portion disposed between the second base and the second blade, and a third portion disposed on the second blade,
wherein the third portion of the insulation layer has a first side in contact with the second blade and a second side that is exposed.

2. The actuator of claim 1, wherein the insulation layer comprises a buried oxide layer.

3. The actuator of claim 1, wherein the first blade is electrically connected to the first base by at least one first via extending through the first portion of the insulation layer.

4. The actuator of claim 1, wherein the second blade is electrically connected to the second base by at least one first via extending through the second portion of the insulation layer.

5. The actuator of claim 1, wherein the first blade extends from the first base substantially perpendicularly so that the first base and the first blade define a T-shaped configuration.

6. The actuator of claim 1, wherein the third portion of the insulation layer and a side surface of the second base collectively define a notch.

7. The actuator of claim 6, wherein the notch defines an opening that overlaps at least partially with the first base in a first direction.

8. The actuator of claim 1, wherein applying different voltages to the first blade and the second blade causes the second blade to be electrostatically attracted toward the first blade, thereby causing the stage to pivot about the first and second flexures.

9. The actuator of claim 1, wherein:
applying different voltages to the first blade and the second blade causes the second blade to overlap with the first blade, thereby generating a primary actuating torque;
applying the different voltages to the first blade and the second blade further causes the second blade to also overlap with a first end of the first base, thereby generating a supplemental actuating torque; and
the first blade extends from the first base substantially perpendicularly such that the first base and the first blade define a T-shaped configuration.

10. The actuator of claim 1, further comprising a third blade coupled to a third base; wherein:
applying a first voltage to the first blade and the third blade and applying a second voltage to the second blade cause the second blade to overlap with the first blade and the third blade, thereby generating a primary actuating torque;
applying the first voltage to the first blade and the third blade and applying the second voltage to the second blade further cause the second blade to also overlap with a first end of the first base and a first end of third base thereby generating a supplemental actuating torque;
the first blade extends from the first base substantially perpendicularly such that the first base and the first blade define a first T-shaped configuration;
the third blade extends from the third base substantially perpendicularly such that the third base and the third blade define a second T-shaped configuration,
the frame includes the third base; and
the first voltage is different from the second voltage.

11. An actuator, comprising:
a frame defining a cavity;
a stage;
a first flexure and a second flexure suspending the stage within the cavity;
a plurality of stage fingers extended from the stage toward the frame, the stage fingers including a first stage finger; and
a plurality of frame fingers extended from the frame toward the stage, the frame fingers including a first frame finger,
wherein an end portion of the first stage finger overlaps with an end portion of the first frame finger.

12. The actuator of claim 11, further comprising:
a first blade extending from the stage; and
a second blade extending from the frame, the first and second blades being substantially parallel.

13. The actuator of claim 11, further comprising:
a first blade extending from the stage;
a second blade extending from the frame; and
a third blade extending form the frame, the second and third blades being spaced apart to define a gap,
wherein the first blade is configured to tilt into the gap during operation.

14. The actuator of claim 11, wherein:
the plurality of stage fingers includes the first stage finger and a second stage finger in parallel with the first stage finger; and
the end portion of the first frame finger is disposed between the first stage finger and the second stage finger.

15. The actuator of claim 11, wherein:
the plurality of frame fingers includes the first frame finger and a second frame finger in parallel with the first frame finger; and
the end portion of the first stage finger is disposed between the first frame finger and the second frame finger.

16. The actuator of claim 12, wherein applying different voltages to the first blade and the second blade causes the plurality of stage fingers to be electrostatically attracted toward the plurality of frame fingers, thereby causing the stage to pivot about the first and second flexures.

17. The actuator of claim 12, wherein applying different voltages to the first blade and the second blade, the plurality of stage fingers and the plurality of frame fingers generate a first actuating torque; and applying the different voltages to the first blade and the second blade further causes the first blade to overlap with the second blade, thereby generating a second actuating torque.

18. The actuator of claim 12, wherein applying different voltages to the first blade and the second blade, the plurality of stage fingers and the plurality of frame fingers generate a first actuating torque; applying the different voltages to the first blade and the second blade further causes the first blade to overlap with the second blade, thereby generating a second actuating torque; and applying the different voltages to the first blade and the second blade further causes the first blade to overlap with the plurality of frame fingers, thereby generating a third actuating torque.

19. The actuator of claim 12, wherein:
a first overlap area is defined by interleaving of the plurality of stage fingers with the plurality of frame fingers; and
applying different voltages to the first blade and the second blade causes the first overlap area increases.

20. The actuator of claim 12, wherein:
a first overlap area is defined by a first overlapping area of the first blade and the second blade; and
applying different voltages to the first blade and the second blade causes the first overlap area increases.

21. The actuator of claim 12, wherein applying different voltages to the first blade and the second blade causes a top surface of the plurality of stage fingers to elevate such that the top surface of the plurality of stage fingers is disposed higher than a top surface of the plurality of frame fingers.
